(19) United States
(12) Patent Application Publication
(10) Pub. No.: US 2022/0255068 A1
(43) Pub. Date: Aug. 11, 2022

(54) Deeply Rechargeable Battery Systems and Methods

(71) Applicant: Georgia Tech Research Corporation, Atlanta, GA (US)

(72) Inventors: Nian Liu, Atlanta, GA (US); Yutong Wu, Atlanta, GA (US); Yamin Zhang, Atlanta, GA (US)

(21) Appl. No.: 17/639,824

(22) PCT Filed: Sep. 3, 2020
(86) PCT No.: PCT/US2020/049142

§ 371 Date: Mar. 2, 2022

Related U.S. Application Data
(60) Provisional application No. 62/895,455, filed on Sep. 3, 2019.

(51) Int. Cl. H01M 4/36; H01M 4/48

(52) U.S. Cl. CPC H01M 4/366; H01M 2004/027; H01M 4/48

(57) ABSTRACT

Deeply rechargeable battery systems and methods, where a core/shell nanoscale structure provides deeply rechargeable anodes that overcome intrinsic limitations of conventional battery materials that involve soluble intermediates or insulating discharge products. The deeply rechargeable battery systems and methods simultaneously overcome the dilemmas of passivation and dissolution. An ion-sieving concept is applied to a Zn anode that confines larger zincate ions and allows smaller hydroxide ions to permeate, can limit/prevent ZnO dissolution and electrode shape change.

### CROSS-REFERENCE TO RELATED APPLICATIONS

This application claims the benefit of U.S. Provisional Patent Application No. 62/895,455 filed 3 Sep. 2019, the entire contents and substance of which are hereby incorporated by reference as if fully set forth below.

### STATEMENT REGARDING FEDERALLY SPONSORED RESEARCH OR DEVELOPMENT

Not Applicable

### THE NAMES OF THE PARTIES TO A JOINT RESEARCH AGREEMENT

Not Applicable

### SEQUENCE LISTING

Not Applicable

### STATEMENT REGARDING PRIOR DISCLOSURES BY THE INVENTOR OR A JOINT INVENTOR

Not Applicable

### BACKGROUND OF THE DISCLOSURE

### 1. Field of the Disclosure

The various exemplary embodiments of the disclosure relate generally to processes, methods, and systems energy carrying. It is particularly related to deeply rechargeable battery systems and methods.

### 2. Background

Alternative energy carriers have been sought after due to fossil fuels' slow regeneration and environmental concerns such as climate change, air and water pollution. Indeed, the depletion of fossil fuel resources is leading to steadily increasing energy demands.

Sustainable electrochemical energy storage (EES) systems are being sought that are low-cost, reliable, and eco-friendly. Extensive research into EES in recent years has prompted the emergence of technologies for applications in portable devices, electric vehicles (EVs) and grid-scale energy-storage systems.

When carrying clean electricity from solar or wind, batteries are promising to alleviate the current energy and environmental problems. A wide variety of electrochemical cells, or “batteries,” are known, and in general are devices that convert chemical energy into electrical energy by means of an electrochemical oxidation-reduction reaction.

Batteries can be generally described as comprising three components: an anode that contains a material that is oxidized (yields electrons) during discharge of the battery (i.e., while it is providing power), a cathode that contains a material that is reduced (accepts electrons) during discharge of the battery, and an electrolyte that provides for transfer of ions between the cathode and anode. During discharge, the anode is the negative pole of the battery, and the cathode is the positive pole.

Batteries can also be generally categorized as being “primary,” where the electrochemical reaction is essentially irreversible, so that the battery becomes unusable once discharged, and “secondary,” where the electrochemical reaction is, at least in part, reversible so that the battery can be “recharged” and used more than once. Secondary batteries are increasingly used in many applications because of their convenience (particularly in applications where replacing batteries can be difficult), reduced cost (by reducing the need for replacement), and environmental benefits (by reducing the waste from battery disposal).

Secondary batteries utilizing faradaic energy storage mechanisms are the most prominent systems among the EES technologies. Undoubtedly, lithium-ion batteries (LIBs) have been an enormous success in the realms of portable devices and EVs due to their high energy density, light weight, and low self-discharge rate. For these reasons, LIBs are still receiving significant attention.

However, LIBs continue to face challenges related to safety (with their use of flammable organic electrolytes), energy density, longevity, and concerns around material availability (such as Li and Co metals). Particularly, battery safety is an increasingly vital concern in electric vehicle applications. These issues seriously limit the popularization of EVs and the development of grid-energy storage.

One approach to these limitations includes research into fluorinated organic electrolytes and solid-state electrolytes as alternatives to flammable organic solvents. Another approach towards ultra-safe batteries is to develop battery chemistries that are compatible with aqueous electrolytes. Batteries that use aqueous electrolytes have enhanced safety, ion conductivity, and cost-effectiveness. Yet, a main obstacle to successful aqueous batteries includes their narrow stable voltage window and evolution of hydrogen and oxygen gases that occurs upon the electrolysis of water.

Neutral and alkaline electrolytes are two major classes of aqueous electrolytes for zinc anodes. Rechargeable zinc anodes in neutral electrolytes such as “water-in-salt” electrolytes and molten hydrate electrolytes have been investigated. Nonetheless, cycling zinc anodes deeply in alkaline electrolytes remains challenging due to the dramatic change of the chemical and physical forms of zinc species and the severe hydrogen evolution side reaction during cycling. Despite the challenges, it is important to enable highly rechargeable zinc anodes in alkaline electrolytes to propel the development of rechargeable Zn-air batteries, as air cathodes kinetically favor alkaline electrolytes over neutral ones.

Although non-alkaline electrolytes have been investigated for Zn-air batteries, their oxygen reduction reaction (ORR) and their oxygen evolution reaction (OER) kinetics at the air cathode are slow. In alkaline electrolytes, there are two consecutive zinc conversion reactions (Complexation, Equation (1) and Anode, Equation (2)). This solid-solute-solid mechanism inherently causes passivation and dissolution issues on zinc anodes.

ZnO+H₂O+2OH⁻ [symbol] Zn(OH)₄²⁻ (1)

Zn(OH)₄²⁻+2e⁻ [symbol] Zn+4OH⁻ (2)

These issues are due to the following processes: (i) the insulating discharge product ZnO passivates the surface of zinc anodes, preventing the latter from further discharging or recharging back to metallic zinc, and (ii) the intermediate zincate Zn(OH)₄²⁻ is soluble in alkaline electrolytes, which leads to active material loss, random ZnO precipitation on the electrode, and morphology change of the electrode over cycling.

In addition, the hydrogen evolution reaction (HER) Equation (3) is a side reaction on the zinc anode. In an alkaline electrolyte with pH 14, the Zn/ZnO standard reduction potential (−1.26 V vs the standard hydrogen electrode (SHE)) is lower than that of the HER (−0.83 V vs SHE). Thus, HER is thermodynamically favored during charging, which causes low Coulombic efficiency, electrolyte drying, bubble accumulation, and eventually cell failure.

2H₂O+2e⁻ [symbol] H₂+2OH⁻ (3)

A battery-gas chromatography (GC) quantitative analysis method is used herein to identify the influence of HER on the capacity loss of zinc anodes. The cathode and overall reactions are, respectively:

2ZiOOH+2H₂O+2e⁻ [symbol] 2Ni(OH)₂+2OH⁻ (4)

2ZiOOH+Zn+H₂O [symbol] 2Ni(OH)₂+Zn (5)

In consideration of Zn anodes, HER suppressing Zn anodes should possess high Coulombic efficiency (discharge capacity/charge capacity). Thus, the need for ultra-safe, high-energy, and low-cost EES devices has prompted a search for new energy-storage technologies.

Within the stability window of water, zinc is an attractive anode material because it is the most active metal that is stable with water. Rechargeable Zn-based aqueous batteries have immense potential in large-scale energy storage systems due to their high gravimetric capacity (specific capacity) of 820 milliampere hours per gram (mA·h/g; hereinafter “mAh/g” or similar units) and high volumetric capacity of 5854 milliampere hours per cubic centimeter (mA·h/cm³; hereinafter “mAh/cm³”, “mAh/mL” or similar units), cost effectiveness, and high chemical stability in air and aqueous solution. Thus, as an anode, Zn has roughly three times the volumetric capacity compared to Li (2062 mAh/cm³). Without the necessity of flammable organic electrolyte, aqueous Zn-based batteries do not require the comparably complex subsystems required for lithium-based batteries including thermal management, sophisticated electronic controls, and structural protection to manage any catastrophic events.

By using aqueous electrolyte, zinc-based batteries not only are safer, but also can be manufactured in ambient air rather than dry room, and have much higher tolerance to moisture and air during operation. Having two valence electrons and high density, zinc metal has three times the volumetric capacity of lithium metal. Among various zinc-based batteries, Zn-air has a theoretical volumetric energy density (energy density) of 4400 watt-hour per liter (W·h/L; hereinafter “Wh/L” or similar units), that is more than three times of conventional Li-ion batteries (1400 Wh/L), and approaching Li-S batteries (5200 Wh/L). Primary Zn-air batteries have already been the battery of choice for hearing aids, which require extremely high energy density and safety. Finally, zinc is abundant, low-cost, and environmentally benign, rendering them suitable for large scale applications.

In contrast to a LIB graphite host anode, which undergoes intercalation and de-intercalation, the zinc anode undergoes dissolution/precipitation, complexation, and reduction/oxidation repetitive processes during the charge/discharge process in aqueous electrolytes. The overall reactions on the zinc anode are:

As a result of this dissolution/precipitation cycle, the longstanding constraint that has prevented the implementation of Zn in next-generation batteries for large-scale application is its poor rechargeability due to, among other things, dendrite growth, shape change, and passivation.

Major challenges for a rechargeable Zn anode for aqueous batteries as a result of the solid-solute-solid mechanism, the insulating nature of discharge product (ZnO), and the water stability window include: (1) ZnO (the soluble and insulating discharge product) passivates the surface of unreacted Zn, which leads to low utilization of active material and a poor rechargeability; (2) ZnO dissolution causes Zn deposition to happen in random locations, which leads to electrode morphology change and dendrite growth after continuous cycling. In a lean electrolyte configuration, the Zn dendrite can penetrate the separator to short-circuit the battery; and (3) H₂ evolution on the Zn anode compromises Coulombic efficiency. Especially in a sealed cell with a limited amount of electrolyte (rather than the often-used beaker cell with saturated ZnO), H₂ evolution dries out the electrolyte, enhances internal pressure of the battery, and gas bubbles block the ionic pathway, which leads to a low Coulombic efficiency (≈60%) and even sudden battery failure.

Zn dendrites are formed during the charging process (i.e., electrodeposition of Zn metal) when Zn(OH)₄²⁻ and/or Zn²⁺ ions are deposited unevenly, with faster growth occurring along energetically favorable crystallographic directions, resulting in internal short circuit. Furthermore, incomplete reduction of zincate ions coupled with non-uniform redistribution of Zn electrode material during the charging process leads to densification of the electrode at specific regions over many charge/discharge cycles, causing loss of usable capacity.

Aside from dendrite formation and shape change of the Zn electrode, the passivation layer on the bulk zinc anode shortens the cycle life because active Zn is transformed into relatively insulating ZnO, which increases the internal resistance of the Zn electrode. This passivation inhibits the discharge process as the insulating ZnO film on the Zn surface blocks the migration of the discharge products and/or hydroxide ions, causing significant loss of energy efficiency for the charge/discharge cycles. While the passivation mechanism of the Zn anode in alkali electrolytes has been investigated, effective methods for resolving this problem have yet to be proposed.

Attempts have been made in the past to overcome one or two of the challenges of passivation, dissolution, and HER. For example, a recent attempt has been made to mitigate dendrite formation and shape change of the Zn electrode by altering the Zn electrode design. In one, a 3D-zinc sponge anode was prepared to improve the rechargeability of Zn-based batteries. Although the performance of the zinc battery improved with this design, problems persist: (1) passivation is still present in the 3D-zinc anodes, especially with a high depth of discharge (DOD); (2) the larger electrode-electrolyte contact area accelerates the dissolution of zinc, leading to shape change and capacity fading; and (3) the volume capacity decreases because of the porosity of the zinc sponge and the low depth-of-discharge.

In another investigation, Zn anodes with a carbon coating were utilized to improve anti-corrosion performance. However, most of these studies could not overcome the dissolution and passivation problems simultaneously. In these studies, although nanoscale, carbon-coated zinc oxide particles were used as anode materials in rechargeable zinc cells, there is considerable room for improvement to mitigate the dissolution problem. An anode composed of micron-sized ZnO spheres was synthesized by a complicated co-precipitation process or ball milling approach, which increased the tap density of the electrode, but the passivation problem still needs to be resolved.

Also, some zinc battery systems using mild electrolytes, such as ZnSO₄-MSO₄ (M=Mn, Co), Zn(CF₃SO₃)₂—Mn(CF₃SO₃), and Zn(TFSI)₂—LiTFSI, in which expensive TFSI salts should be replaced with salts having lower costs, were developed to mitigate the zinc dendritic growth effectively. Nevertheless, the reversibility of a zinc anode in alkaline electrolyte is a great concern to exploit some highly rechargeable Zn-air batteries with high specific energy density (5200 Wh/kg).

In terms of battery testing protocols, most previous results of Zn anode performance were obtained using beaker cells rather than closed cells (cylindrical cells or coin cells). In these beaker cells, abundant electrolyte significantly decreased the overall specific capacity of batteries. Also, since electrolyte saturated with ZnO was used in these beaker cells, it is difficult to ascribe the contribution of active material and calculate the performance of batteries due to the inevitable reduction of zin-cate from outsourcing of ZnO in the electrolyte. The performance of these cells cannot reflect real conditions in practical commercial batteries in which the reasonable electrolyte content is a pivotal factor for high volumetric and gravimetric capacity.

These problematic conventional battery testing protocols raise several problems: (1) the amount of electrolyte exceeds the amount of electrode materials by ≈1000 times, which lowers the overall energy density and covers the problem of electrolyte side reactions; (2) the open cell configuration covers the problem of gas evolution and cell swelling; (3) the electrolyte is usually saturated with ZnO to extend the cycle life. Yet, the capacity from the ZnO dissolved in the electrolyte is 250-fold the active material used (for example, assuming 10 mL of electrolyte and ZnO solubility of approximately 0.256 mol/L measured by inductively coupled plasma), and the mass of dissolved ZnO is not counted when calculating the specific capacity. The true performance of the active material was not evaluated; (4) the utilization of Zn is usually low (<approximately 50%), which extends the cycle life, but lowers the overall energy density.

As noted, advantages of the Zn-air cell compared to the Li—S cell are that Zn is much more economical than Li and the battery is safer due to absence of flammable organic liquid, making Zn-based batteries attractive candidates for electric vehicles and large-scale energy storage. There has been recent progress on rechargeable Zn anode materials in neutral or mildly acidic conditions that eliminate concerns of ZnO passivating the Zn surface.

In order for Zn-based aqueous batteries to have higher specific energy than state-of-the-art LIBs, however, an oxygen cathode must be used, which favors alkaline electrolytes (e.g., KOH) to facilitate the ORR and the OER. Although developing efficient ORR and OER electrocatalysts could lower the polarization and improve the round trip energy efficiency of Zn-air batteries, their reversibility is mainly limited by the Zn anode, which has received far less attention.

From the above, it is evident that improvements in battery technologies are needed. Batteries can be characterized by the specific materials that make up each of the three main components of the anode, cathode and electrolyte. Selection of these components can yield batteries having specific voltage and discharge characteristics that can be optimized for particular applications.

Although stable cycling of Zn anodes in mild acidic electrolyte has been demonstrated, an alkaline electrolyte is ideal for zinc-air batteries because an oxygen cathode has minimum overpotential in alkaline electrolyte. However, a deeply rechargeable (>50% DOD) Zn anode in lean alkaline electrolyte (mass ratio of electrolyte to electrode <100:1) is still lacking due to multiple challenges.

A particularly rich avenue for increased benefits relates to improvements in rechargeability and specific capacities by limiting passivation and dissolution issues related to the choices of anode, cathode and electrolyte. While Zn vs. Li is discussed above, various chemistries can provide the improvements being sought. An exemplary electrode would include anodic core elements comprising core material, the core material having a passivation interface size and an intrinsic dissolution rate, and a conformal shell coating on an outer surface of the anodic core elements forming core/shell structures, wherein the anodic core elements comprise a feature size smaller than the core material passivation interface size, and wherein a dissolution rate of the core material from the core/shell structures is less than the intrinsic dissolution rate. Further, the shell should be made of material that has low activity towards the HER of reduction of water to hydrogen as a side reaction.

### BRIEF SUMMARY OF THE DISCLOSURE

In exemplary embodiments of the present invention, core/shell nanoscale structures provide deeply rechargeable anodes, and can overcome intrinsic limitations of other battery materials that involve soluble intermediates or insulating discharge products.

Starting with a nanomaterial with high-surface area could avoid the passivation layer problem. However, the dissolution problem is more severe. On the other hand, a nonporous coating could prevent ZnO dissolution, but would also block the OH⁻ transport necessary for the zinc redox reaction to occur. Therefore, simultaneously solving the dilemmas of passivation and dissolution are an answer.

While specific exemplary embodiments disclose particular metals, coatings, thicknesses, the present invention encompasses a myriad of core material/coatings that with optimization of the core and shell materials, from aspects of pore size, porosity, and surface charge, leads to various improvements of anode performance and stability. Many materials with controlled ion-sieving and HER suppressing properties are contemplated herein. The design principles can be applied to other morphologies (e.g. particles) of starting materials for large scale production. The mechanistic understanding and design principles cover many types of rechargeable high-energy aqueous batteries.

The concept of separating ions and molecules by size using selective membranes is known. A variety of materials such as graphene, graphene oxide, polymer, and metal carbide membranes with a controllable pore size and permeability have been demonstrated to have ion-sieving capabilities in various applications. Applying the ion-sieving concept to Zn anode, to confine larger zincate ions and allow smaller hydroxide ions to permeate, can limit/prevent ZnO dissolution and electrode shape change.

In an exemplary embodiment of the present invention, an electrode comprises anodic core elements comprising a core material of zinc, the core material having a core material passivation interface size of approximately 2 μm, a core material intrinsic dissolution rate, and a core material hydrogen evolution reaction (HER) rate.

The electrode further comprises a conformal shell coating of TiO₂ on an outer surface of the anodic core elements, thus forming ZnO@TiO₂ core/shell structures. The electrode can be a sub-micron zinc anode sealed with an ion-sieving coating that suppresses hydrogen evolution reaction. ZnO nanorods are coated with TiO₂, which overcomes passivation, dissolution, and hydrogen evolution issues simultaneously. It achieves superior reversible deep cycling performance with a high discharge capacity of approximately 616 mAh/g and Coulombic efficiency of approximately 93.5% when cycled with 100% depth of discharge at lean electrolyte. It can also deeply cycle ˜350 times in a beaker cell.

In an exemplary embodiment, the electrode further comprises a conformal shell coating of TiNₓO_{y} on an outer surface of the anodic core elements, thus forming ZnO@TiNₓO_{y} core/shell structures. The anodic core elements are nanoscale, so as to comprise a feature size smaller than the zinc passivation interface size. The anodic core elements can be nanorods with a diameter of less than approximately 2 μm, and more preferably less than approximately 500 nm.

The dissolution rate of zinc from the core/shell structures is less than the Zn intrinsic dissolution rate, as the relatively thin (having a thickness of less than approximately 10 nm) and conformal TiNₓO_{y} coating mitigates Zn dissolution in an alkaline electrolyte.

The ZnO@TiNₓO_{y} core/shell nanorod structures provide a deeply rechargeable Zn anode. The small diameter of ZnO limits to fully prevents passivation, and allows near to full utilization of active materials, while the relatively thin and conformal TiNₓO_{y} coating not only mitigates the Zn dissolution, but also mechanically maintains the morphology of the nanostructures, and delivers electrons to the nanorods. As a result, the ZnO@TiNₓO_{y} core/shell nanorod anode achieves superior specific capacity and cycle life compared with bulk Zn foil and uncoated ZnO nanorod anodes.

The discharge capacity of the ZnO@TiNₓO_{y} core/shell nanorod anode is approximately twice as large as that of an uncoated ZnO nanorod anode. It was surprisingly found that the ZnO@TiNₓO_{y} nanorod anode achieves a much higher specific discharge capacity of approximately 508 mAh/g than that of conventional zinc anodes. Further, it can deeply cycle greater than approximately 640 times (over 64 days) in a beaker cell, and can deliver excellent long-term electrochemical performance (more than approximately 7500 cycles) when cycled under start-stop conditions.

In another exemplary embodiment of the present invention, an electrode comprises anodic core primary elements comprising a core material of zinc, the core material having a core material passivation interface size of approximately 2 μm, a core material intrinsic dissolution rate, and a core material HER rate.

The electrode further comprises a conformal shell coating of carbon on an outer surface of the anodic core primary elements, thus forming ZnO@C core/shell structures. The anodic core primary elements are nanoscale, so as to comprise a feature size smaller than the zinc passivation interface size. The anodic core primary elements can be particles with a diameter of less than approximately 2 μm, and more preferably are nanoparticles (NPs) with a diameter of less than approximately 100 nm.

The dissolution rate of zinc from the core/shell structures is less than the Zn intrinsic dissolution rate, as the relatively thin (having a thickness of less than approximately 15 nm) and conformal amorphous, microporous, and conductive carbon coating mitigates Zn dissolution in an alkaline electrolyte.

An assembly (secondary cluster) of these core/shell structures form Zn-pome microspheres (pomegranate-like nanoporous carbon-coated ZnO clusters). Each secondary cluster/Zn-pome microsphere can be approximately 6 mm in size and comprise on the order of approximately 10⁵ ZnO NPs individually encapsulated by an amorphous, microporous, and conductive carbon shell that slows down the dissolution of zincate intermediate species during cycling. The shell further suppresses zinc dissolution by decreasing the electrode-electrolyte contact area.

The nanoscale, pomegranate-structured Zn anode can be fabricated via a bottom-up microemulsion approach. As disclosed, the in the Zn-pome, primary ZnO NPs assemble into secondary clusters after which they are individually encapsulated by a conductive, microporous carbon framework. The small size of ZnO NPs overcomes the problematic issue of passivation, whereas the secondary structure and ion-sieving carbon shell mitigates the dissolution problem.

Inductively coupled plasma (ICP) analysis confirms that Zn dissolution from the Zn-pome anode is effectively suppressed, leading to a considerably prolonged cycle life compared to that of a conventional ZnO anode in an alkaline aqueous electrolyte. The Zn-pome anode maintains its capacity after long resting. This performance is achieved in harsh yet practical conditions: a limited amount of electrolyte, sealed coin cells, and approximately 100% DOD.

In another exemplary embodiment of the present invention, an electrode comprises anodic core primary elements comprising a core material of zinc, the core material having a core material passivation interface size of approximately 2 μm, a core material intrinsic dissolution rate, and a core material HER rate.

The electrode further comprises a conformal shell coating of an ion-sieving carbon on an outer surface of the anodic core elements, thus forming ZnO@C core/shell structures. The anodic core primary elements are nanoscale, so as to comprise a feature size smaller than the zinc passivation interface size. The anodic core primary elements can be particles with a diameter of less than approximately 2 μm, and more preferably are nanoparticles (NPs) with a diameter of less than approximately 100 nm.

The dissolution rate of zinc from the core/shell structures is less than the Zn intrinsic dissolution rate, as the relatively thin (having a thickness of less than approximately 30 nm) and conformal ion-sieving carbon coating mitigates Zn dissolution in an alkaline electrolyte.

The ion-sieving carbon nanoshell coated ZnO nanoparticle anode can be synthesized in a scalable way with controllable shell thickness. The nanosized ZnO prevents passivation, while the microporous carbon shell slows down Zn species dissolution. Under extremely harsh testing conditions (closed cell, lean electrolyte, no ZnO saturation), this Zn anode shows significantly improved performance compared to Zn foil and bare ZnO nanoparticles. The ion-sieving nanoshell can be beneficial to other electrodes such as sulfur cathode for Li-S batteries.

In another exemplary embodiment of the present invention, an electrode comprises anodic core elements comprising core material, the core material having a core material passivation interface size, a core material intrinsic dissolution rate, and a core material hydrogen evolution reaction (HER) rate, a conformal shell coating on an outer surface of the anodic core elements forming core/shell structures, wherein the anodic core elements comprise a feature size smaller than the core material passivation interface size, wherein a dissolution rate of the core material from the core/shell structures is less than the core material intrinsic dissolution rate; and wherein the HER rate of the shell is less than the core material HER rate.

The electrode can be deeply rechargeable.

The electrode can have a DOD of greater than 50%.

The core material can be selected from the group comprising a metal, metal oxide, metal sulfide, and combinations thereof.

The core material can be selected from the group comprising Zn, Li, Na, Mg, Ca, ZnO, Li₂O, Na2O, MgO, CaO, ZnS, Li₂S, Na₂S, MgS, CaS, and combinations thereof.

The conformal shell coating can comprise a cermet. The conformal shell coating can comprise carbon.

The core/shell structures can have a specific discharge capacity of at least 70% of the theoretical limit of the specific discharge capacity of the core material.

The electrode can have a coulombic efficiency greater than about 93.5%.

The anodic core/shell structures can be formed by a deposition technique of layers of the conformal shell coating over a deposition cycling series, and wherein a morphology of the anodic core elements prior to the deposition cycling series is substantially the same as a morphology of the core/shell structures after the deposition cycling series.

The anodic core/shell structures can be formed by an atomic layer deposition (ALD) technique of layers of the conformal shell coating over an ALD cycling series, and wherein a morphology of the anodic core elements prior to the ALD cycling series is substantially the same as a morphology of the core/shell structures after the ALD cycling series.

In another exemplary embodiment of the present invention, the anodic core elements are nanorod structures, the core material comprises ZnO, and the conformal shell coating comprises TiNₓO_{y}.

The diameter of the nanorods can be less than approximately 2 μm. The diameter of the nanorods can be less than approximately 500 nm.

The conformal shell coating can have a thickness of less than 10 nm. The conformal shell coating can have a thickness of less than approximately 6 nm.

In another exemplary embodiment of the present invention, the anodic core elements are nanoparticles, the core material comprises ZnO, and the conformal shell coating comprises carbon.

The conformal shell coating can comprise an amorphous, microporous, and conductive carbon.

An assembly of core/shell structures can form Zn-pome microspheres (pomegranate-like nanoporous carbon-coated ZnO clusters). Each Zn-pome microsphere can have a diameter of approximately 6 μm. Each Zn-pome microsphere can comprise on the order of approximately 10⁵ core/shell structures.

The diameter of the nanoparticles can be less than approximately 2 μm. The diameter of the nanoparticles can be less than approximately 100 nm.

The conformal shell coating can have a thickness of less than 15 nm. The conformal shell coating can have a thickness of less than approximately 10 nm.

In another exemplary embodiment of the present invention, the anodic core elements are nanoparticles, the core material comprises ZnO, and the conformal shell coating comprises an ion-sieving carbon shell.

In another exemplary embodiment of the present invention, a rechargeable battery system comprises anodic core/shell structures comprising a ZnO core coated with a shell layer of TiNₓO_{y}, an aqueous electrolyte, and a cathode.

In another exemplary embodiment of the present invention, a rechargeable battery system comprises anodic Zn-pome microspheres each comprising a pomegranate-like assembly of individual ZnO nanoparticles coated with a shell layer of carbon, an aqueous electrolyte, and a cathode.

In another exemplary embodiment of the present invention, a rechargeable battery system comprises anodic core/shell nanoparticles comprising a ZnO core coated with a shell layer of ion-sieving carbon, an aqueous electrolyte, and a cathode.

In each of the rechargeable battery systems, the rechargeable battery system can be deeply rechargeable.

In each of the rechargeable battery systems, the rechargeable battery system can have a DOD of greater than 50%.

In each of the rechargeable battery systems, the cathode can comprise Ni(OH)₂.

In each of the rechargeable battery systems, the anodic core/shell structures can be formed by a deposition technique of the conformal shell on the core over a deposition cycling series, and wherein a morphology of the core prior to the deposition cycling series can remain substantially the same as the morphology of the core/shell structures after the deposition cycling series.

These and other objects, features and advantages of the present disclosure will become more apparent upon reading the following specification in conjunction with the accompanying description, claims and drawings.

### BRIEF DESCRIPTION OF THE DRAWINGS

The accompanying Figures, which are incorporated in and constitute a part of this specification, illustrate several aspects described below.

FIG. 1 is illustrative of typical issues of Zn anode in alkaline electrolyte and design of a high-performance Zn anode by overcoming the issues, and includes schematic diagrams of passivation (FIG. 1A) and dissolution (FIG. 1B) issues of zinc anodes. FIG. 1C is a schematic diagram of the battery-GC quantitative analysis method developed to quantitatively identify the influence of HER on Coulombic efficiency of zinc anodes by measuring the H₂ evolved in the reactor after charging/discharging the zinc anode for 1 cycle. FIG. 1D illustrates the distribution of the charged capacity on the zinc anode in a Zn—Ni battery. The capacity loss on the Zn anode is almost fully caused by HER. Thus, HER suppressing zinc anodes should possess high Coulombic efficiency.

FIGS. 2A-C present a schematic diagram (FIG. 2A), experiment setup (FIG. 2B), and reactor design (FIG. 2C) of the battery-GC quantitative analysis method used to quantitatively identify the influence of HER on Coulombic efficiency of zinc anodes. PRR: pressure reducing regulator; MFC: mass flow controller; and GC: gas chromatography.

FIGS. 3A-B include a graph (FIG. 3A) and schematic diagram (FIG. 3B) of electrode reactions happening during charging for the Zn—Ni battery system of FIGS. 1C and 2A-C.

FIG. 4 is a schematic illustration of the presently inventive HER suppressing sealed nanorod (HSSN) zinc anode design principle: sealed sub-micron-sized anodes with an HER suppressing ion-sieving coating to overcome passivation, dissolution, and hydrogen evolution issues simultaneously in alkaline electrolytes.

FIGS. 5A-C illustrate the fabrication of an HSSN anode. Schematic diagrams and scanning electron microscopy (SEM) images of carbon paper (FIG. 5A), ZnO nanorod anode (FIG. 5B), and HSSN anode (FIG. 5C).

FIGS. 6A-C are SEM images of an uncoated ZnO nanorod anode with a mass loading of ZnO nanorods ranging from 0.5 mg/cm² to 5.5 mg/cm².

FIG. 7A is a schematic diagram of TiO₂ coating process. FIGS. 7B-C are SEM images of ZnO nanorods before (FIG. 7B) and after TiO₂ coating (FIG. 7C). FIG. 7D is a SEM image and elemental mappings of the present HSSN anode.

FIGS. 8-11 are a characterization of a single ZnO@TiO₂ nanorod collected from the present HSSN anode. FIGS. 8A-8C include a scanning transmission electron microscopy (STEM) image and elemental mappings of a ZnO@TiO₂ nanorod.

FIGS. 9A-B shows spatial distributions of Zn and Ti elements and energy-dispersive X-ray (EDX) spectroscopies in the core and shell regions.

FIG. 10 is a transmission electron microscopy (TEM) diffraction image of a ZnO@TiO₂ nanorod, showing the diffraction pattern of hexagonal ZnO. A [002]; B [110]; C [112].

FIG. 11 is a TEM image of a ZnO@TiO₂ nanorod, showing the thickness (˜30 nm) of a TiO₂ coating.

FIGS. 12A-C are varying magnitude SEM images of the present HSSN anode after etching ZnO away.

FIG. 13 presents ICP results showing dissolved Zn concentration after soaking the present HSSN and uncoated ZnO anodes in 4M KOH solution. 90% ZnO dissolution is suppressed in the HSSN anode, which means that the TiO₂ coating effectively blocks zincate ions.

FIGS. 14A-B are varying magnitude SEM images and elemental mappings of the uncoated ZnO (FIG. 14A) and HSSN (FIG. 14B) anodes after soaking in 4M KOH solution. The reservation of Zn in the HSSN anode supports the assumption that a TiO₂ coating can effectively block zincate ions.

FIG. 15 is a graph of X-ray diffraction (XRD) patterns of uncoated ZnO and HSSN anodes before and after charging. The weak ZnO peaks of the HSSN anode after charging is from residual unreacted ZnO.

FIGS. 16-17 are SEM images before and after charging of an uncoated ZnO anode (FIG. 16) and HSSN anode (FIG. 17).

FIGS. 18-19 are SEM images of an uncoated ZnO nanorod anode (FIG. 18) and HSSN anode (FIG. 19) after five galvanostatic cycles with 25 μL electrolyte. They were cycled at ˜0.25 mA/cm² for 2 hours of charge and ˜0.25 mA/cm² discharge to 1.5V. The mass loadings of ZnO nanorods on both anodes are ˜3.3 mg/cm².

FIG. 20 is a STEM image of a ZnO@TiO₂ nanorod after charging.

FIG. 21 is a STEM image and elemental mappings of a ZnO@TiO₂ nanorod after charging. The same anode sample was used in FIGS. 17 and 20-21.

FIG. 22 is a SEM image and elemental mappings of the present HSSN anode after charge.

FIGS. 23A-B are graphs illustrating the Brunauer-Emmett-Teller (BET) pore width distribution (FIG. 23A) and surface areas (FIG. 23B) of uncoated ZnO and HSSN anodes. After TiO₂ coating, nanopores are measured which indicates that TiO₂ coating is nanoporous.

FIG. 24 is an X-ray photoelectron spectroscopy (XPS) survey of the ZnO@TiNₓO_{y} anode. The atomic ratio of O to N is ˜6.66 in the TiNₓO_{y} coating.

FIG. 25 is a schematic diagram of a three-electrode cell in 4M KOH electrolyte with a TiO₂ or TiNₓO_{y} electrode as the working electrode, an Hg/HgO electrode as the reference electrode, and Pt foil as the counter electrode.

FIG. 26 is a schematic of TiN ALD recipe.

FIG. 27 shows IR-corrected polarization curves of TiNₓO_{y} and TiO₂ electrodes. At any fixed potential, the hydrogen evolution on TiNₓO_{y} electrode is severer than TiO₂ electrode. Scan rate: 2 mV/s.

FIG. 28 shows IR-corrected polarization curves of a CP substrate, and TiNₓO_{y} and TiO₂ electrodes. HER can be suppressed with the existence of TiO₂. CP: carbon paper. Scan rate: 2 mV/s.

FIG. 29A is an XPS survey spectra of the TiO₂ coating. FIG. 29B is an XPS survey spectra of the TiNₓO_{y} coating. FIG. 29C is a table that shows sheet resistance and resistivity of TiNₓO_{y} and TiO₂ coatings measured using a four-point probe system.

FIG. 30A shows basic models of TiO₂, TiNₓO_{y}-1 and TiNₓO_{y}-2 clusters, and FIG. 30B an adsorption free energy diagram of each cluster.

FIG. 31A shows basic models of TiO₂, TiNₓO_{y}-3 and TiNₓO_{y}-4 clusters, and FIG. 31B an adsorption free energy diagram of each cluster.

FIG. 32 is a table of a summary of simulated energy of clusters (M) and H-adsorbed clusters (M-H), binding energy, and free energy. Atoms in clusters: smallest “atom”, N; larger, H; larger still, Ti; and largest, O.

FIG. 33 illustrates ICP results showing dissolved Zn concentration after soaking the uncoated ZnO, HSSN and ZnO@TiNₓO_{y} anodes in 4M KOH solution. 90% ZnO dissolution is suppressed in the HSSN and ZnO@TiNₓO_{y} anodes. This shows HSSN and ZnO@TiNₓO_{y} anodes have very similar ion-sieving capability.

FIG. 34 contains SEM images and elemental mappings of the ZnO@TiNₓO_{y} anode after soaking in 4M KOH solution. The reservation of Zn in the ZnO@TiNₓO_{y} anode supports that TiNₓO_{y} coating can effectively block zincate ions.

FIG. 35A shows cell components of a pouch cell, and FIG. 35B the assembled pouch cell. The separator has a 1.5 cm diameter. The anode has a 1 cm diameter.

FIG. 36 illustrates voltage profiles of Zn—Ni batteries with HSSN and ZnO@TiNₓO_{y} as anodes. The Coulombic efficiency of the present HSSN anode is higher with better HER suppressing capability.

FIG. 37A shows cycling performance of the ZnO@TiNₓO_{y} and HSSN anodes in lean electrolyte at 100% DOD. FIG. 37B shows cycling performance of the HSSN and ZnO@TiNₓO_{y} anodes at various C rates. State of charge: 20%.

FIGS. 38A-B are graphs illustrating BET pore width distribution (FIG. 38A) and surface areas (FIG. 38B) of HSSN and ZnO@TiNₓO_{y} anodes.

FIG. 39 is a table showing a comparison of Coulombic efficiency of the present HSSN anode with conventional zinc-based anodes (100% DOD) in alkaline electrolytes.

FIG. 40 shows cycling performance of the present HSSN anode in a lean electrolyte at 40% DOD

FIG. 41 illustrates charge-discharge profiles of the present HSSN anode in a lean electrolyte at 40% DOD.

FIG. 42 are CV curves of CP-TiO₂ and HSSN electrodes. There is no capacity contribution from TiO₂ during the electrochemical reaction. Scan rate: 10 mV/s.

FIG. 43 are optic microscope images of the HSSN anode before and after battery failure.

FIG. 44 shows cycling performance of the present HSSN anode in a beaker cell with a large amount of electrolyte at 100% DOD.

FIGS. 45A-B are voltage profiles (from cycle 50^{th} to 70^{th}) of the HSSN anode cycled in a lean electrolyte at 40% DOD (FIG. 45A) and a beaker cell with a large amount of electrolyte at 100% DOD (FIG. 45B).

FIG. 46 is a table comparing the present HSSN anode with conventional zinc-based anodes in aspects of electrolyte-to-discharge-capacity (E/DC) ratio and Coulombic efficiency in alkaline electrolyte. The DOD of Anode No. 0 is 40%. The DOD of the remaining Anode Nos. 1-22 are 100%.

FIG. 47 illustrates via graph a comparison of the HSSN anode and conventional anodes (with 100% DOD) in aspects of E/DC ratio and Coulombic efficiency.

FIG. 48 is another schematic similar to FIG. 1A of morphological changes of zinc electrode during electrochemical cycling, where Zn foil of the prior art shows very low utilization (<1%) because of the ZnO passivation layer. The critical passivation size is ˜2 μm, as shown above the foil.

FIG. 49 is a graph of 1 cycle discharge and charge test for Zn foil under 10 mA, showing that Zn foil can only deliver ˜1.7 mAh capacity (1% utilization) and charge capacity is only ⅕^{th} of discharge capacity.

FIG. 50 is an SEM image of ZnO passivation layer on Zn mesh (Dexmet), formed by discharging Zn mesh under 1 mA with a 10 μL electrolyte. The separator used was Celgard 3501.

FIG. 51 is a schematic of morphological changes of zinc electrode during electrochemical cycling, where the feature size of an uncoated ZnO nanorod of the prior art is smaller than the critical passivation size, however, the large electrode-electrolyte surface area accelerates anode dissolution and promotes electrode shape change.

FIG. 52 is a schematic of morphological changes of zinc electrode during electrochemical cycling, where the shape of the present ZnO@TiNₓO_{y} nanorod anode retains during cycling with the inventive sealed nanorod structure.

FIG. 53 is a schematic of a TiN ALD recipe.

FIGS. 54A-54C are pictures of a beaker cell (FIG. 54A), a coin cell (FIG. 54B) and scalability of Zn—Ni single coin cell (FIG. 54C). Top and bottom cases have an approximate 2 cm diameter. The separator has an approximate 1.5 cm diameter. The working electrode (WE) has an approximate 1 cm diameter.

FIG. 55 is an optical picture of a pouch cell.

FIG. 56 is a schematic of the fabrication process for the present ZnO@TiNₓO_{y} core/shell nanorod anode.

FIG. 57 is a low magnification SEM image of a ZnO nanorod anode.

FIGS. 58A-58C are high magnification SEM images of three ZnO nanorod anodes with different mass loadings.

FIG. 59 is an SEM image of a ZnO@TiNₓO_{y} nanorod anode.

FIG. 60 is a TEM image of a ZnO@TiNₓO_{y} nanorod.

FIG. 61 is a high resolution transmission electron microscopy (HRTEM) image of a ZnO@100TiNₓO_{y} nanorod, showing the thickness (˜6.1 nm) of the TiNₓO_{y} coating.

FIG. 62 is an HRTEM image of a ZnO@TiNₓO_{y} nanorod, showing the lattice of ZnO, [002], d≈0.26 nm.

FIG. 63 is an electron diffraction pattern of a ZnO@TiNₓO_{y} nanorod, showing the diffraction pattern of ZnO. A [002]; B [200]; C [202].

FIG. 64 is an SEM image and elemental mapping of ZnO@TiNₓO_{y} nanorods.

FIGS. 65-67 are graphs of an XPS survey of ZnO nanorod and ZnO@TiNₓO_{y} nanorod anodes (FIG. 65); a high-resolution XPS spectra of Zn 2 p peaks (FIG. 66); and a high-resolution XPS spectra of Ti 2 p peaks (FIG. 67). The samples shown in FIGS. 59-67 are all deposited by ALD for 100 cycles.

FIGS. 68-69 are XPS survey spectra (FIG. 68) and high-resolution Zn 2 p and Ti 2 p spectra (FIG. 69) of a ZnO@TiNₓO_{y} nanorod anode with 200 cycles ALD.

FIG. 70 illustrates ICP results and an image (inset) showing dissolved Zn concentration after soaking the ZnO@TiNₓO_{y} and uncoated ZnO anodes in 4M KOH solution.

FIGS. 71-72 are SEM images of an uncoated ZnO nanorod anode (FIG. 71) and a ZnO@TiNₓO_{y} nanorod anode (FIG. 72) before and after a 2 hour charge with a 25 μL electrolyte.

FIG. 74 are SEM images of approximately 0.5 mg/cm² ZnO@TiNₓO_{y} nanorod anode with 200 cycles ALD after a 1 hour constant current charge at 1 C rate with a 25 μL electrolyte. Tin was used as anode current collector.

FIG. 74 is an SEM image and elemental mapping of a ZnO@TiNₓO_{y} nanorod anode after a 2 hour charge.

FIG. 75 is an TEM image of a ZnO@TiNₓO_{y} nanorod anode after 2 hour charge. FIGS. 72 and 74-75 are from the same anode sample with 100 cycles ALD.

FIG. 76 are XRD results of a ZnO nanorod and a ZnO@TiNₓO_{y} nanorod anode before and after charge. The weak ZnO peaks of ZnO@TiNₓO_{y} nanorod anode with 200 cycles ALD after charge is from residual unreacted ZnO. Tin foils were used as anode current collectors.

FIG. 77 is an electrochemical impedance spectroscopy (EIS) result and equivalent circuit of an uncoated ZnO anode and a ZnO@TiNₓO_{y} nanorod anode. Z_{w}: Warburg impedance; R_{ct}: charge-transfer resistance; CPE: double layer capacity; R_{c}: total ohmic resistance.

FIGS. 78-80 are SEM images of a pristine ZnO@TiNₓO_{y} nanorod anode with 200 cycles ALD (FIG. 78), after a 3 hour constant current charge at 0.33 C with a 25 μL electrolyte (FIG. 79), and after further constant current discharge at 0.33 C (0.7 hours) to 1.5 V with a 25 μL electrolyte (FIG. 80). All SEM images are from same sample with a mass density of ˜1.7 mg/cm². This result indicates that there is almost no shape change during the charge and discharge step.

FIGS. 81-82 are SEM images of a pristine uncoated ZnO nanorod anode (FIG. 81), and after a 3 hour constant current charge at 0.33 C with a 25 μL electrolyte (FIG. 82). All SEM images are from same sample with a mass density of ˜1.7 mg/cm². Some nanorods were detached from the beginning as shown in FIG. 81, due to external mechanical force during transfer. After charge, most ZnO nanorods grown on the top layer of carbon fibers detached. Because of the small amount of electrolyte, the ZnO nanorods grown on the inner carbon fibers were not in contact with electrolyte in the first charge, and remained.

FIG. 83 is a schematic diagram of beaker cell and coin cell.

FIG. 84 shows cycling performance of pure current collector in the beaker cell and coin cell. Real: count all the zinc in the electrolyte. Pseudo: calculation without counting zinc in the electrolyte. One dot every four data points.

FIG. 85 illustrates discharge capacity for the first 32 galvanostatic cycles of an uncoated ZnO nanorod and the ZnO@TiNₓO_{y} nanorod anodes with ˜2.1 mg/cm² at 0.5 C rate in a coin cell with ZnO-free electrolyte. 50 μL electrolyte was dropped onto a separator and 10 μL electrolyte was dropped onto cathode. Inset: optical image of a coin cell.

FIG. 86 is a graph of the charge voltage profiles of the ZnO and ZnO@TiNₓO_{y} anodes.

FIG. 86 illustrates discharge capacity retention of uncoated ZnO nanorod and ZnO@TiNₓO_{y} nanorod anodes with ˜1.5 mg/cm² at 0.25 C rate in coin cells. 25 μL electrolyte was dropped onto separator. The cut-off voltages are approximately ˜1.5/1.9V. The maximum discharge capacity (corresponding to approximately 100%) of uncoated ZnO nanorod and ZnO@TiNₓO_{y} nanorod anodes are approximately 235.2 mAh/g and approximately 153.5 mAh/g, respectively.

FIG. 88 shows cycling performance of ˜1.1 mg/cm² ZnO@TiNₓO_{y} nanorod anodes in pouch cells with ZnO saturated and ZnO-free electrolytes, respectively. They were cycled at 1 C for charge and 5 C for discharge with approximately 1.4/2V cut-off voltages.

FIG. 89 is a comparison of specific discharge capacity between the present anode and previously reported anodes. Zinc in the electrode and electrolyte are both counted.

FIG. 90 shows cycling performance of the ZnO@TiNₓO_{y} nanorod anode (˜2 mg/cm²) with 200 cycles with ALD at 0.5 C charge and 2 C discharge rates in beaker cell with 10 mL ZnO saturated 4M KOH electrolyte. The cut-off voltages are approximately 1.4/2 V. One dot every five data points.

FIG. 91 is a cyclic voltammogram (CV) for ZnO@TiNₓO_{y} anode in a coin cell at approximately 0.1 mV/s scan rate. The CV was done using two electrodes with ZnO@TiNₓO_{y} anode and Ni(OH)₂ cathode in ZnO free electrolyte.

FIGS. 92-93 are CVs for ZnO@TiNₓO_{y} anodes in a pouch cell (FIG. 92) and beaker cell (FIG. 93) at an approximately 0.1 mV/s scan rate. The CV for the anode in pouch cell was done using two electrodes with ZnO@TiNₓO_{y} anode and Ni(OH)₂ cathode in ZnO saturated electrolyte. The CV for the anode in beaker cell was done using three electrodes with ZnO@TiNₓO_{y} anode, Hg/HgO reference electrode and graphite counter electrode in ZnO saturated 4M KOH electrolyte.

FIG. 94 is a current density profile as cycled under start-stop conditions in coin cells.

FIG. 95 shows long-term discharge capacity retention of Zn foil and a ZnO@TiNₓO_{y} nanorod anode as cycled under start-stop conditions with 100 μL electrolyte. The Zn foil with approximately 0.02% DOD and the ZnO@TiNₓO_{y} nanorod anode with approximately 1% DOD were cycled at the same current density, which is shown in FIG. 94. Tin foils were used as anode current collectors. Cells were cycled between approximately 0 and 2 V.

FIG. 96 are voltage profiles of a ZnO@TiNₓO_{y} nanorod anode of the 2000^{th} and 4000^{th} cycles under start-stop conditions.

FIGS. 97-98 are photos of cells, with a ZnO@TiNₓO_{y} nanorod anode (FIG. 97) and Zn foil (FIG. 98) as anode respectively, after long-term start-stop conditions at the same current density (shown in FIG. 94).

FIG. 99 shows the discharge capacity of a ZnO@TiNₓO_{y} nanorod anode under rate test conditions, showing electrochemical stability at different rate after several activation cycles.

FIG. 100A illustrates ZnO NPs with fast dissolution rate in alkaline aqueous solution; (FIG. 100B) illustrates ZnO NPs coated with carbon; (FIG. 100C) illustrates the present Zn-pomegranate in which carbon filled into the free space of ZnO clusters plays an important role in ion sieving, conductivity, and structure stabilization of the electrode; and (FIG. 100D) shows the calculated surface area in contact with electrolyte and the number of primary nanoparticles in one Zn pomegranate cluster versus its diameter. The smaller the surface contact with the electrolyte, the lower the capacity fading.

FIG. 101 is a cross-sectional SEM image of Zn mesh with a ZnO passivation layer formed on it after discharging the Zn mesh under 1 mA with a 100 μL electrolyte comprising 2M KF, 2M K₂CO₃ and 4M KOH. The passivation layer is approximately 2 μm.

FIG. 102 illustrates the synthesis of a Zn-pome. FIG. 102A shows the Zn-pome were prepared by a bottom-up microemulsion approach. FIG. 102B is a picture of ZnO NPs. FIG. 102C is a picture and FIG. 102F is a SEM image of ZnO clusters collected from centrifugation at approximately 1500 rpm for 5 minutes. The size is not uniform. FIG. 102D is a picture and FIG. 102G is a SEM image of ZnO clusters obtained by first centrifuging at 400 rpm for 1 minute to remove large clusters, and then centrifuging at approximately 1500 rpm for 5 minutes. FIG. 102E is a picture and FIG. 102H is a SEM image of Zn-pome synthesized using Zn clusters shown in FIGS. 102D and 102G.

FIGS. 103A-C are SEM images of clusters of ZnO nanoparticles assembled via a microemulsion approach. FIGS. 103D-F are SEM images of Zn-pome (nano-porous carbon-coated ZnO cluster). FIG. 103G is a TEM image of Zn-pome. FIG. 103H is a TEM image of the carbon framework of Zn-pome after etching away ZnO in 1M HC1 for 24 hours. FIG. 103I is a cross-sectional SEM image of one Zn-pome microparticle obtained by focused ion beam (FIB) analysis.

FIG. 104A is a TEM image of a Zn-pome. FIG. 104B is a schematic of etching ZnO. FIGS. 104C-F are TEM images of the Zn-pome after etching away ZnO in 1M HCl.

FIGS. 105-106 are FIB milling of Zn-pome. FIG. 105 is a top-view image of Zn-pome after FIB milling. FIG. 106 is a cross-section image of Zn-pome after FIB milling.

FIG. 107A illustrates XRD patterns and FIG. 107B XPS spectra of ZnO NPs, ZnO@C NPs and Zn-pome. FIG. 107C is a high-resolution XPS spectra of ZnO NPs and Zn-pome. FIG. 107D is a TGA weight loss curve and FIG. 107E is a BET pore size distribution of Zn-pome. FIG. 107F shows dissolved and undissolved portions of zinc in 4M KOH electrolyte for ZnO NPs, ZnO@C NPs and Zn-pome; embedded pictures show the electron microscopy images of ZnO NPs, ZnO@C NPs and Zn-pome.

FIG. 108 includes a picture of CR2032 coin cell cases (left) and a schematic of coin cell components and their arrangement used (right).

FIG. 109A is a graph of specific capacity of ZnO NPs and Zn-pome. FIG. 109B is voltage profiles of Zn-pome/Ni(OH)₂. FIG. 109C is a graph of specific capacity of ZnO NPs/Ni(OH)₂ and Zn-pome/Ni(OH)₂ at a 5 C discharge rate. FIG. 109D illustrates testing of self-discharge of Zn-pome cell cycling at 0.5 C for one cycle, resting for 24 hours, then cycling at 1 C. FIG. 109E is a SEM image of Zn-pome anode before cycling (FIGS. 109F and G) and after two cycles.

FIG. 110A is a graph of specific capacity of Zn-pome, ZnO NPs@C and ZnO NPs. FIG. 110B shows additional battery cycling data of bare ZnO and Zn-pome anodes (1 C rate).

FIG. 111 illustrates the performance of bare ZnO and Zn-pome anodes at 5 C discharge rate.

FIG. 112 presents the cycle performance of bare ZnO and Zn-pome anodes (charged at 1 C, discharged at 5 C), after resting for 24 hours followed by the first cycle at 0.5 C.

FIGS. 113A-F are SEM images of Zn-pome anode after cycling at 1 C. FIGS. 113A-D after cycling 10 cycles. FIGS. 113E-L after cycling 20 cycles.

FIG. 114A is a SEM image of commercial ZnO nanoparticles with a short rod-like shape. FIG. 114B is a TEM image of a ZnO@C nanoparticle. FIG. 114C are TGA results used to determine the carbon content in ZnO@C nanoparticles. FIG. 114D is SEM image of carbon-coated ZnO nanoparticles (ZnO@C). FIG. 114E is a TEM image of HCl etched ZnO@C particles, resulting in a uniform hollow carbon nanoshell. FIG. 114F are XRD results for bare ZnO and ZnO@C nanoparticles.

FIG. 115 is a SEM image of nanoparticles ZnO@C at 5.0 kV. The ZnO@C core-shell structure is visible.

FIG. 116 contains SEM images of ZnO@C particles with different carbon shell thickness, synthesized using different mass of dopamine hydrochloride. The mass of dopamine hydrochloride is 100 mg (1:1), 200 mg (2:1), and 300 mg (3:1).

FIG. 117 shows TGA data of ZnO@polydopamine nanoparticles under an Ar environment. Above about 680° C., there is a dramatic sample weight loss, suggesting that ZnO gets reduced by carbon and escapes from the carbon shell.

FIG. 118A illustrates the structure and size of hydroxide ion and zincate ion calculated by DFT. FIG. 118B is XPS spectra for bare ZnO and ZnO@C nanoparticles. FIG. 118C is XPS high-resolution Zn spectra for bare ZnO and ZnO@C nanoparticles. FIG. 118D is a graph of N₂ adsorption/desorption isotherms of ZnO and ZnO@C nanoparticles. FIG. 118E is a graph of BET pore width distribution of ZnO and ZnO@C nanoparticles. FIG. 118F is a graph of ICP-AES quantification of ZnO dissolution in KOH electrolyte from bare ZnO and ZnO@C nanoparticles for 5 minutes, 1 day, and 10 days. Bare ZnO dissolves much faster than ZnO@C.

FIG. 119 illustrates specific capacity and Coulombic efficiency of bare ZnO (1.03 mg), ZnO@C (0.94 mg), and bulk Zn foil anodes during discharge process, the inset shows a typical 2032 coin cell fabricated during the experiment.

FIG. 120 is a second set of cycling data of bare ZnO and ZnO@C anodes. The mass loading of the bare ZnO and ZnO@C is ˜0.941 mg and ˜0.98 mg. The cycling performance is similar to the data presented in FIG. 119.

FIG. 121 is a comparison of voltage profile between bare ZnO and ZnO@C for the first charging process, ZnO@C particles show a lower overpotential.

FIG. 122 is a comparison of voltage profile between bare ZnO and ZnO@C for all the cycles, ZnO@C particles show a lower overpotential for every cycle.

FIG. 123 shows voltage profiles of the cell with ZnO@C anode at 1^{st}, 10^{th}, 20^{th}, 30^{th}, 40^{th} cycles.

FIG. 124A is a SEM image of bare ZnO anode before cycling. FIG. 124B is a SEM image of bare ZnO anode after three cycles, showing a dramatic shape change. Pores are indicated by yellow arrows. FIG. 124C is a SEM image of ZnO@C anode before cycling. FIG. 124D is a SEM image of ZnO@C anode after three cycles, the nanoparticles maintained a spherical shape as before cycling.

FIG. 125 is a TEM image of a ZnO@C particle after charging, the active material is still well confined inside the nanoshell.

FIG. 126 illustrates the performance of ZnO@C batteries with different thickness of nanoshell coating. The mass of active material is ˜1mg and the batteries are tested at 1 C rate and 100% DOD. ZnO@C 2:1 shown in the main text demonstrates superior performance.

FIG. 127 presents the Coulombic efficiency in a ZnO@C pouch cell with ZnO saturated electrolyte at 1 C and 100% DOD.

FIG. 128 presents the Coulombic efficiency of a ZnO@C pouch cell with >95% Coulombic efficiency and ˜100% retention for 500 cycles, with an actual rate of 12 C.

### DETAILED DESCRIPTION OF THE DISCLOSURE

Although preferred exemplary embodiments of the disclosure are explained in detail, it is to be understood that other exemplary embodiments are contemplated. Accordingly, it is not intended that the disclosure is limited in its scope to the details of construction and arrangement of components set forth in the following description or illustrated in the drawings. The disclosure is capable of other exemplary embodiments and of being practiced or carried out in various ways. Also, in describing the preferred exemplary embodiments, specific terminology will be resorted to for the sake of clarity.

As used in the specification and the appended claims, the singular forms “a,” “an” and “the” include plural referents unless the context clearly dictates otherwise.

Also, in describing the preferred exemplary embodiments, terminology will be resorted to for the sake of clarity. It is intended that each term contemplates its broadest meaning as understood by those skilled in the art and includes all technical equivalents which operate in a similar manner to accomplish a similar purpose.

Ranges can be expressed herein as from “about” or “approximately” one particular value and/or to “about” or “approximately” another particular value. When such a range is expressed, another exemplary embodiment includes from the one particular value and/or to the other particular value.

Using “comprising” or “including” or like terms means that at least the named compound, element, particle, or method step is present in the composition or article or method, but does not exclude the presence of other compounds, materials, particles, method steps, even if the other such compounds, material, particles, method steps have the same function as what is named.

Mention of one or more method steps does not preclude the presence of additional method steps or intervening method steps between those steps expressly identified. Similarly, it is also to be understood that the mention of one or more components in a device or system does not preclude the presence of additional components or intervening components between those components expressly identified.

Exemplary embodiments of the present invention comprise innovative components of a deeply rechargeable battery system, and an innovative system and method of rechargeable batteries. A core/shell nanoscale structure provides deeply rechargeable anodes that overcome intrinsic limitations of conventional battery materials that involve soluble intermediates or insulating discharge products. The present invention simultaneously overcomes the dilemmas of passivation and dissolution. An ion-sieving concept is applied to a Zn anode that confines larger zincate ions and allows smaller hydroxide ions to permeate, can limit/prevent ZnO dissolution and electrode shape change.

Examples of the present invention include sealing ZnO nanorods for deeply rechargeable high-energy aqueous battery anodes, a deeply rechargeable zinc anode with pomegranate-inspired nanostructure for high-energy aqueous batteries, ion-sieving carbon nanoshells for deeply rechargeable Zn-based aqueous batteries, and a deeply rechargeable and hydrogen-evolution-suppressing zinc anode in alkaline aqueous electrolyte.

### A Deeply Rechargeable and Hydrogen-Evolution-Suppressing Zinc Anode in Alkaline Aqueous Electrolyte

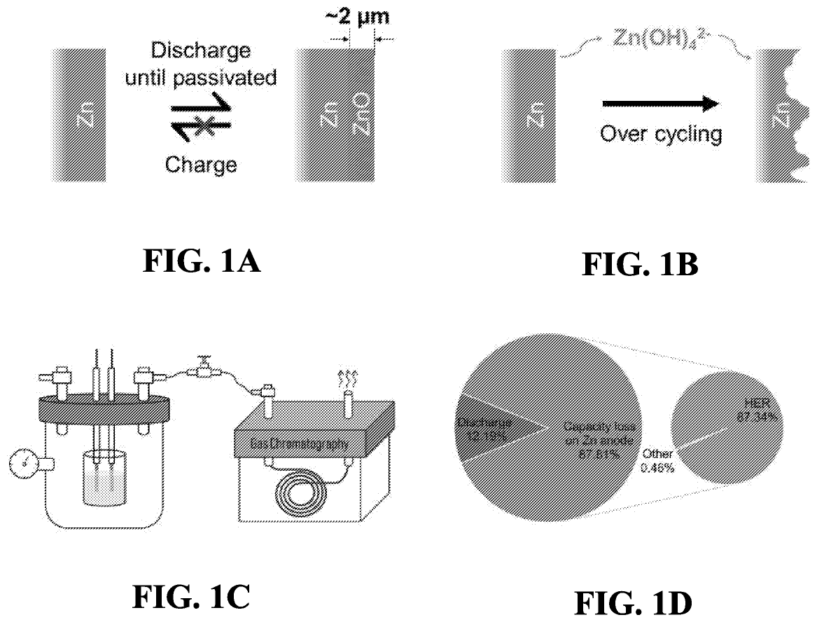

FIG. 1A is illustrative of the passivation issue, where FIG. 1B is illustrative of the dissolution issue. As discussed above, these issues are due to the following processes: (i) the insulating discharge product ZnO passivates the surface of zinc anodes, preventing the latter from further discharging or recharging back to metallic zinc, and (ii) the intermediate zincate Zn(OH)₄²⁻ is soluble in alkaline electrolytes, which leads to active material loss, random ZnO precipitation on the electrode, and morphology change of the electrode over cycling.

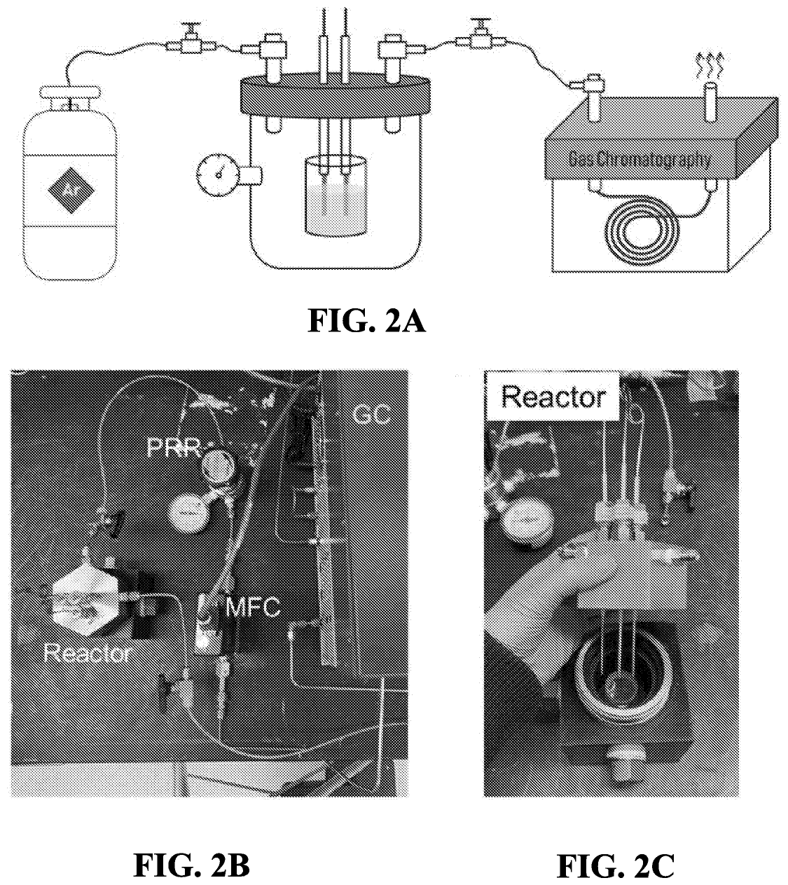

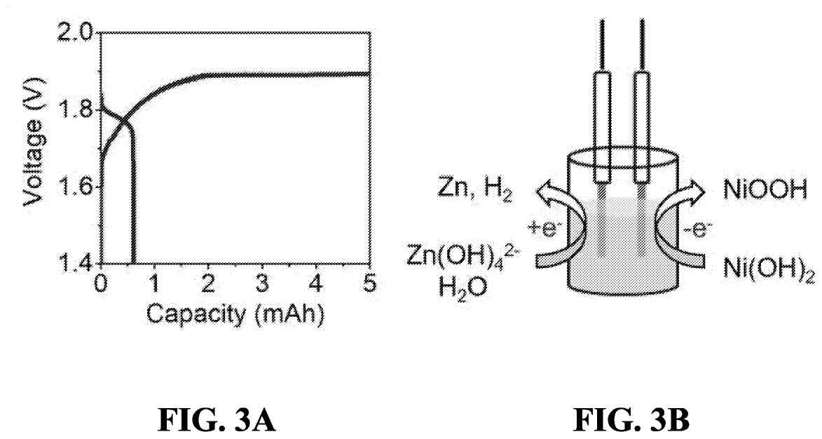

A GC quantitative analysis method (FIGS. 1C and 2A-C) is used herein to identify the influence of HER on the capacity loss of zinc anodes. This is achieved by measuring the evolved H₂ using GC after charging/discharging the zinc anode in alkaline electrolyte (ZnO-saturated 4M KOH) for one cycle (FIGS. 3A-B).

The amount of NiOOH was in excess, which could guarantee the full depletion of Zn in the discharge step. In other words, the capacity loss (charge capacity-discharge capacity) on Zn anodes is attributed to side reactions on Zn anodes. As shown in FIG. 2D, the capacity loss on the Zn anode is almost fully caused by HER (˜99.47%≈87.34%/87.81%). The other ˜0.46% of capacity loss might be caused by the oxidation of Zn through reacting with O₂. In consideration of Zn anodes, HER suppressing Zn anodes should possess high Coulombic efficiency (discharge capacity/charge capacity).

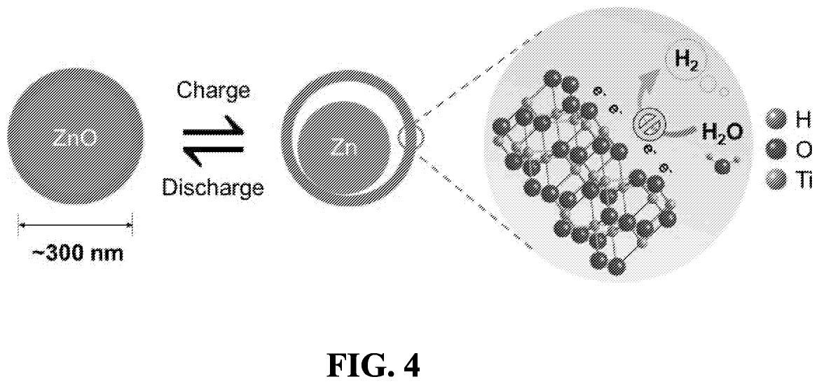

In an exemplary embodiment, the present invention comprises sealed sub-micron-sized anodes, coated with a HER suppressing ion-sieving layer to simultaneously tackle passivation, dissolution, and HER issues (FIG. 4). Such a design features at least the following advantages: (i) sub-micron-sized ZnO avoids passivation and allows complete utilization of the active materials; (ii) the ion-sieving coating layer confines zincate inside and mitigates shape changes of the electrode; and (iii) the coating layer is made of a HER suppressing material, which represses side reactions. The results demonstrate that HER suppressing sealed nanorod (HSSN) zinc anodes exhibit long cycle life, high Coulombic efficiency, and high specific discharge capacity.

The critical thickness of ZnO passivation layer has previously been quantified to be 2 μm when a zinc metal anode is completely passivated. Thus, sub-micron-sized zinc anodes are believed to be able to overcome the passivation problem. However, decreasing the feature size to be nanoscale will intensify the dissolution and HER problems, due to increased electrode-electrolyte contact area. Therefore, sealing sub-micron-sized anodes by uniformly coating a HER suppressing ion-sieving layer is developed, which can suppress HER and selectively block larger zincate ions inside the coating while enabling OH⁻/H₂O transport (FIG. 4).

Coat technology is important, as conventional attempts with non-uniform coatings creates structures that still suffer dissolution and HER issues, which might be a reason these prior results had short cycle life (<20 cycles) and low specific discharge capacity. In this embodiment of the present invention, a TiO₂ coating material is investigated to demonstrate it is stable with alkaline electrolytes and has a low HER activity.

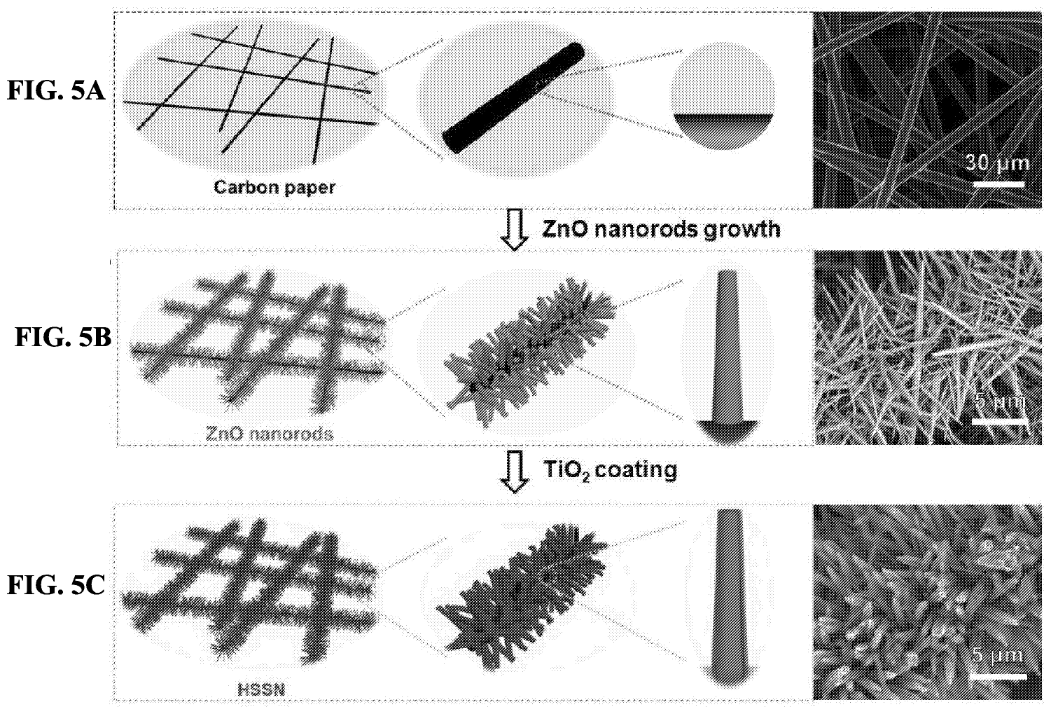

The present HSSN anode was successfully fabricated as shown in FIGS. 5A-C. ZnO nanorods were first grown on the carbon paper hydrothermally. The mass loading of ZnO nanorods on carbon paper can be tuned from 0.5 mg/cm² to 5.5 mg/cm².

### Synthesis of the Uncoated ZnO Nanorod Anode

ZnO nanorods were grown on carbon papers (˜8.4 mg/cm²) by a hydrothermal method. Carbon paper (Fuel Cell Store) was first heated in air at 500° C. for 1 hour to increase its wettability. Then, the carbon paper was soaked in 0.1M KMnO₄ (Sigma Aldrich) aqueous solution for 1 hour to form a seed layer. The ZnO precursor solution was prepared by mixing 50 mL zinc nitrate hexahydrate (30 mM, Alfa Aesar), 50 mL hexamethylenetetramine (30 mM, Sigma Aldrich), and ammonia (28.0-30.0% NH3 basis, Sigma Aldrich).

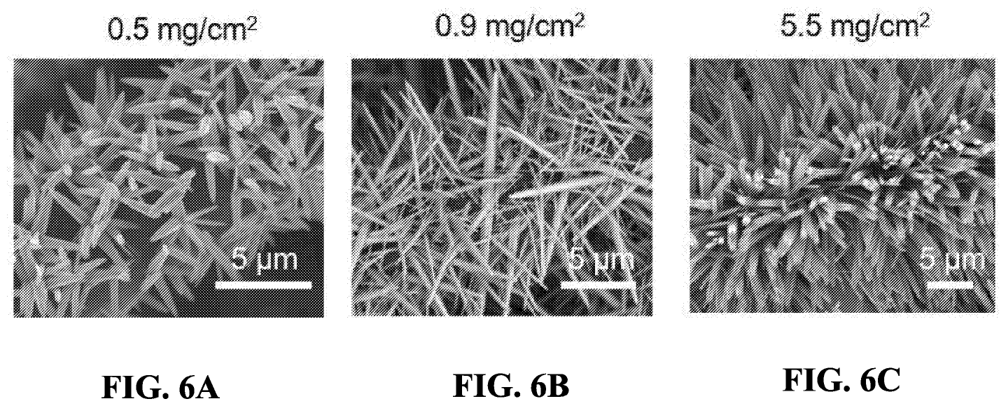

The seeded carbon paper was placed in the solution, followed by heating in an oven at 90° C. After DI-H₂O washing and drying at 80° C. for 3 hours, the white-colored product on carbon paper was obtained. Different mass loadings (0.5˜5.5 mg/cm²) of ZnO nanorods on carbon paper were achieved by adjusting reaction conditions, as summarized in TABLE 1 and shown in FIGS. 6A-C. Specifically, the “Repeat” column means that the ZnO nanorods-loaded carbon paper from the first reaction was put into a new precursor solution to repeat the reaction.

TABLE 1
Experiment Conditions For Different Mass Loadings Of ZnO
Nanorods

| | Carbon Paper | | Total | |
|---|---|---|---|---|
| Mass | Area Per | NH₃ | Hydrothermal | |
| Loading | Batch | Quantity | Time | Repeat |
| 0.5 mg/cm² | 2 × (2.1*6) cm² | 2 mL | 13 h | No |
| 0.9 mg/cm² | 1 × (2.1*6) cm² | 4 mL | 22 h | No |
| 5.5 mg/cm² | 1 × (2.1*6) cm² | 4 mL | 2*20 = 40 h | Once |

### Synthesis of the HER Suppressing Sealed Nanosized (HSSN) Zinc Anode

The HSSN zinc anode (a ZnO core/TiO₂ shell structure) was synthesized using a solution method. The carbon paper with grown ZnO nanorods was immersed into a solution of 0.075M (NH₄)₂TiF₆ and 0.2M H₃BO₃ for 10 minutes at room temperature. A layer of ˜30 nm thick TiO₂ was deposited.

### Synthesis of the ZnO@TiNₓO_{y} Anode

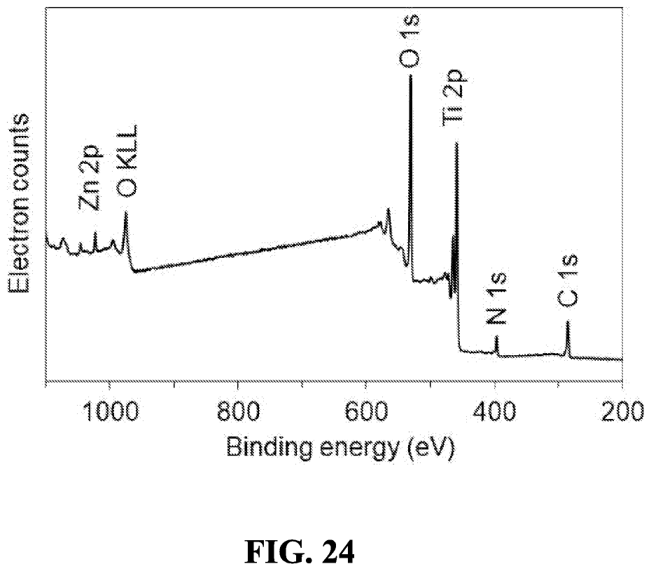

To achieve the ZnO@TiNₓO_{y} anode, TiN was deposited onto the uncoated ZnO nanorod anode through ALD. ALD was conducted in Cambridge FIJI Plasma ALD system. The detailed ALD recipe is shown in FIG. 26. The precursors of TiN were TDMAT and N₂. During the TiN ALD process, the recipe was run 200 cycles (1 Å per cycle) at 250° C. Then, when ZnO@TiN nanorods were exposed to air, the TiN was partially oxidized to TiNₓO_{y} (FIG. 24).

### Sheet Resistance Measurement of TiNₓO_{y} And TiO₂ Coatings Using a Four-Point Probe System

To measure the sheet resistance of TiNₓO_{y} and TiO₂ coatings, TiNₓO_{y} and TiO₂ are deposited onto glass slides, respectively. The glass slides were cleaned by sonication in acetone/ethanol, followed by ultraviolet-ozone (UVO) treatment. TiNₓO_{y} was obtained through an ALD of TiN on the glass slides followed by an oxidation step in air.

The precursors of TiN were TDMAT and N₂. The detailed ALD recipe is shown in FIG. 26. During ALD process, the recipe was run 400 cycles (1 Å per cycle) at 250° C. A layer of 1 μm thick TiO₂ was deposited on the glass slides by immersing the glass slides in a solution of 0.1M (NH₄)₂TiF₆+0.2M H₃BO₃ for 11 hours at 25° C. The sheet resistance was measured using a four-point probe measurement system (2000 multimeter, Keithley).

### Material Characterization and Measurements

The morphological and compositional analyses were carried out using SEM (Hitachi SU 8230), TEM (Hitachi HT7700, FEI Tecnai F30, and JEOL 100 CX-II), and STEM (Hitachi HD-2700). The XRD patterns (Panalytical XPert PRO Alpha-1) were carried out with Cu K-Alpha radiation. The XPS was measured with Thermo Scientific K-Alpha system. The specific BET surface areas and pore size distribution were determined by physisorption (BELSORP-max, MicrotracBEL Corp.). The dissolved Zn concentration of samples in 4M KOH electrolyte was measured with an ICP measurement. Cyclic voltammetry, linear sweep voltammetry, and electrochemical impedance spectroscopy were conducted using a VSP system (BioLogic). Battery cycling tests were carried out using LANHE operating in galvanostatic mode.

In the battery-gas chromatography quantitative analysis measurement, the airtight battery system (FIGS. 2A-C) was connected to a gas chromatography (MG #5, SRI Instruments). The system was purged with Ar before the measurement. The stainless-steel rod was used as the anode. ZnO-saturated 4M KOH (Sigma Aldrich) was used as the electrolyte. A 4 cm² cathode from a commercial Ni—Zn AA battery (PowerGenix), which is a mixture of NiOOH (˜8 mAh/cm²)/Ni(OH)₂ (˜32 mAh/cm²), was harvested to pair with the anode.

The battery was charged at 20 mA for 15 minutes and then fully discharged (20 mA) to 0.8 V for 1 cycle. Then H₂ measurements were conducted using the thermal conductivity detector. Ar was the carrier gas for gas chromatography. The capacity loss on the Zn anode is almost fully caused by HER (99.47%).

Capacity loss=Charge capacity−Discharge capacity=Capacity (HER)+Capacity (Other) (6)

### Electrochemistry

The zinc anodes were cut to round disks with a diameter of 1 cm. Cathodes from commercial Ni—Zn AA batteries (PowerGenix), which is a mixture of NiOOH (˜8 mAh/cm²)/Ni(OH)₂ (˜32 mAh/cm²), were harvested to pair with the anodes.

### Coin Cell

CR2032 cases (MTI Corporation) were used to make coin cells. The aqueous electrolyte consists of 4M KOH (Sigma Aldrich, 99.99%), 2M KF (Alfa Aesar, 99.99%) and 2M K₂CO₃ (Alfa Aesar, 99.997%). 25 μL electrolyte was used. Glass fiber (GE Healthcare, Whatman™ 10370003) was used as the separator.

### Pouch Cell

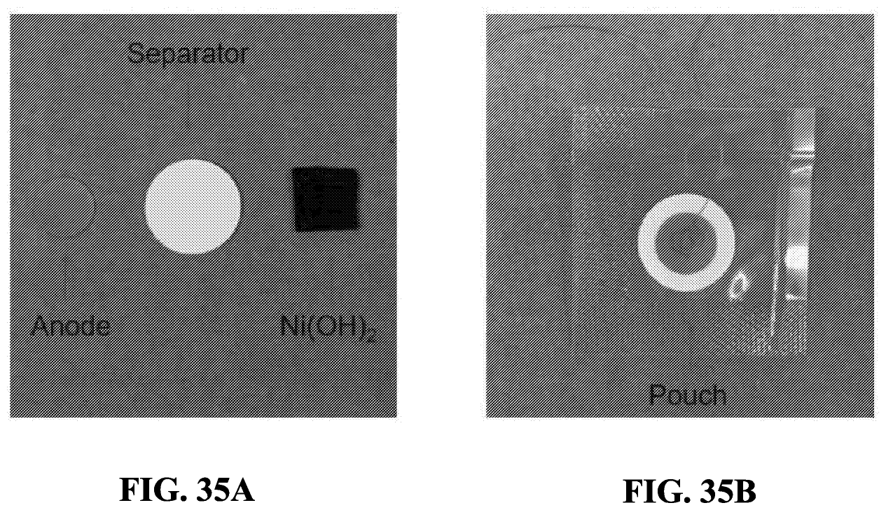

Pouch-type batteries (FIGS. 35A-B) were assembled using Ampac's SealPAK. The mass loading of active material (ZnO) on the anode is 1.5 mg/cm². The aqueous electrolyte comprises 4M KOH (Sigma Aldrich, 99.99%), 2M KF (Alfa Aesar, 99.99%) and 2M K₂CO₃ (Alfa Aesar, 99.997%) with saturated ZnO. 100 μL electrolyte was used. Glass fiber (GE Healthcare, Whatman™ 10370003) was used as the separator. Ti wires were used as electrode terminals.

Cells are galvanostatically cycled at a charge rate of 1 C and a discharge rate of 5 C between 1.4 and 1.9 V. For anodes cycled at 100% DOD, the anodes were activated by being pre-cycled in pouch cells for 6 cycles. The charge capacity limit cut-off is 658 mAh/g (theoretical specific capacity of ZnO). For anodes cycled at 40% DOD, the anodes were activated by being pre-cycled with 100% active material utilization for 1 cycle and then being fully charged.

### Beaker Cell

In beaker-type batteries, the mass loading of active material (ZnO) on the anode is 1.6 mg/cm². 10 mL ZnO-saturated 4M KOH (Sigma Aldrich) was used as the electrolyte. Cells are galvanostatically cycled at 100% DOD at a charge rate of 1 C and a discharge rate of 5 C between 1.4 and 1.9 V. The anodes were activated by being pre-cycled in beaker cells for 50 cycles. The charge capacity limit cut-off is 658 mAh/g. Ag wire was used as the anode terminal. Stainless steel wire was used as the cathode terminal.

As discussed, the charge capacity was limited to the theoretical capacity of ZnO (approximately 658 mAh/g). The theoretical specific capacity (charge capacity) was calculated by:

$${C}_{T} ( mAh / g ) = \frac{1}{M W} * \frac{n F}{3.6} \qquad ( 7 )$$

where MW is the molar weight of active material, n is the number of electrons transferred in the relevant reaction, and F is the Faraday's constant. In this work, MW of ZnO=81.38 g/mol; n=2; F=96485 C/mol.

The specific discharge capacity of the electrode was calculated by:

C=It/m (8)

where I is the discharge current, t is the discharge time per cycle, and m is active materials' mass (ZnO).

A rate of mC corresponds to a full charge/discharge in 1/m hour(s). The electrolyte-to-discharge-capacity (E/DC) ratio is:

E/C ratio=Volume of electrolyte/measured discharge capacity (9)

Thus, the theoretical gravimetric capacity of Zn metal is:

$${C}_{g} ( mAh / g ) = \frac{1}{M {W}_{Z n}} * \frac{n F}{3.6} = \frac{1}{65.38} * \frac{2 * 96485}{3.6} = 820 \qquad ( 10 )$$

The theoretical volumetric capacity of Zn metal is:

C_{ν}(mAh/cm³)=C_{g}*ρ_{Zn}=5854 (11)

where ρ_{Zn} is the density of Zn:

ρ_{Zn}=7.14 g/cm³ (12)

The theoretical gravimetric energy density of Zn-air batteries (calculated based on the discharged state, ZnO) is:

$${E}_{g} ( Wh / kg ) = \frac{1}{M W {z}_{n} o} * \frac{n F}{3.6} * V = \frac{1}{81.38} * \frac{2 * 96485}{3.6} = 1093 \qquad ( 13 )$$

where V is the battery voltage. V=1.66 V.

The theoretical volumetric energy density of Zn-air batteries is:

E₈₄ (Wh/L)=E_{g}*ρ_{ZnO}=6134 (14)

where ρ_{ZnO} is the density of ZnO.

ρ_{ZnO}=5.61 g/cm³ (15)

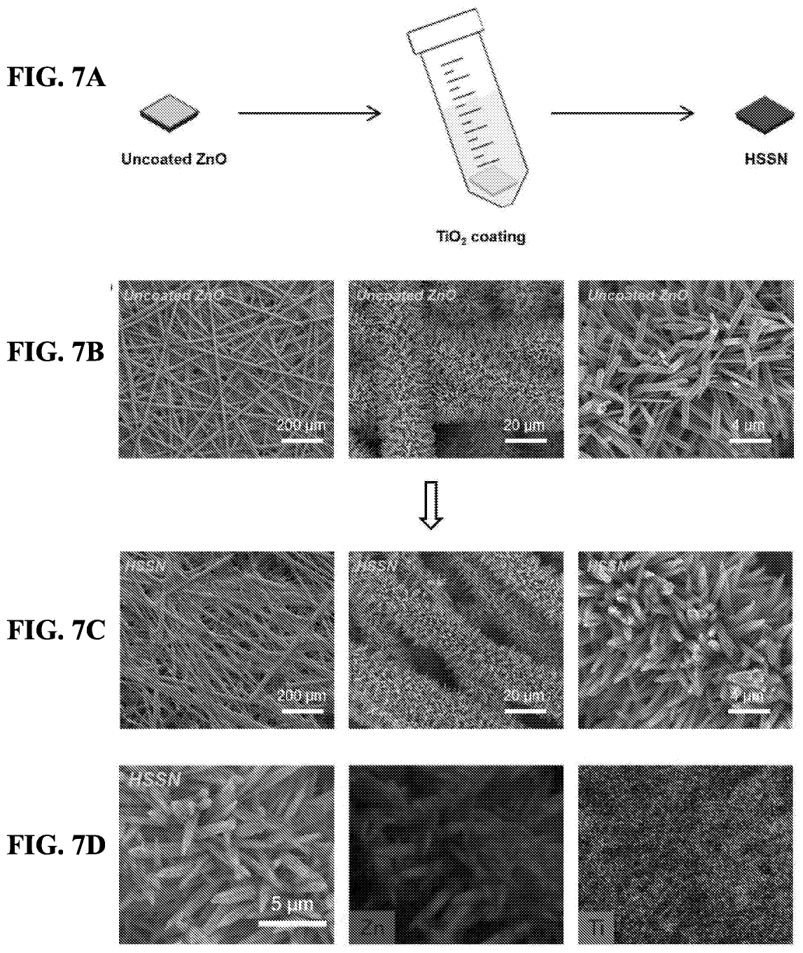

The TiO₂ layer was coated on the ZnO nanorods via a mild solution method at room temperature. The ZnO nanorods were immersed in an aqueous solution comprising 0.075M (NH₄)₂TiF₆ and 0.2M H₃BO₃. After the TiO₂ coating, the ZnO nanorod structure was well maintained (FIGS. 7A-D).

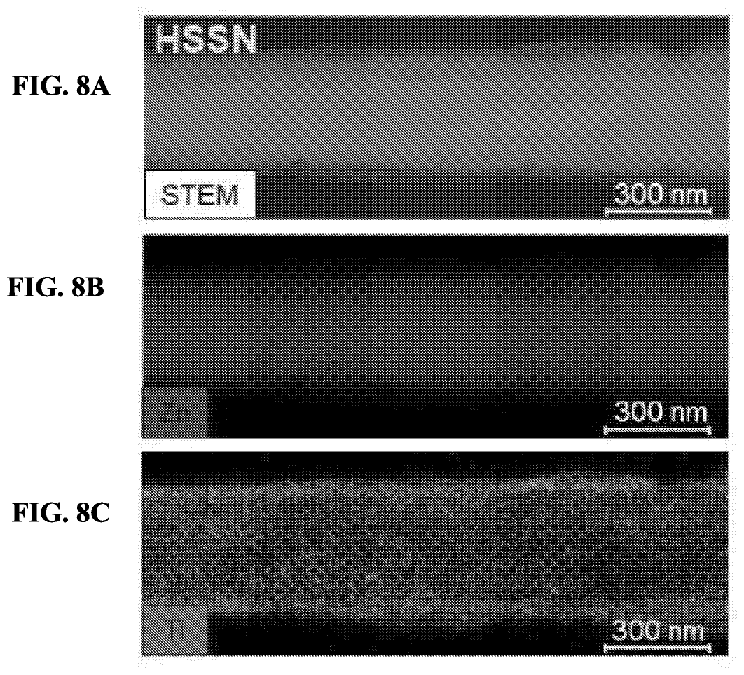

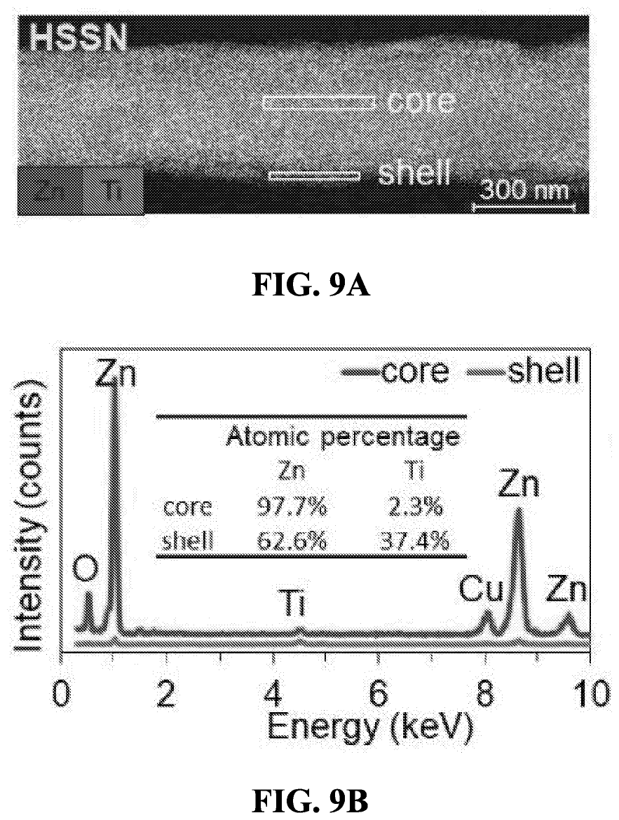

STEM image and elemental mappings (FIGS. 8A-C) of the present HSSN anode confirm that the TiO₂ coating is uniform. Spatial distributions of Zn and Ti were obtained by taking EDX spectroscopies in the core and shell regions (FIGS. 9A-B). The core region shows a much higher Zn intensity than that of the shell region, which further affirms the ZnO core/TiO₂ shell structure.

During synthesis, (NH₄)₂TiF₆ hydrolyzed to TiO₂ on the surface of ZnO while the surface of ZnO slightly dissolved in the solution with acids produced by (NH₄)₂TiF₆ hydrolysis. Thus, it appears some Zn species went into the TiO₂ coating during the synthesis, which may explain for the Zn signal on the TiO₂ shell.

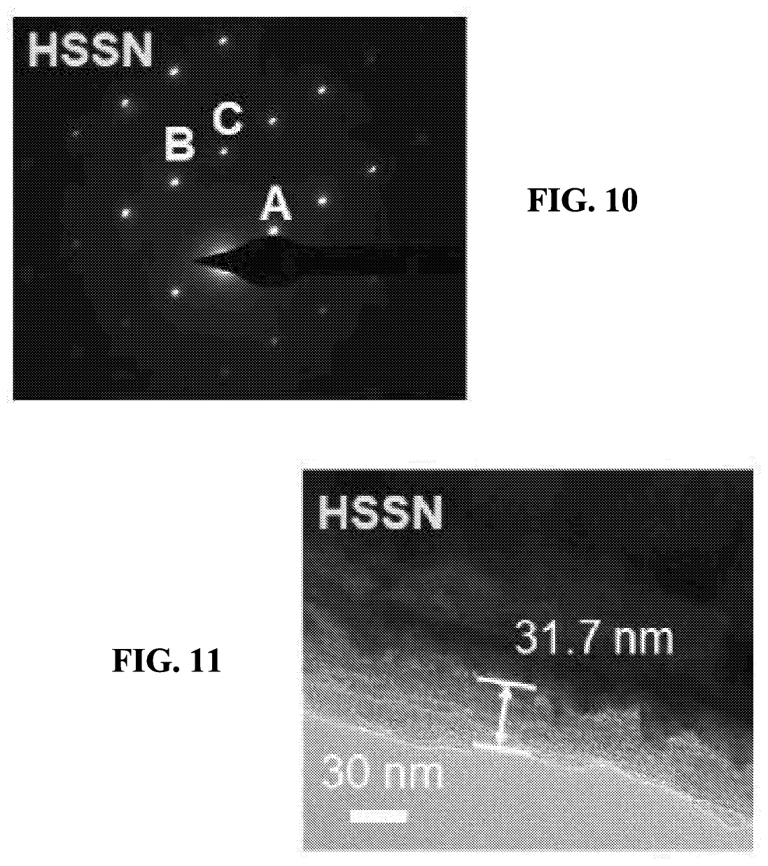

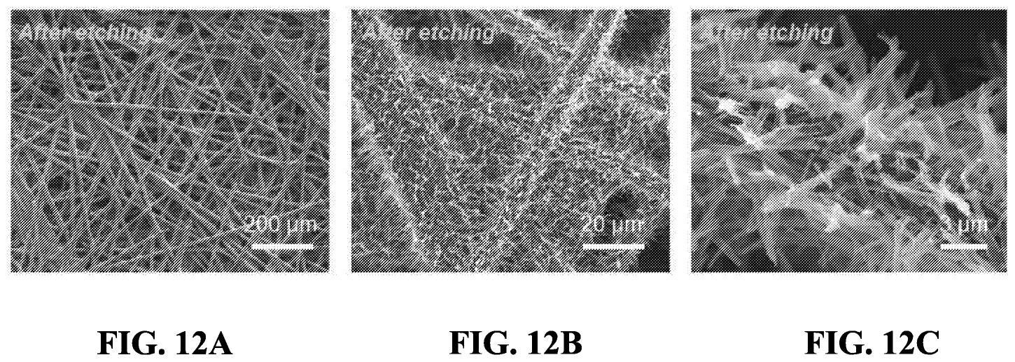

As evidenced by FIG. 10, the ZnO in the core has a hexagonal close packed crystal structure and the TiO₂ coating is amorphous. The TiO₂ layer has a thickness of ˜31.7 nm (FIG. 11). The mass loading of TiO₂ is ˜0.35 mg/cm², which is only ˜10.4 wt % of the present HSSN anode (with approximately 3 mg/cm² ZnO nanorods). After etching the ZnO away, the hollow nanoarrays stayed in place (FIGS. 12A-C), displaying that the TiO₂ coating, although only ˜30 nm thick, is mechanically strong and firmly supports the ZnO nanorods.

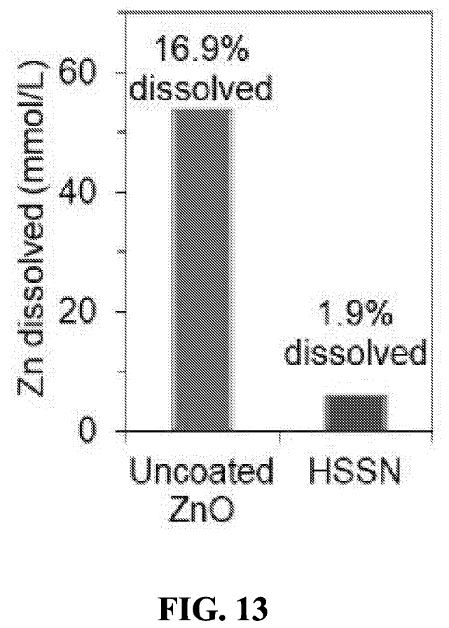

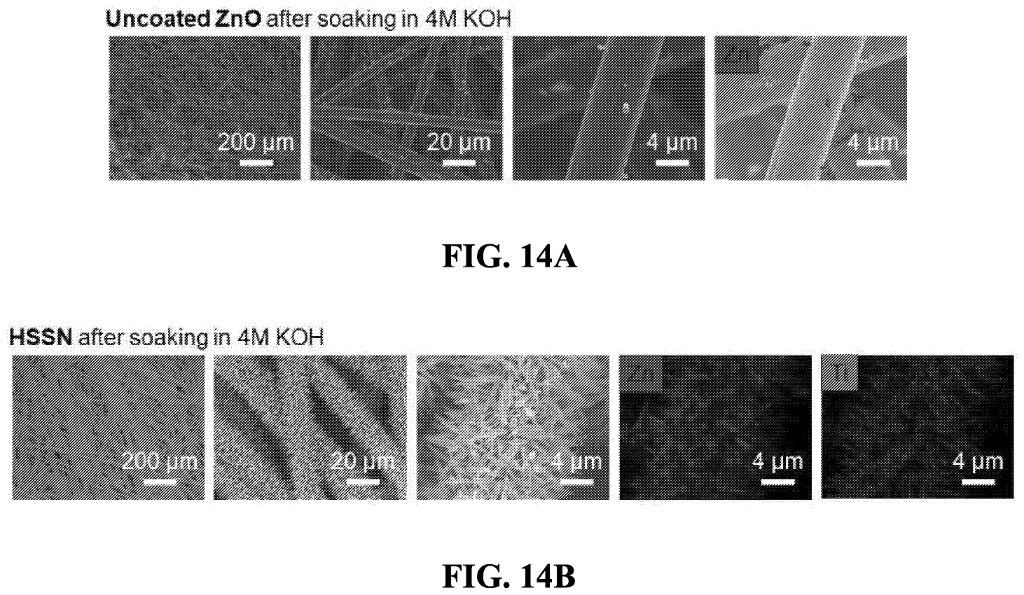

To evaluate the capability of the TiO₂ shell to suppress zincate dissolution, both the HSSN and the uncoated ZnO anodes were soaked in a ZnO-free 4M KOH solution for 15 minutes. The ratio of ZnO active material mass and solution volume was 0.02 mg/μL. The dissolved Zn concentration was then measured in both solutions using inductively coupled plasma atomic emission spectroscopy (ICP-AES). As shown in FIG. 13, the dissolved Zn of the HSSN anode (1.9%) was much lower than that of the uncoated ZnO anode (˜16.9%). ˜90% ZnO dissolution is suppressed in the HSSN anode, which displays that the TiO₂ shell effectively blocks zincate ions. Both anodes were imaged after soaking in 4M KOH solution (FIGS. 14A-B), which also supports that TiO₂ coating can effectively confine zincates inside the shell.

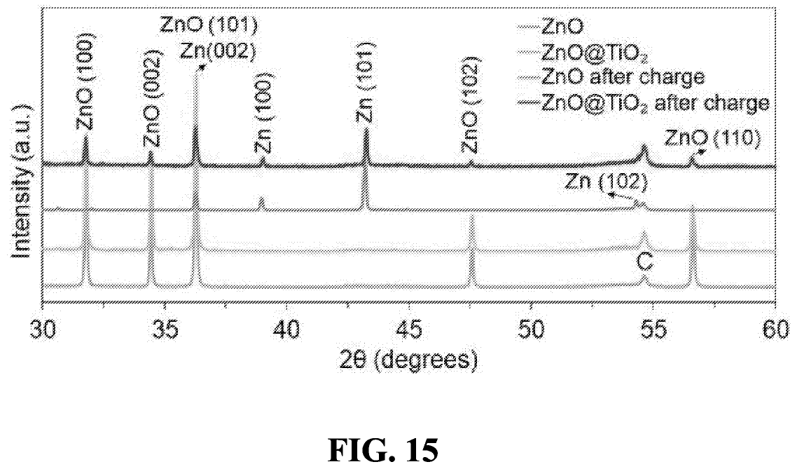

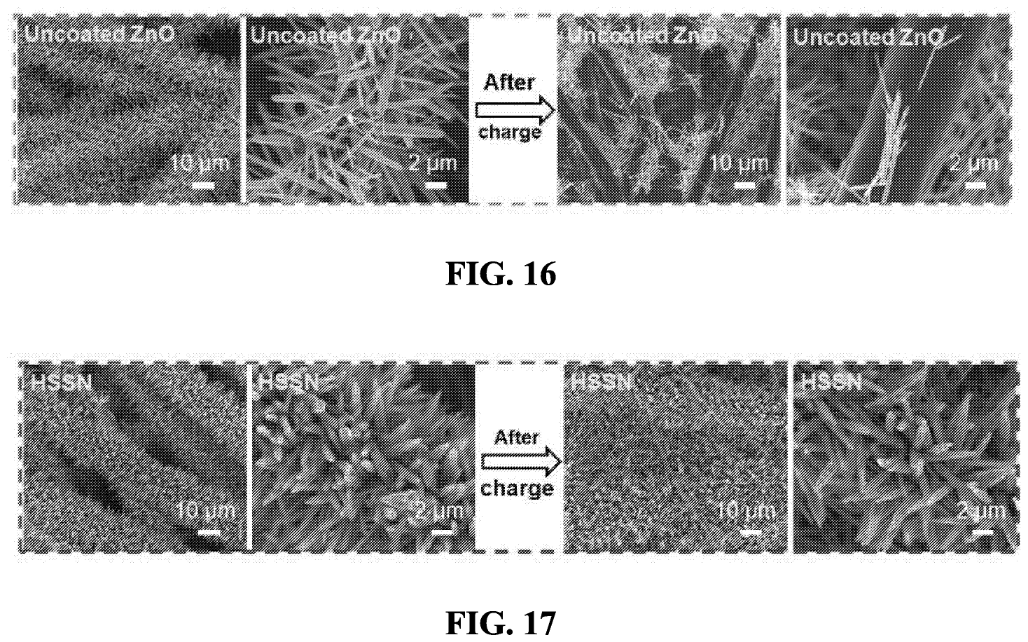

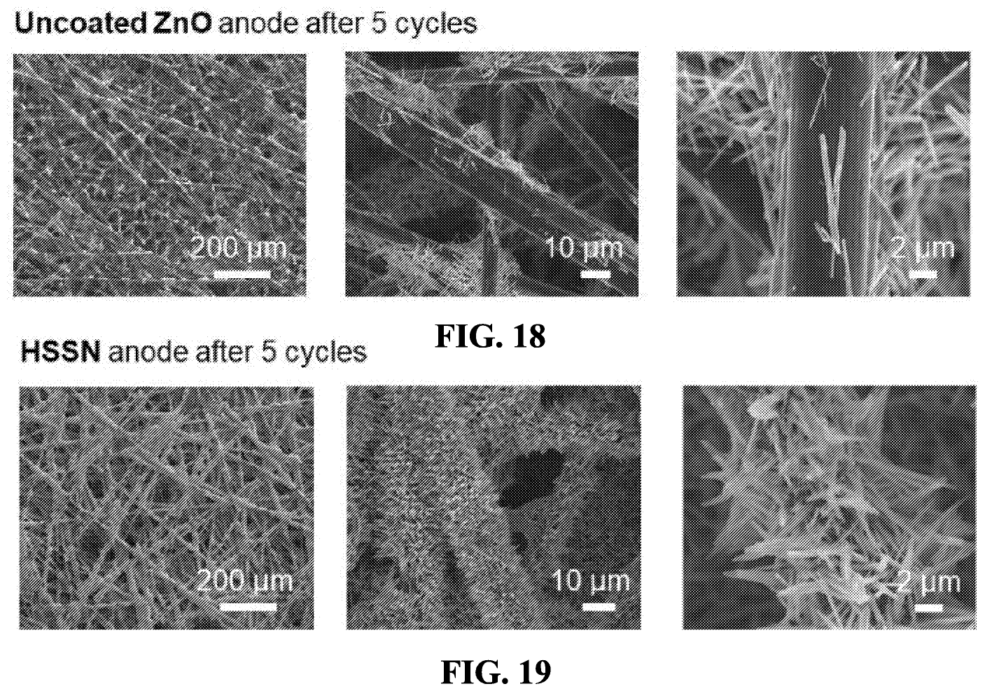

The zinc-based anodes were also characterized before and after a single charge in coin cells. As shown in FIG. 15, XRD patterns confirmed the existence of the charging product, metallic Zn. After being charged at 0.25 mA/cm² for 1.5 hours, the uncoated ZnO nanorod anode showed severe structural degradation. The nanorods detach from carbon paper (FIG. 16). In contrast, the HSSN anode has no obvious shape change (FIG. 17). Additionally, the HSSN anode kept nearly unchanged after five cycles (FIGS. 18-19).

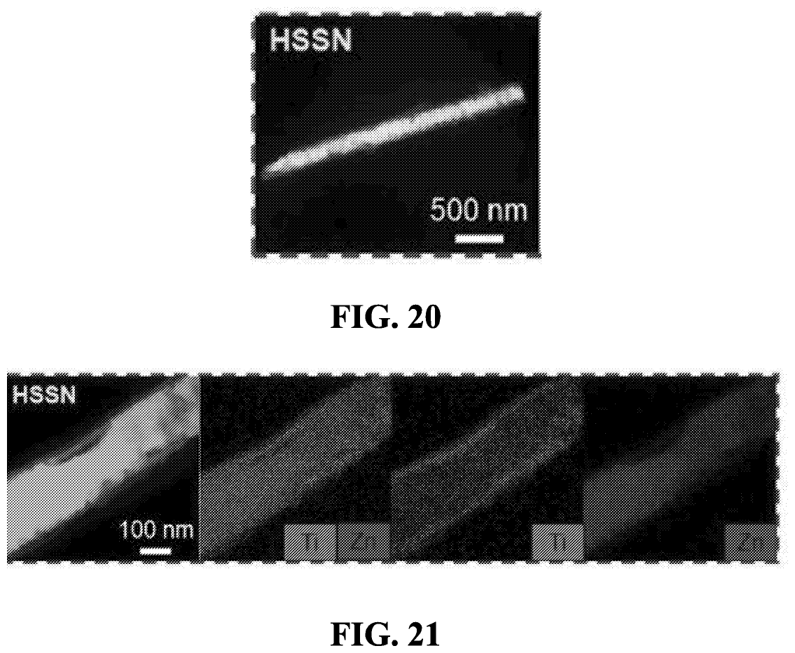

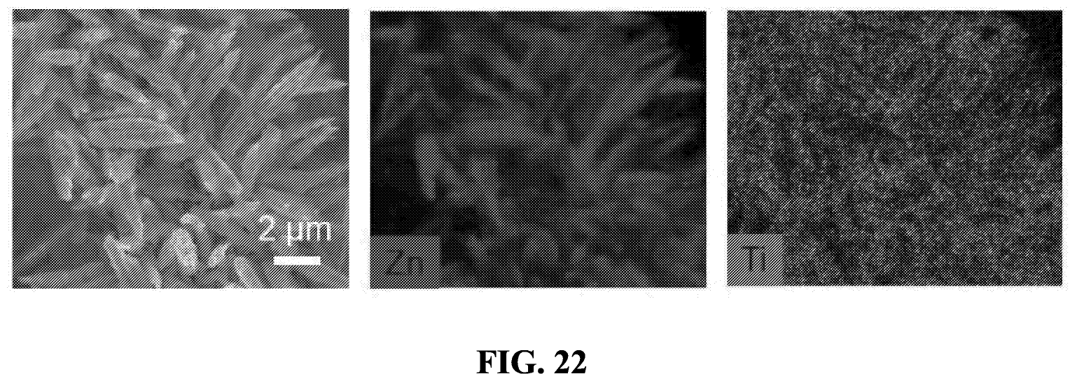

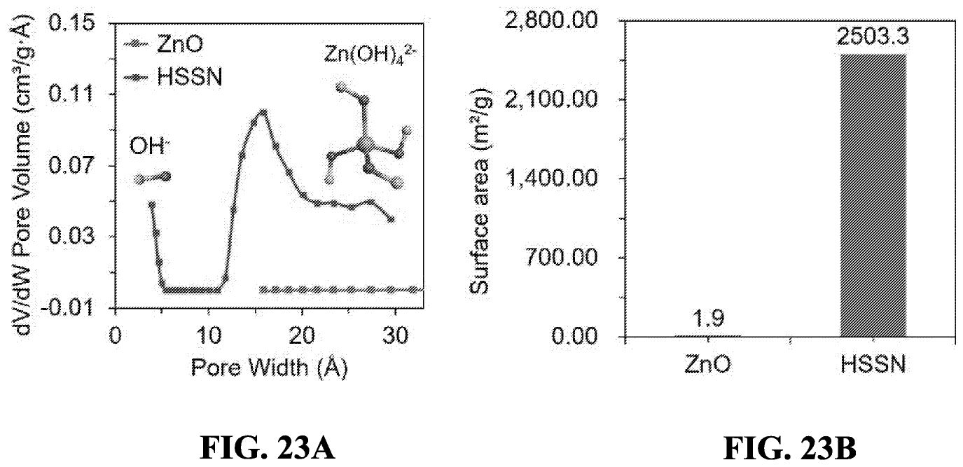

STEM images and elemental mappings of the present HSSN anode after charging are presented in FIGS. 20-22. These results indicate that the TiO₂ shell confines zinc active materials inside during cycling, which can be attributed to the ion-sieving effect of the TiO₂ shell. As shown in the N₂ absorption spectrum (FIG. 23), TiO₂ layer has nanosized pores, which block larger zincate ion inside the shell and enable OH⁻/H₂O transport through the shell. The porosity of TiO₂ can likely be further engineered to optimize its ion-sieving performance.

As discussed above, an ion-sieving coating layer is important for nanostructured Zn anodes to effectively suppress active material dissolution. In consideration of HER, such an ion-sieving coating layer should be HER suppressing. To evaluate the HER suppressing capability of the TiO₂ shell and its effect on the Coulombic efficiency, HER activities of TiO₂ and TiNₓO_{y} were investigated.

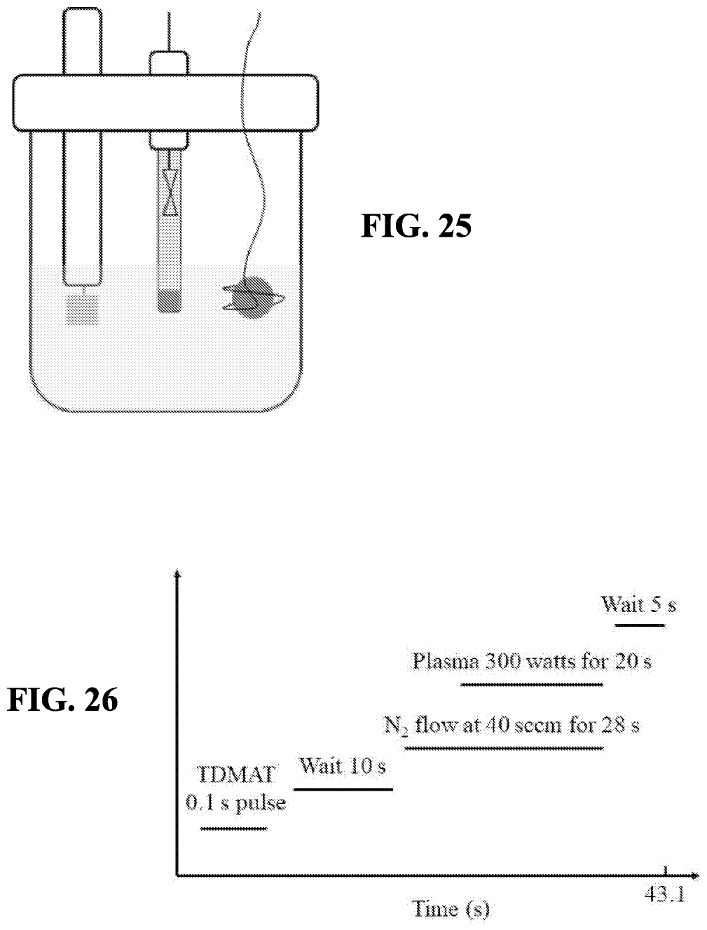

TiNₓO_{y} (FIG. 24) was chosen to be the control material because its uniform coating and ion-sieving property have been achieved. To best represent the anodes, ZnO was etched away from the HSSN and ZnO@TiNₓO_{y} anodes to get TiO₂ and TiNₓO_{y} hollow nanorod coatings on carbon paper substrates, respectively (FIG. 24). Three-electrode cells were then assembled in 4M KOH electrolyte with TiO₂ or TiNₓO_{y} electrode as the working electrode, Hg/HgO electrode as the reference electrode, and Pt foil as the counter electrode (FIGS. 25-26).

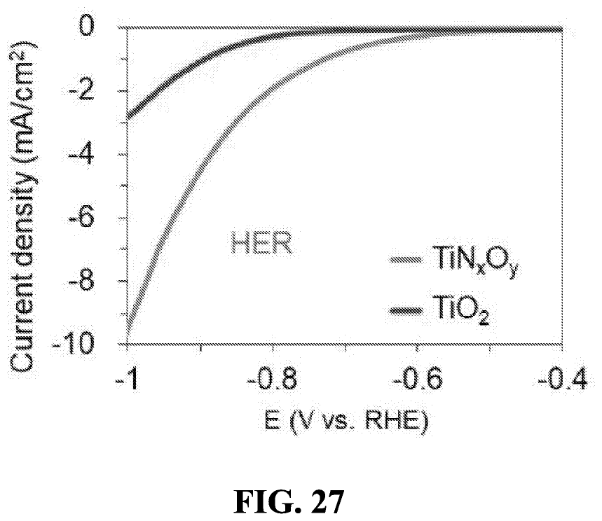

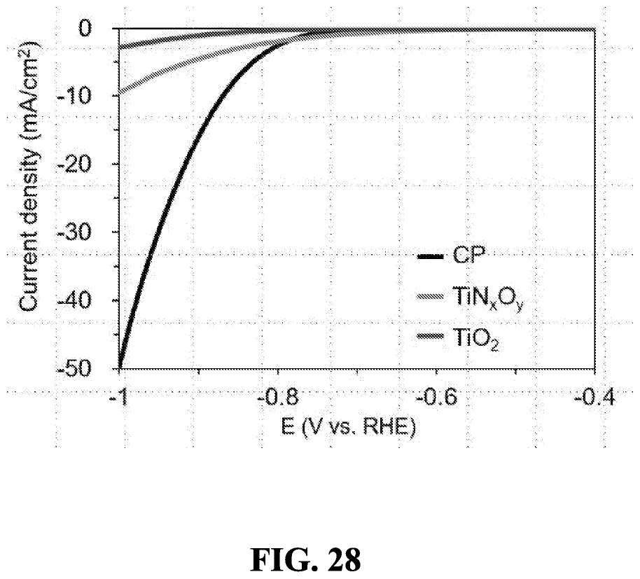

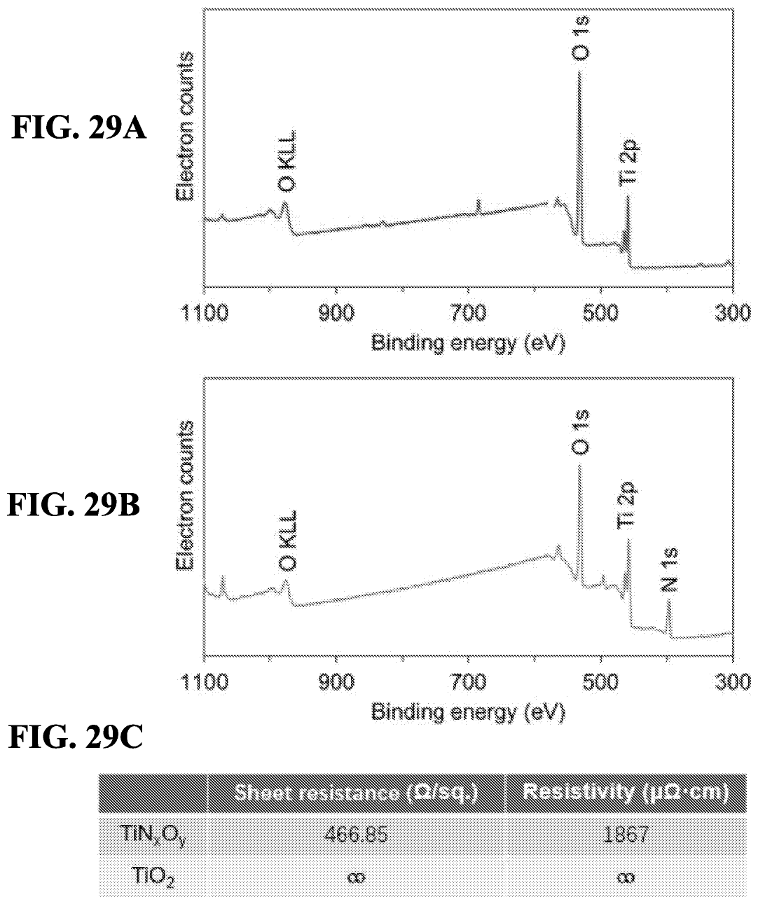

As shown in IR-corrected polarization curves (FIG. 27), the HER on the TiNₓO_{y} electrode was more severe (higher current density at a fixed HER potential) than on TiO₂. These experimental results reveal that the TiO₂ is more hydrogen suppressive than TiNₓO_{y}. In addition, the HER activities of the TiO₂ electrode were also compared with the carbon paper substrate, which experimentally indicates that the existence of TiO₂ coating can suppress HER (FIG. 28). To understand the hydrogen suppressing property of TiO₂, the sheet resistance of TiO₂ and TiNₓO_{y} was measured using a four-point probe system (FIGS. 29A-C).

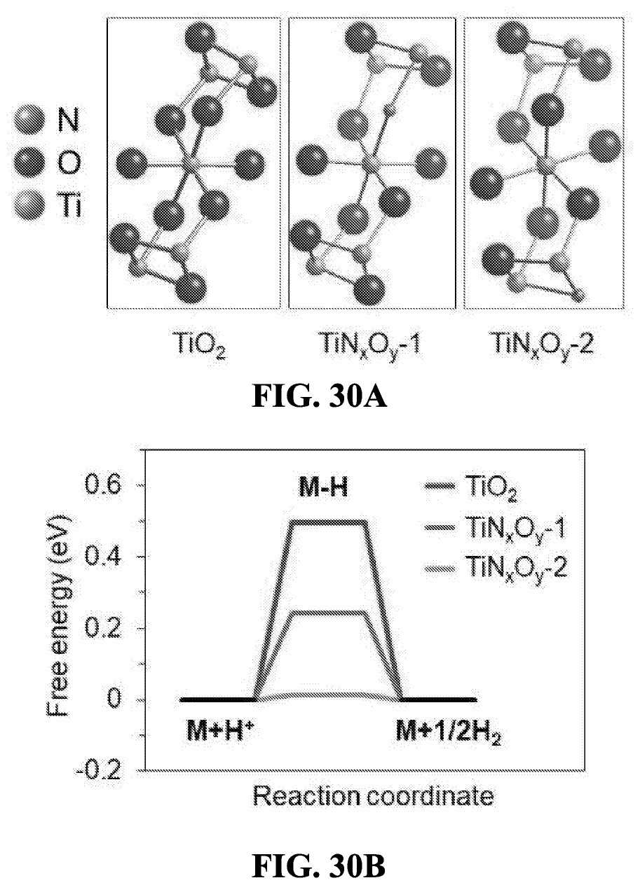

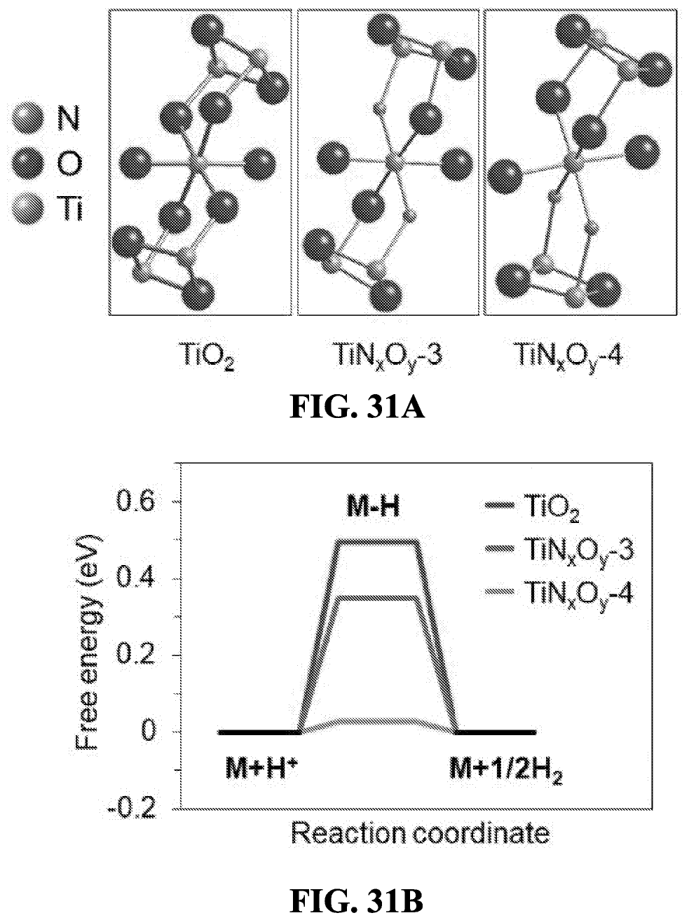

TiO₂ has lower electrical conductivity, which may be part of the reason for its lower HER activity and better HER suppressing capability. Simulations based on the force field model were also conducted to confirm the hydrogen suppressing property of TiO₂. Cluster rather than the slab model was chosen because of its applicability in representing amorphous materials (FIG. 30A). In a three-state diagram (FIG. 30B), ΔG_{H}* represents the free energy for H adsorption. The material with higher |ΔG_{H}*| value possesses lower catalytic activity and better hydrogen suppressing capability. The free energy for TiO₂ is 0.495 eV, which is higher than that of TiNₓO_{y} clusters (FIGS. 31A-B and 32). This result illustrates that TiO₂ is the most hydrogen suppressive.

Simulation based on the force field model was conducted to investigate the hydrogen suppressing property of TiO₂ and TiNₓO_{y}. The Monte Carlo and Least Squares techniques were used to minimize the energy. A Ti₅O₁₀ cluster was used to represent amorphous TiO₂. For TiNₓO_{y}, the overall atomic ratio of O to N (O/N) was experimentally determined to be ˜6.66 as evidenced by XPS (FIG. 24).

From many possible structures of amorphous TiNₓO_{y}, four representative models (denoted as TiNₓO_{y}-n, n=1, 2, 3, 4) were chosen and built with O/N atomic ratios of 9 and 4 to simulate the actual shell material. Ti₅O₉N cluster (O/N=9) for TiNₓO_{y}-1 and TiNₓO_{y}-2, and Ti₅O₈N₂ cluster (O/N=4) for TiNₓO_{y}-3 and TiNₓO_{y}-4 were built. ΔGH^{*} represents the free energy for H adsorption.

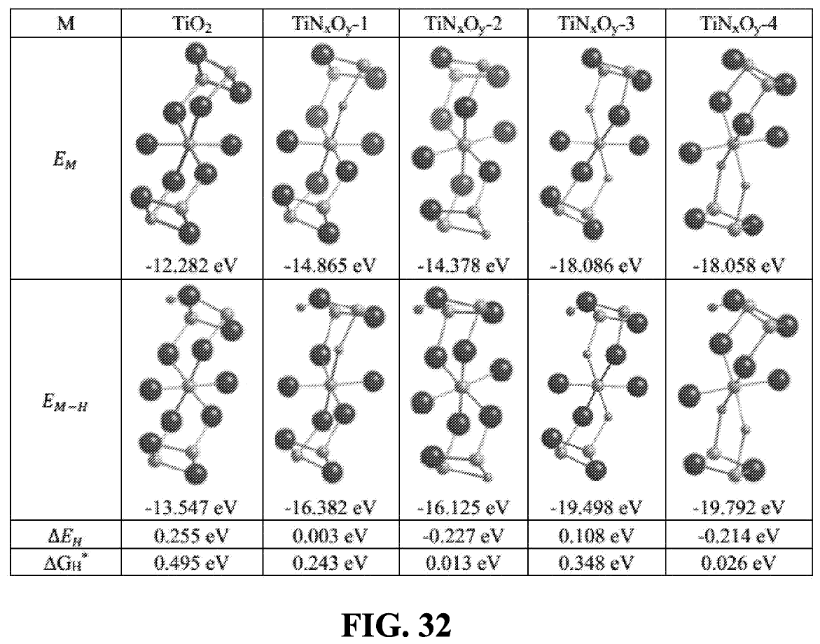

In a three-state diagram, comprising an initial H⁺ state, an intermediate H* state, and ½H₂ as the final product, the material with higher |ΔG_{H}*| value possesses lower catalytic activity and thus better hydrogen suppressing capability. ΔG_{H}* was obtained by ΔG_{H}*=ΔE_{H}+ΔE_{ZPE}−TΔS_{H}, where ΔE_{H} is the binding energy of H species, and ΔE_{ZPE} and ΔS_{H} are the zero point energy change and entropy change of adsorption H, respectively. The contribution of entropies and ZPE for AGH* were obtained, where finally ΔG_{H}*=ΔE_{H}+0.24 eV. ΔE_{H} was obtained by ΔE_{H}=E_{M-H}−E_{M}−½*E_{H}_{₂}·E_{H}_{₂} was calculated to be −3.040 eV. The summary of these values is listed in the table of FIG. 32.

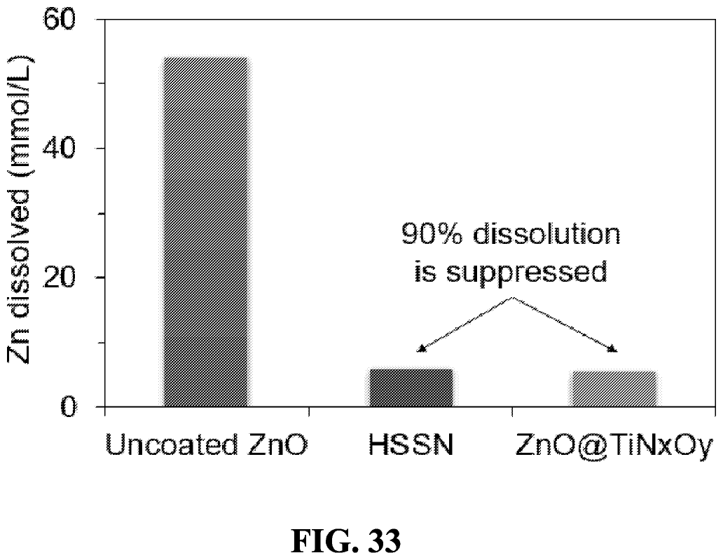

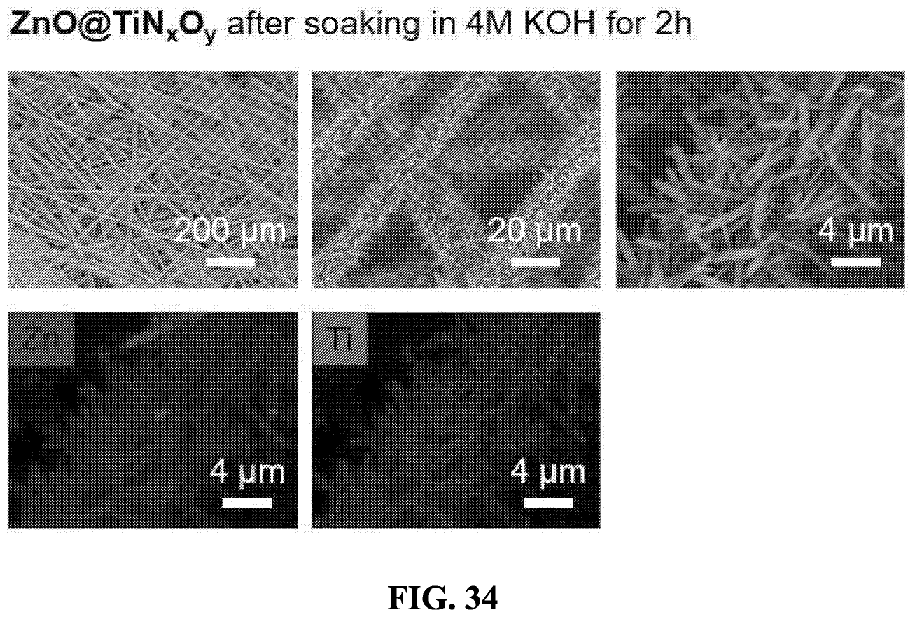

As shown in FIGS. 33 and 34, HSSN and ZnO@TiNₓO_{y} anodes have very similar ion-sieving capability. With hydrogen suppressing capability, the present HSSN anode shows higher Coulombic efficiency compared to the ZnO@TiNₓO_{y} counterpart. To specifically focus on Zn anodes, for all the cells shown below, cathodes with excess capacity were harvested to pair with Zn anodes. The calculation of the specific capacity of zinc anodes is based on the mass of ZnO (theoretical capacity: 658 mAh/g) if not otherwise specified. Cells were galvanostatically cycled at a charge rate of 1 C and a discharge rate of 5 C. The anodes were cycled in pouch cells (FIGS. 35A-B) instead of coin cells to avoid the HER on stainless steel coin cell cases. They were cycled at 100% DOD. Thus, the extent of side reactions on them can be directly indicated by the cell Coulombic efficiency. Higher “clean” Coulombic efficiency means fewer side reactions.

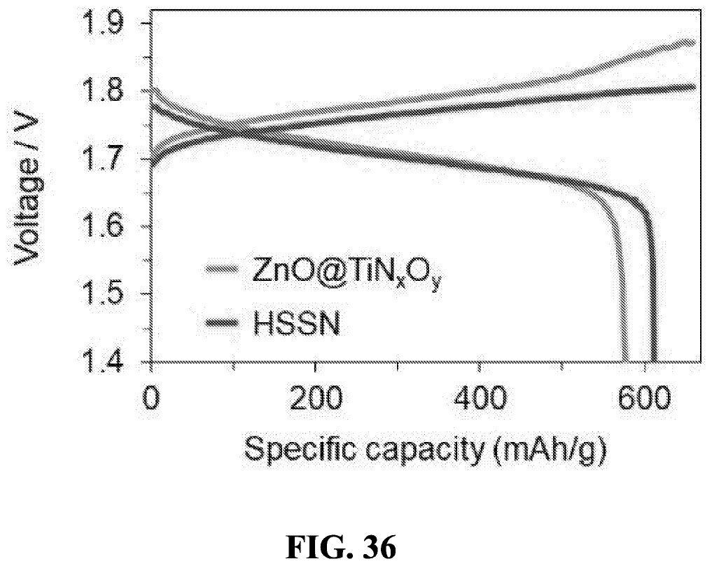

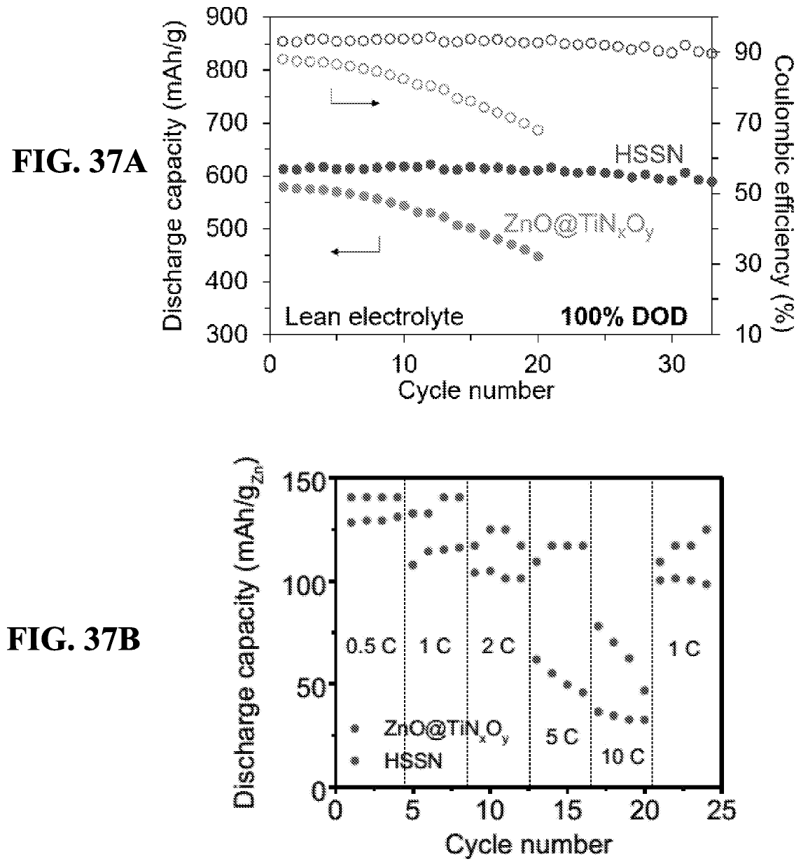

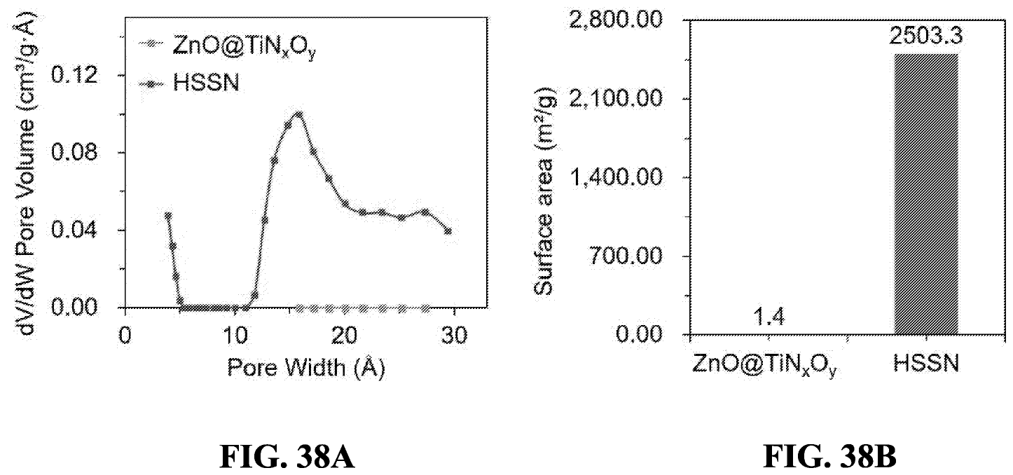

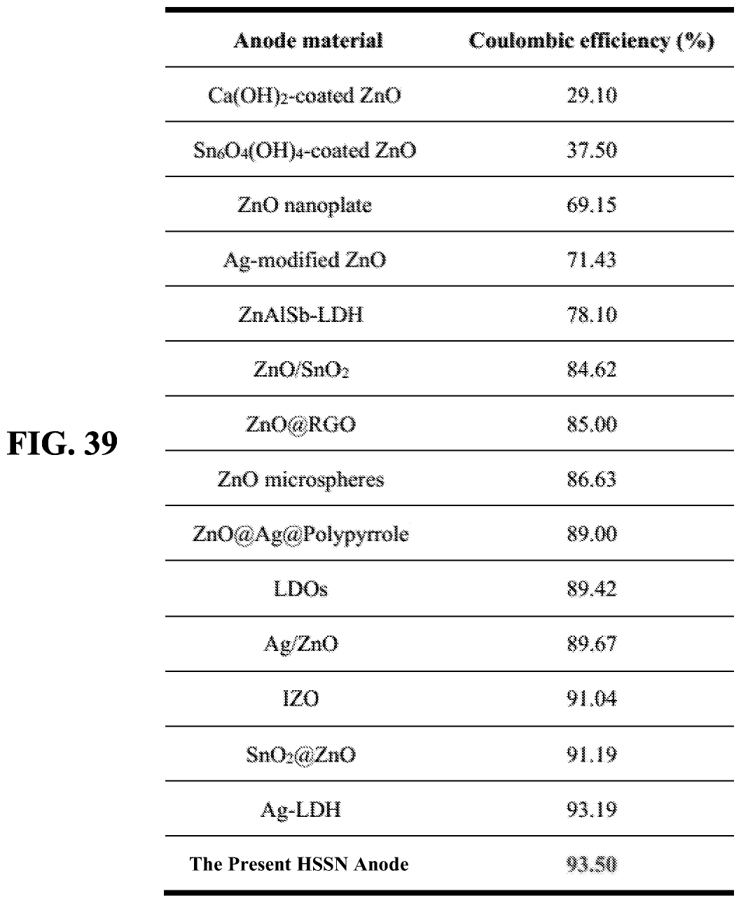

The charge/discharge profiles of HSSN and ZnO@TiNₓO_{y} anodes cycled in lean electrolyte (100 μL) are plotted in FIG. 36. Their cycling performance and rate-capability tests can be found in FIGS. 37A and 37B. The average Coulombic efficiency (˜93.50%) of the present HSSN anode in the first 12 galvanostatic cycles is much higher than that of the ZnO@TiNₓO_{y} anode (˜84.96%). Even though TiO₂ has lower electrical conductivity than TiNₓO_{y}, the HSSN anode showed slightly better rate capability than the ZnO@TiNₓO_{y} anode, which may be because there are more pores on the present HSSN anode and thus the faster OH⁻/H₂O transport can be achieved through the TiO₂ shell (FIGS. 38A and 38B). The HSSN anode achieves higher Coulombic efficiency of ˜93.09% than the ZnO@TiNₓO_{y} anode (˜88.07%). In similar alkaline electrolytes with 100% DOD, conventional studies show Coulombic efficiency lower than ˜90% (FIG. 39).

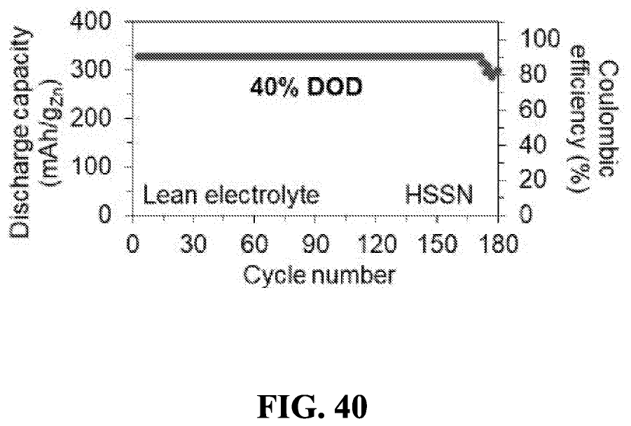

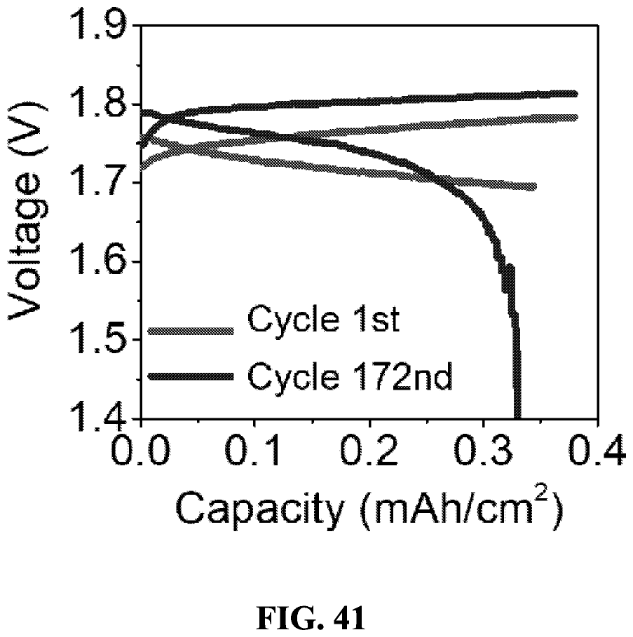

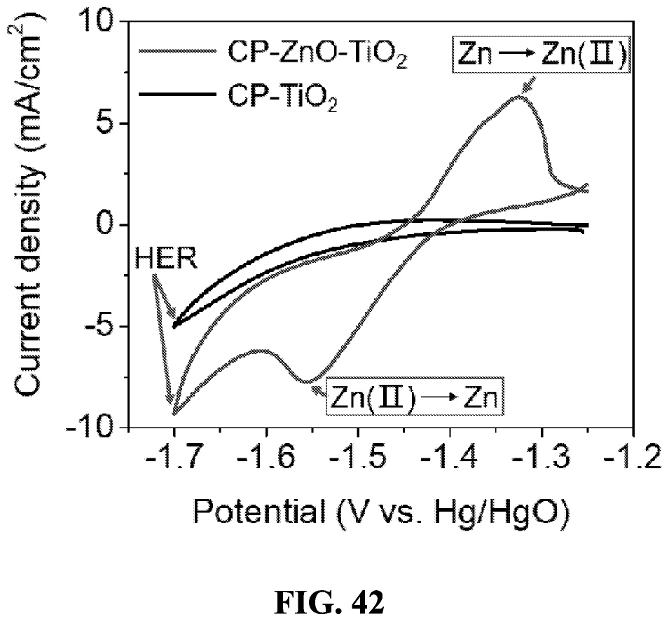

As shown in FIGS. 40 and 41, when cycled at 40% DOD in a lean electrolyte, the present HSSN anode (with 1.05 mg/cm² ZnO) demonstrated long-term stable cycling for more than 170 cycles. There was no capacity contribution from the TiO₂ shell during the electrochemical reactions (FIG. 42). When cycled at 100% DOD in a lean electrolyte, the present HSSN anode (with ˜1.5 mg/cm² ZnO) achieved an average Coulombic efficiency of 93.5% and average discharge capacity of 616 mAh/g in the first 12 galvanostatic cycles (FIG. 37A).

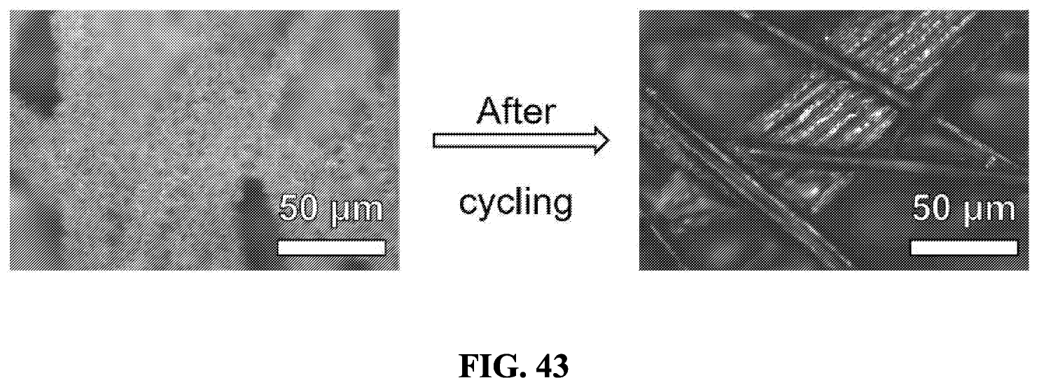

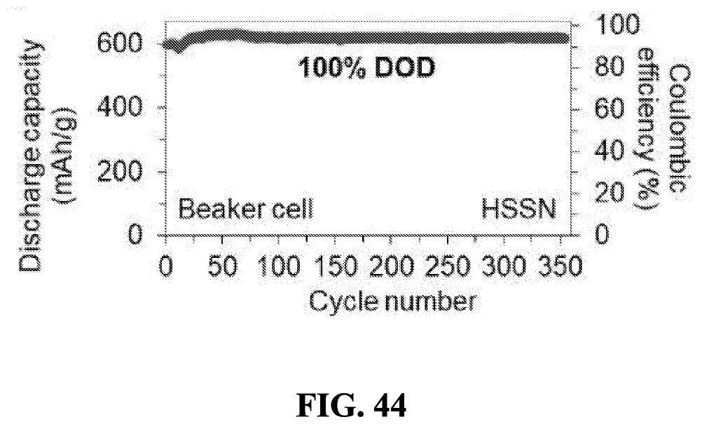

The capacity fading occurs after 33 cycles. The battery failure can be attributed to (1) the structural collapse of the HSSN anode (FIG. 43) due to the shape and volume changes of Zn/ZnO inside the shell, and (2) the limited mass transfer of Zn species caused by electrolyte decomposition and hydrogen accumulation. The anode was also evaluated in a beaker cell with a large amount of ZnO-saturated electrolyte. As shown in FIG. 44, the present HSSN anode (with 1.6 mg/cm² ZnO) was cycled more than 350 times with Coulombic efficiency of 94.3% and a discharge capacity of 621 mAh/g.

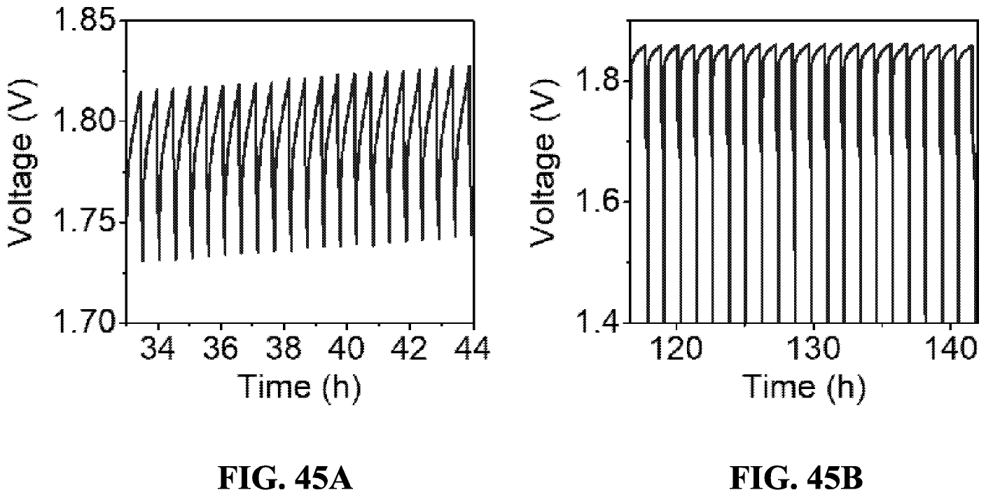

Voltage profiles for the batteries shown in FIGS. 40 and 44 can be found in FIGS. 45A-45B. From the above cycling results, cycle life of Zn anodes in a lean electrolyte is much shorter than in a large amount of ZnO-saturated electrolyte. This can be explained by the electrochemistry of alkaline Zn anodes. In a large amount of ZnO-saturated electrolyte, the effect of minor electrolyte decomposition can be minimized with excess water. Moreover, there is excess zincate in the electrolyte, which is the active material for Zn anodes. With a large capacity contribution from the zincate supplied from the electrolyte, the long cycle life of Zn anodes can be achieved yet it is inauthentic. In lean electrolyte (100 μL), batteries fail quicker as a result of complicated synergistic effects caused by electrolyte decomposition and limited mass transfer of Zn species. However, it is still necessary to cycle anodes in lean electrolyte to evaluate their true performance which can represent practical situations despite their short cycle life.

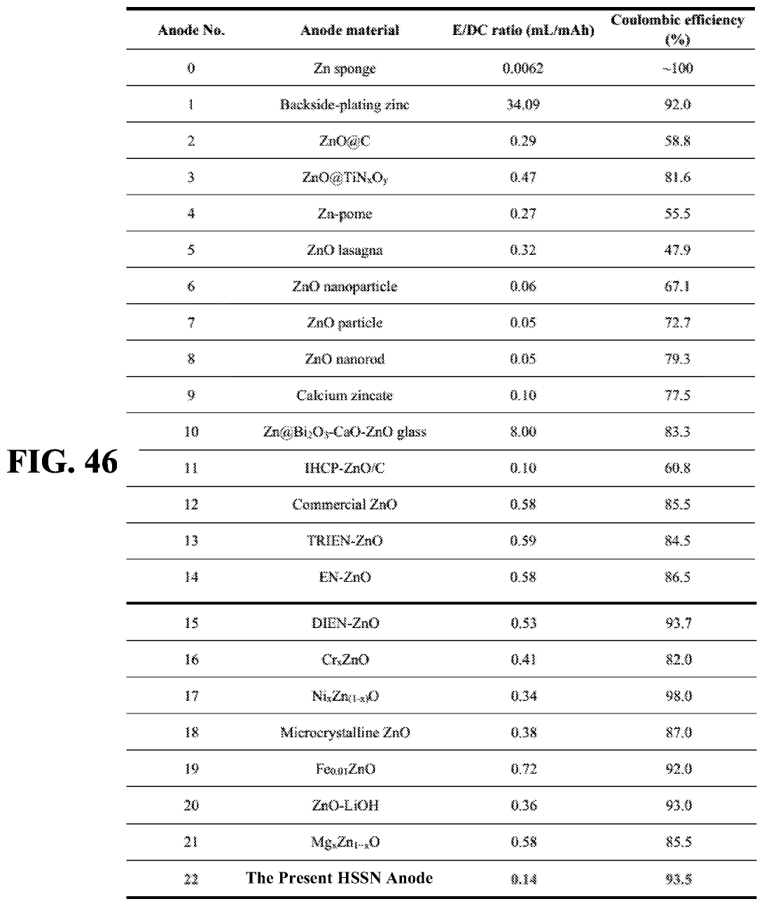

Electrolyte-to-discharge-capacity (E/DC) ratio is also critical for device-level energy density and is crucial for practical applications. The tested Coulombic efficiency of alkaline Zn anodes is highly correlated to the E/DC ratio. Thus, it is necessary to provide E/DC ratios to get a fair comparison on the Coulombic efficiency of different Zn anode materials. However, only a few previous works (summarized in the table of FIG. 46) reported this ratio or provided necessary information for its calculation.

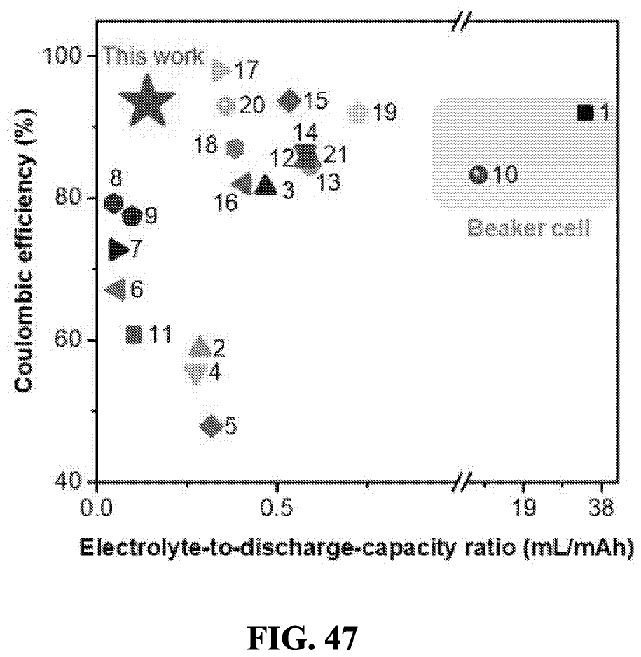

Prior results were summarized, and the anode compared with them in terms of Coulombic efficiency and E/DC ratio in FIG. 47. Notably, to get a comparison on “clean” Coulombic efficiency of different Zn anodes, only deeply cycled Zn anodes with 100% DOD are listed. Partially utilized (DOD<100%) metallic zinc anodes are not included in the comparison because their Coulombic efficiency cannot indicate the extent of side reactions occurring on Zn anodes.

In comparison, the present anode achieves a superior Coulombic efficiency (93.5%) at a low E/DC ratio (0.14 mL/mAh), which suggests the advance of the designed functionally coated Zn anodes (FIG. 37A). With the featured HER suppressing core/shell Zn anode: (1) Zn species are confined inside the shell so there is minimized active material loss; and (2) minimized HER and less electrolyte decomposition can be achieved with the HER suppressing property. These enable the present anode to achieve high Coulombic efficiency in lean electrolyte. The overall real and specific discharge capacities of the present HSSN anode were ˜0.9 mAh/cm² and ˜91 mAh/g, respectively, after considering the mass of the current collector. Due to its specially featured core/shell nanorod structure, its overall capacity was unable to meet design parameters for practical Zn anodes (11.7 mAh/cm²), however the present design principals achieves practically high energy-density Zn anodes.

The present zinc anode design, namely sealing sub-micron-sized ZnO with a HER suppressing and ion-sieving layer, to overcome simultaneously passivation, dissolution, and hydrogen evolution issues in alkaline electrolytes is disclosed. A ZnO nanorod anode and TiO₂ shell were chosen to demonstrate this concept. The fabricated HSSN anode achieves superior reversible deep cycling performance at lean electrolyte. While the Coulombic efficiency of the present HSSN anode is higher than that of most of the previously reported zinc anodes, it will be improved to approach the efficiency of LIBs (99.9%).

Optimization of the shell material, from aspects of pore size, porosity, and surface charge, leads to improvement of anode performance and stability. Other materials with controlled ion-sieving and HER suppressing properties have the potential to be applied as the shell material. This design principle can potentially be applied to other morphologies (e.g. particles) of starting materials for large scale production. The mechanistic understanding and design principle herein will also guide future design of other rechargeable high-energy aqueous batteries.

### Sealing ZnO Nanorods for Deeply Rechargeable High-Energy Aqueous Battery Anodes

As noted in the background, in aqueous alkaline electrolyte, a zinc anode undergoes two consecutive reactions: complexation (or dissolution) and electroreduction reactions in charging (shown in Equation 1: Complexation/Precipitation), and electrooxidation and precipitation reactions in discharging (shown in Equation 2: Electroreduction/Electrooxidation).

Different from conventional intercalation electrodes in lithium ion batteries, this solid-solute-solid (ZnO—Zn(OH)₄²⁻—Zn) transformation of zinc electrode inherently represents a series of challenges: (i) discharge product ZnO passivates the surface of Zn, preventing Zn from further discharging; (ii) ZnO is insulating, which can be hardly recharged to metallic Zn; and (iii) ZnO precipitation from soluble zincates occurs randomly on the electrode surface, and changes the morphology of electrode over cycling.

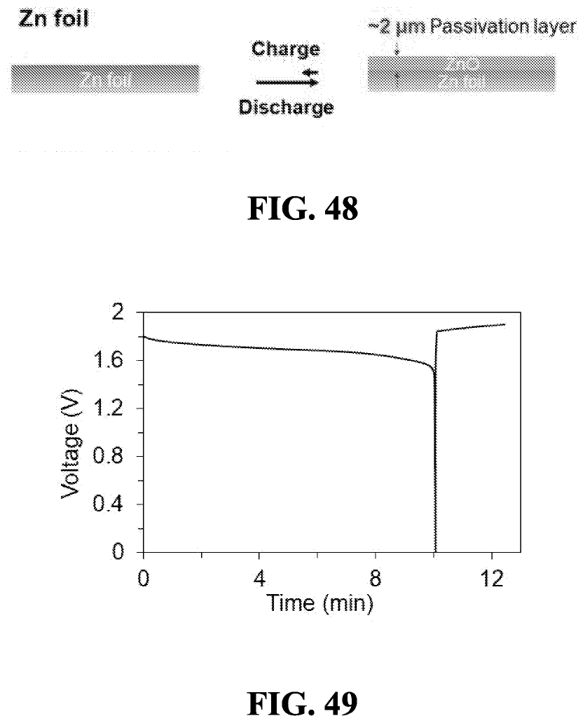

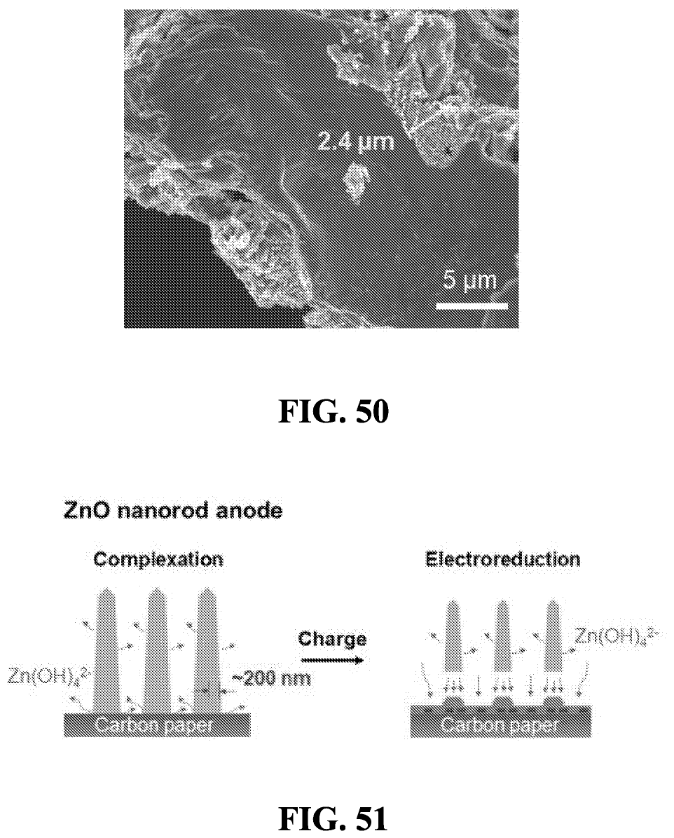

Zn metal foil is the most commonly used Zn anode in aqueous batteries. However, as exemplified in FIGS. 48-49, the passivation problem (nonconductive property of ZnO) of Zn foil limits the utilization (<approximately 1%) of Zn foil anode and makes it non-rechargeable. Under approximately 10 mA discharge, one can only get ˜1.7 mAh capacity of Zn foil with approximately 0.25 mm thickness and approximately 1 cm diameter in a coin cell. As shown in FIG. 50, the thickness of the passivation layer (or the critical passivation size) is ˜2 μm. Microporous Zn sponges are known, and enhance rechargeability, yet the Zn sponge feature size is ˜10 μm (greater than the critical passivation size of approximately 2 μm), so only approximately 40% DOD of them can be achieved.

As shown in FIG. 51, the feature size of an uncoated ZnO nanorod is smaller than the critical passivation size, however, the large electrode-electrolyte surface area accelerates anode dissolution and promotes electrode shape change. Moreover, due to the relatively insulating property of ZnO, electrons can only be distributed on carbon paper, which leads to fast complexation and electroreduction reactions on the root of nanorods in charging. As a result, the nanorods of FIG. 51 detach from carbon paper.

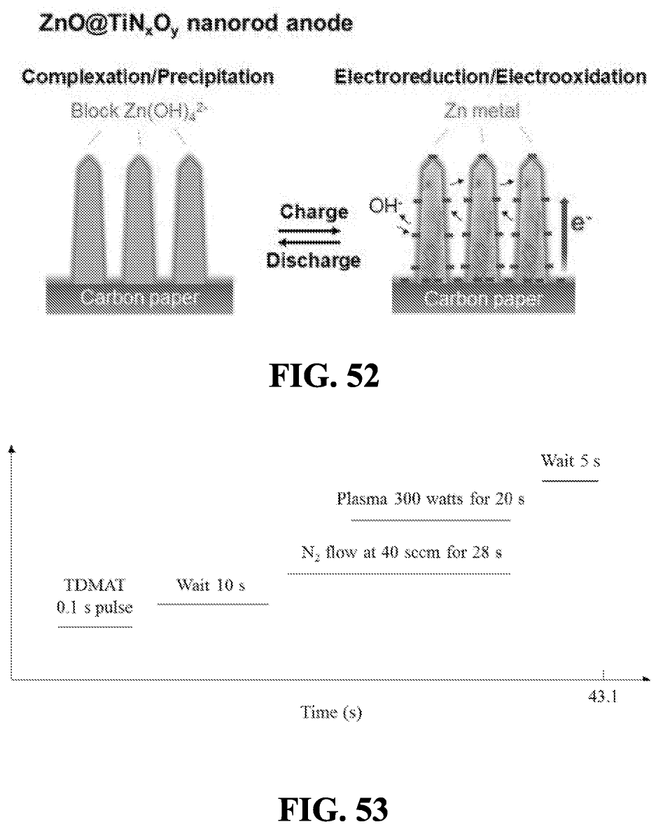

In an exemplary embodiment of the present invention as shown in FIG. 52, the conventional Zn anode dilemmas of passivation and dissolution are overcome with a sealed structure (ZnO@TiNₓO_{y} nanorod anode), with a feature size smaller than the critical passivation size, and a thin and conformal coating to limit/prevent dissolution of the anode.

A hydro-thermal method was used to grow ZnO nanorods on carbon fiber paper. Then, the ALD technique was used to form a strong and conductive stable TiNₓO_{y} coating on the ZnO nanorods. This structure has advantages that include: (i) the feature size of each ZnO nanorod is smaller than the critical passivation size; (ii) a carbon paper framework and TiNₓO_{y} coating, which encapsulates the ZnO nanorod, function as an electrical pathway so that all ZnO nanorods are electrochemically active; and (iii) the TiNₓO_{y} coating enables fast hydroxide/water diffusion as well as blocks large zincates from escaping during electrochemical cycling, thus effectively preventing anode structure fracture.

### Synthesis of ZnO Nanorods

Carbon paper (Fuel Cell Store) was first heat-treated at 500° C. for 1 hour in air to increase its wettability. Then, ZnO nanorods were grown on the carbon paper by a wet chemical process. First, carbon paper was soaked in an aqueous solution containing 0.1M KMnO₄ (Sigma Aldrich) for 1 hour to form a seed layer. Second, the seeded carbon paper was then dipped into a glass bottle with a precursor solution containing 50 mL zinc nitrate hexahydrate (30 mM, Alfa Aesar), 50 mL hexamethylene-tetramine (30 mM, Sigma Aldrich), and ammonia (28.0˜30.0% NH₃ basis, Sigma Aldrich).

Third, the sealed bottle was placed into an oven at 90° C. Next, the white-colored carbon paper ZnO nanorods were obtained by water washing and drying at 80° C. for 3 hours. As shown in TABLE 2, different mass loadings of ZnO nanorods on carbon paper ranging from 0.5 mg/cm² to 5.5 mg/cm² were synthesized by adjusting: the carbon paper area per bottle, the NH₃ concentration, the hydrothermal time, and the hydrothermal times.

TABLE 2

| | Carbon Paper | | | |
|---|---|---|---|---|
| Mass | Area Per | NH₃ | Hydrothermal | Hydrothermal |
| Loading | Bottle | Quantity | Time | Times |
| 0.5 mg/cm² | 2 × (2.1*6) cm² | 2 mL | 13 h | 1 |
| 0.9 mg/cm² | 1 × (2.1*6) cm² | 4 mL | 22 h | 1 |
| 5.5 mg/cm² | 1 × (2.1*6) cm² | 4 mL | 20 h | 2 |

### Synthesis of ZnO@TiNₓO_{y} Core/Shell Nanorods

The synthesis of ZnO@TiNₓO_{y} core/shell nanorods was conducted in Cambridge FIJI Plasma ALD system. First, the TiN was deposited onto the ZnO nanorods. The precursors of TiN were Tetrakis(dimethylamido)Titanium(IV) (TDMAT, Sigma Aldrich) and N₂. During the TiN ALD process, the recipe was run 100 or 200 cycles at 250° C. The TiN ALD recipe is shown in FIG. 53. Then, when the ZnO@TiN nanorods were exposed to air, the TiN was partially oxidized to TiNₓO_{y} (evidenced by XPS spectra in FIG. 67). Thus, for accuracy purpose, the anode is termed throughout as ZnO@TiNₓO_{y}.

### Electrochemistry

To investigate the Zn anode, full batteries were made using Ni(OH)₂ as the rechargeable cathode. The Ni(OH)₂ cathodes were harvested from commercial Ni—Zn AA batteries from PowerGenix.

### Coin Cell

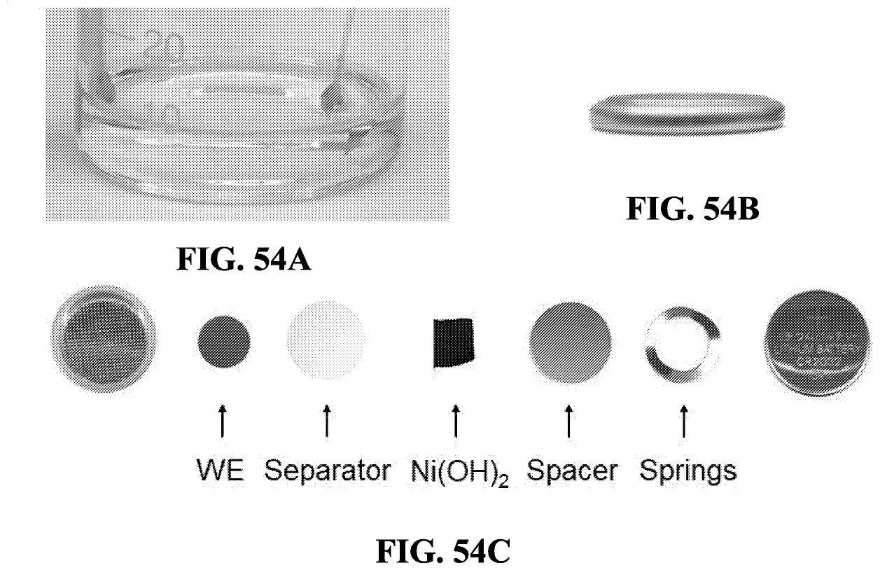

Coin-type batteries were assembled using CR2032 cases (MTI Corporation), the present zinc anodes (round disk, approximately 1 cm diameter) and Ni(OH)₂ cathodes with excess capacity, as shown in FIGS. 54A-54C. The coin cell has a small volume of electrolyte, which is required for practical application. The aqueous electrolyte comprises 4M KOH (Sigma Aldrich, 99.99%), 2M KF (Alfa Aesar, 99.99%) and 2M K₂CO₃ (Alfa Aesar, 99.997%). Glass fiber (GE Healthcare, Whatman™ 10370003) was used as the separator.

For start-stop operation, the ZnO@TiNₓO_{y} nanorod anode and Zn foil were pre-activated. The ZnO@TiNₓO_{y} nanorod anode was pre-cycled three times at 0.5 C between approximately 1.4 and 2 V. The Zn foil (approximately 0.02% DOD) was firstly discharged for 2 hours and re-charged for 2 hours at a constant current of approximately 1.35 mA. Then it was discharged twice and charged once at the same time interval of 1 hour at approximately 1.35 mA.

The Zn foil (approximately 1% DOD) was pre-cycled twice at a constant current of approximately 1 mA. When the Zn foil was used as the anode, the cathode harvested from commercial Ni—Zn AA batteries was electrochemically oxidized to approximately 0.6 V vs an HgO/Hg reference electrode in a beaker cell with 2M KOH as the electrolyte.

### Pouch Cell

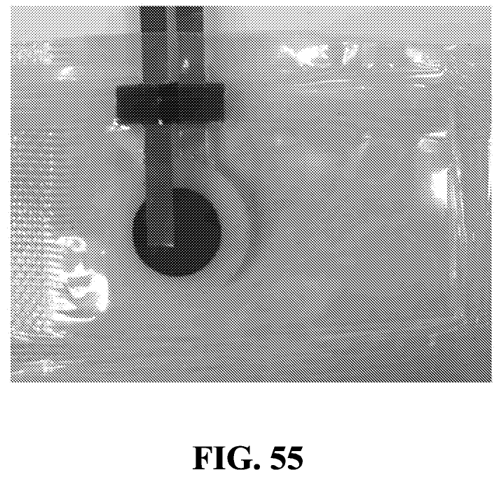

Pouch-type batteries (FIG. 55) were assembled using Ampac's SealPAK, the present zinc anodes (round disk, approximately 1 cm diameter) and Ni(OH)₂ cathodes with excess capacity. The aqueous electrolyte comprises 4M KOH (Sigma Aldrich, 99.99%), 2M KF (Alfa Aesar, 99.99%) and 2M K₂CO₃ (Alfa Aesar, 99.997%). Celgard 3501 (close to anode) and Freudenberg 700/28K (close to cathode) were used as the separators.

### Beaker Cell

Beaker-type batteries (FIG. 54A) were assembled using beakers, the present zinc anodes (round disk, 1 cm diameter) and Ni(OH)₂ cathodes with excess capacity. The electrolyte was 10 mL ZnO saturated 4M KOH (Sigma Aldrich).

EIS measurements were performed on a Bio-Logic instrument. The frequency range was between 100 KHz and 10 mHz. The amplitude of the AC signal was approximately 10 mV. Coin-type batteries assembled using the present zinc anodes and Ni(OH)₂ cathodes were used to measure EIS. 100 μL 4M KOH, 2M KF and 2M K₂CO₃ electrolyte was added to a glass fiber separator.

### Results and Discussion

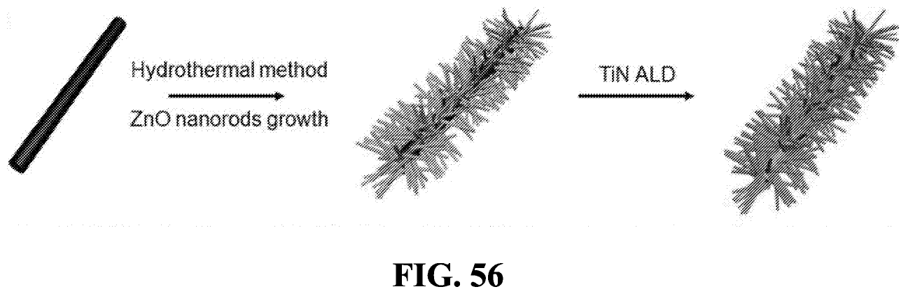

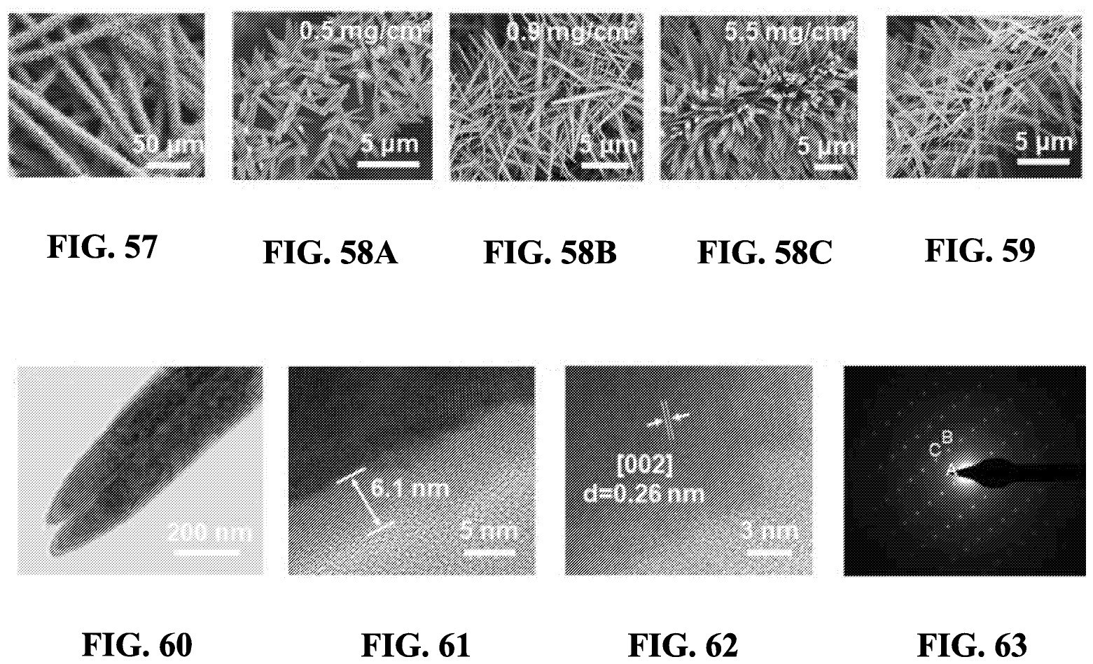

ZnO nanorods are synthesized on carbon paper with mass loading ranging from approximately 0.5 to approximately 5.5 mg/cm² (FIGS. 56-58C) by adjusting the area of carbon paper placed in hydrothermal reactor, NH₃ concentration, hydrothermal time, etc. (TABLE 1). In the ALD process (FIG. 53), the recipe was run 100 or 200 cycles. The TiNₓO_{y} mass loadings of 100 cycles and 200 cycles are approximately 0.057 mg/cm² and approximately 0.19 mg/cm², which are only approximately 0.6 wt % and approximately 1.9 wt % of ZnO@TiNₓO_{y} nanorod anode, respectively (for approximately 3 mg/cm² ZnO nanorods).

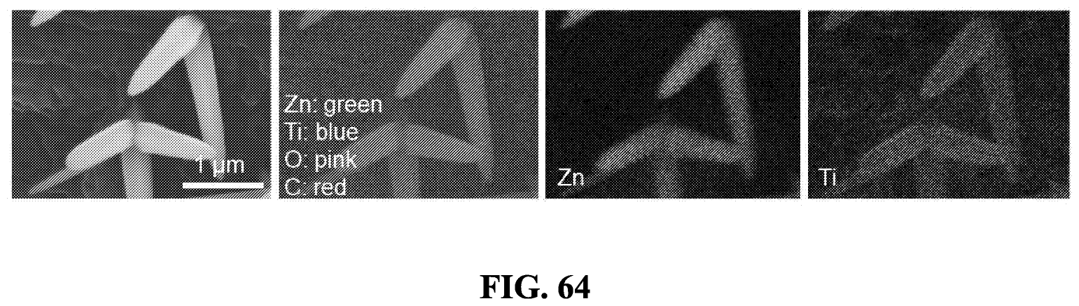

The nanorod morphology does not change after TiNₓO_{y} coating (FIGS. 59 and 64). HRTEM images show uniform TiNₓO_{y} coating with a thickness of approximately 6.1 nm for ZnO@TiNₓO_{y} nanorod with 100 cycles ALD (FIGS. 60-61). ZnO nanorod is hexagonal and TiNₓO_{y} coating is amorphous, which are evident from TEM (FIGS. 62-63) and XRD results (FIG. 76).

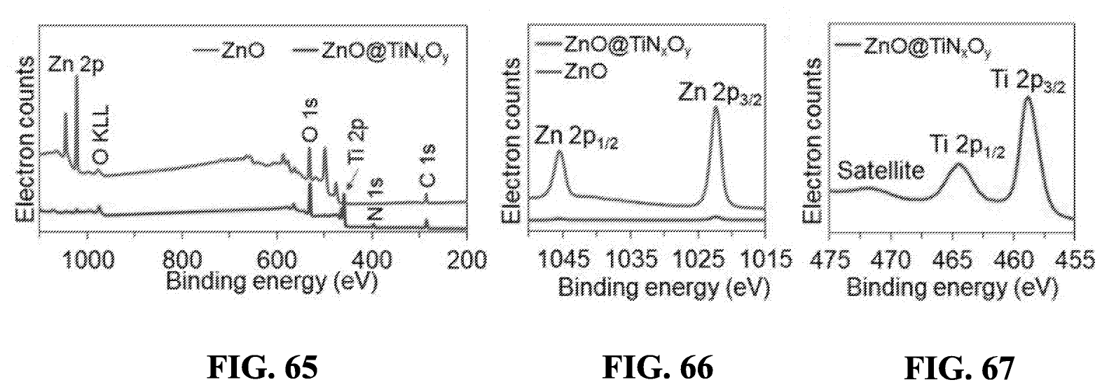

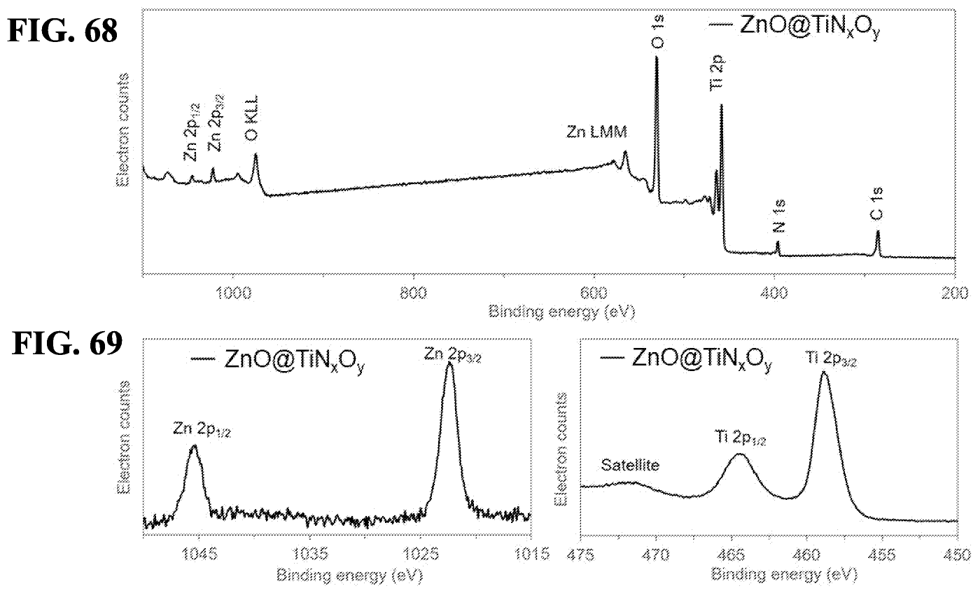

In addition to TEM, XPS results also indicate complete coverage of TiN_{X}O_{y} on ZnO (FIGS. 65-66 and 68-69), which is important for encapsulating zincate during cycling. Besides, nitrogen peak in the XPS survey spectra (FIG. 65) and three Ti 2 p peaks in the high-resolution XPS spectra (FIG. 67), which belong to TiO₂, indicate that ALD TiN is partially oxidized to TiNₓO_{y}.

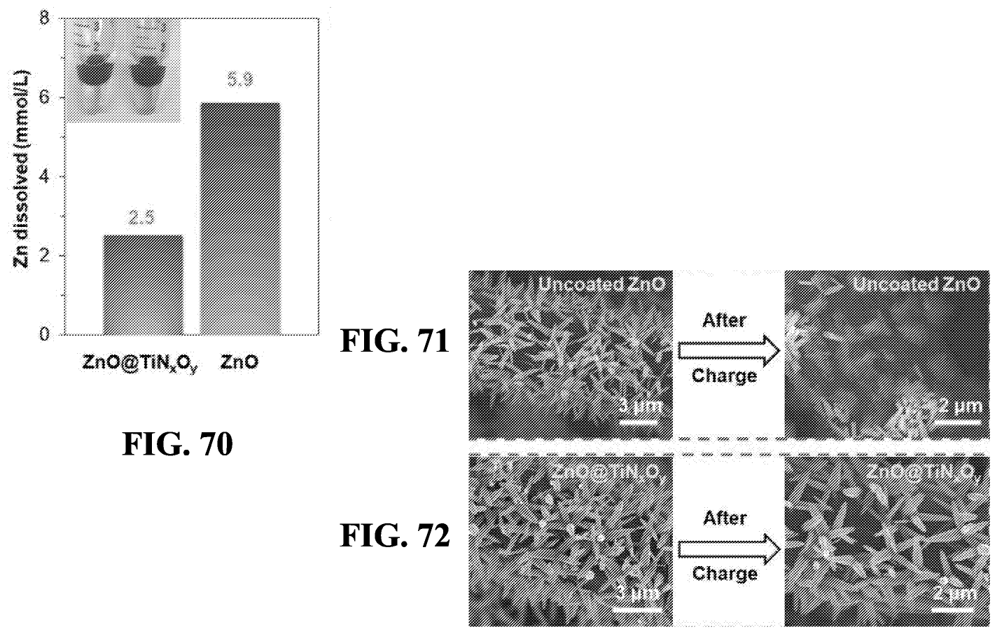

The TiNₓO_{y} coating, although only a few nanometers thick, firmly supports the ZnO nanorod, blocks zincates, and enables OH⁻/H₂O to pass through. As shown in FIG. 70, a ZnO@TiNₓO_{y} anode and an uncoated ZnO anode (1 cm diameter disk) were soaked into two tubes with 2 mL 4M KOH solution, respectively. Then the dissolved Zn concentration was measured in both solutions using ICP atomic emission spectroscopy (ICP-AES). The dissolved Zn of the ZnO@TiNₓO_{y} anode is much lower than that of the uncoated ZnO anode, which means that TiNₓO_{y} coating effectively blocks zincates. Furthermore, coin cells were assembled with these two anodes and Ni(OH)₂ cathodes to investigate the influence of the TiNₓO_{y} coating during electrochemical cycling.

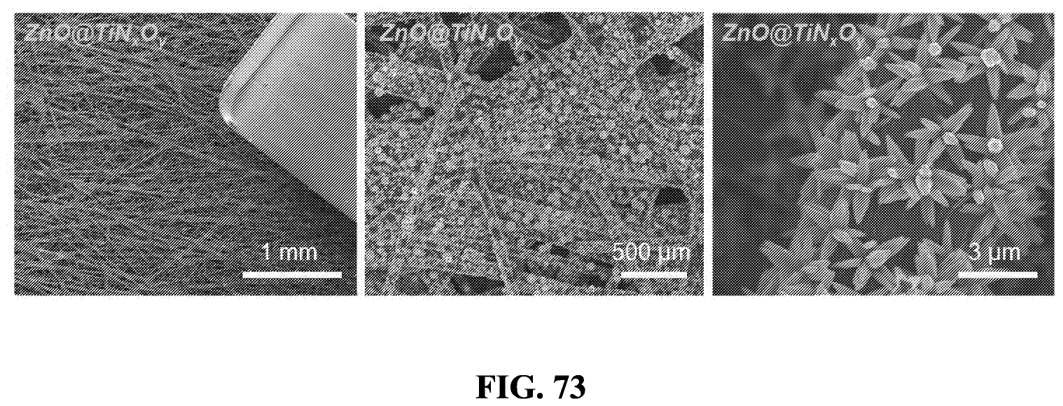

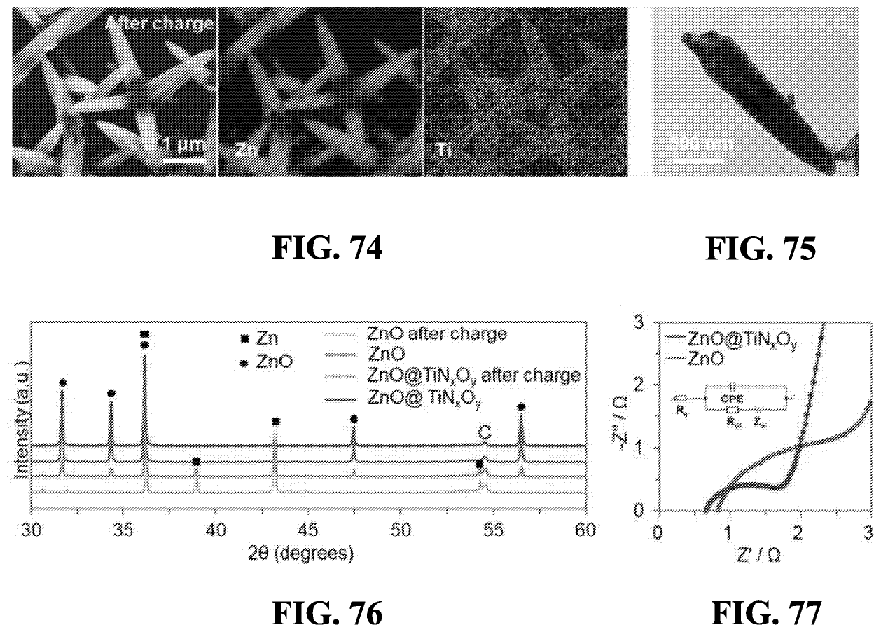

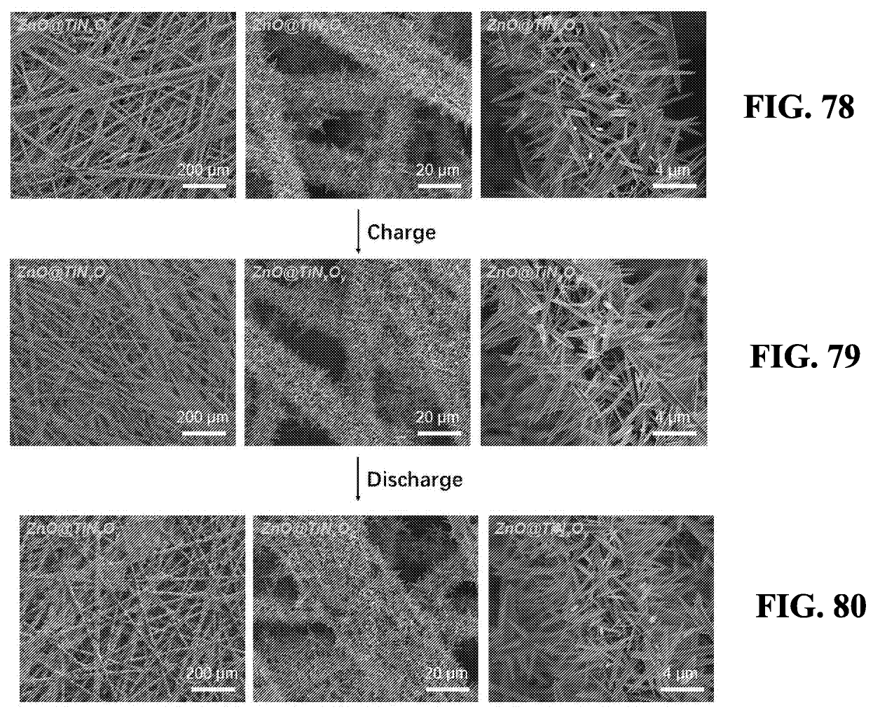

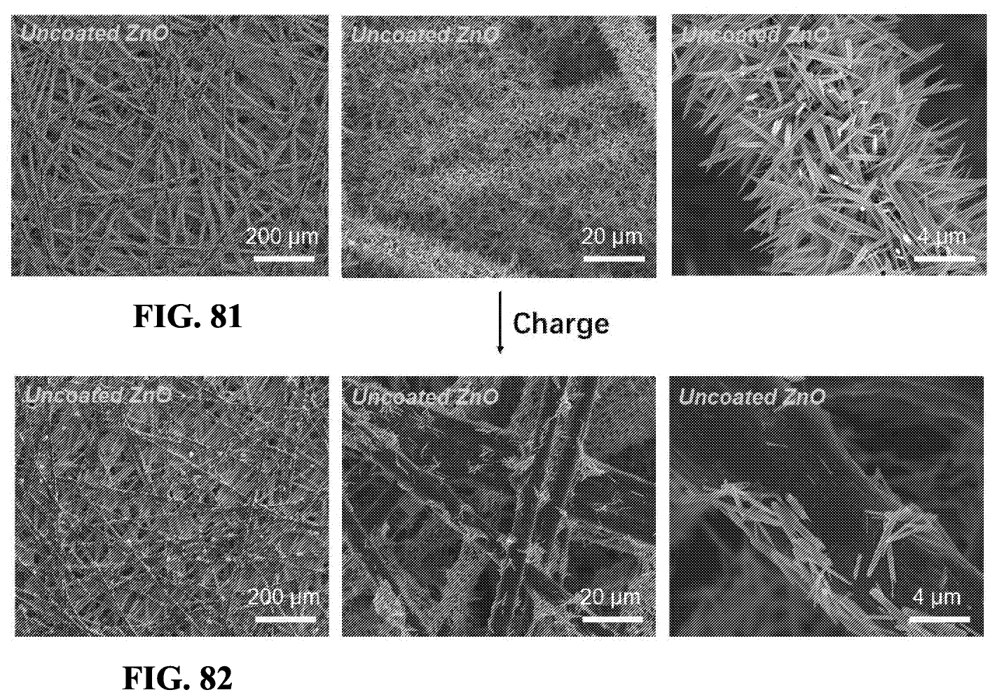

After 2 hours of charge (1 hour constant current at 1 C rate, and 1 hour constant voltage at 1.93 V), the uncoated ZnO nanorod anode shows severely morphological degradation, almost all ZnO nanorods detach from carbon paper because of dissolution (FIG. 71). On the other hand, there is no obvious shape change for the ZnO@TiNₓO_{y} nanorod anode with 100 cycles ALD (FIG. 72). ZnO@TiNₓO_{y} nanorod anode with 200 cycles ALD maintained its morphology after charging as well (FIG. 73). Additional SEM images, elemental mapping (FIG. 74), TEM image (FIG. 75), and Zn peaks in XRD results (FIG. 76) all support that the TiNₓO_{y} coating confined zinc active material inside, while still allowing it to participate in electrochemical reaction. The mass loading of the ZnO nanorods shown in FIGS. 71-72 and 74-75 is approximately 0.5 mg/cm². For longer nanorods with higher mass loading (˜1.7 mg/cm²), there is also no apparent shape change of ZnO@TiNₓO_{y} nanorod anode after the first charge and discharge (FIGS. 78-80), while ZnO nanorod anode shows severe structure degradation after the first charge (FIGS. 81-82).

EIS was also employed to investigate the electrochemical influence of conductive TiNₓO_{y} coating. As shown in the Nyquist plot (FIG. 77) and equivalent circuit (Randles-Ershler impedance), the charge-transfer resistance (R_{ct}) of the ZnO@TiNₓO_{y} nanorod anode is much lower than that of the uncoated ZnO anode. This can be attributed to the good conductivity of TiNₓO_{y} and the high zincate concentration inside the TiNₓO_{y} coating.

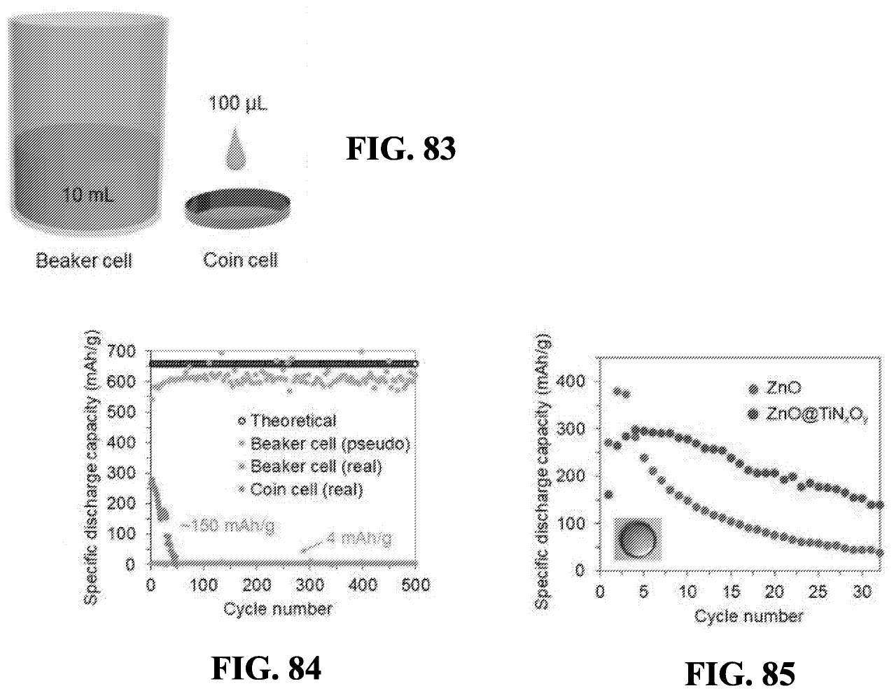

Zinc anodes were tested in coin-type cells with lean zinc-free electrolyte here to evaluate their real performance (FIGS. 54A-C), which is different from most of previous investigations using beaker cells with a large amount of ZnO saturated electrolyte. When testing the performance of zinc anodes in ZnO saturated electrolyte, all the zincates in the electrolyte could also participate in electrochemical reactions and contribute capacity in addition to the Zn in the anode. However, most previous works reported their specific capacity without counting Zn in the electrolyte, which gives pseudo performance. In an extreme case, even if there is no active material in the anode, only a pure current collector can cycle in ZnO saturated electrolyte. Here two pure carbon fiber paper substrates (1 cm diameter disk) were tested in a beaker cell with 10 mL ZnO saturated 4M KOH electrolyte and a coin cell with 100 μL ZnO saturated 4M KOH electrolyte (FIG. 83), respectively. They were both cycled at approximately 1 mA with a limiting charge capacity of approximately 1 mAh and cut-off voltage of approximately 1.4/2 V.

The theoretical specific capacity of ZnO is approximately 658 mAh/g. As shown in FIG. 84, if zinc in the electrolyte is not counted, the pure current collector without any active material in the beaker cell can show excellent cycling performance with a pseudo specific discharge capacity of approximately 600 mAh/g (assuming there is approximately 1.5 mg ZnO on the anode, which has approximately 1 mAh theoretical capacity). However, when zinc in the electrolyte (see TABLE 3 for equivalent ZnO mass) is counted, the real specific discharge capacity in the beaker cell is only approximately 4 mAh/g, while that in the coin cell is approximately 150 mAh/g. These results show that testing zinc anodes in beaker cells with a large amount of ZnO saturated electrolyte will dramatically decrease the overall specific energy.

When testing zinc anodes in beaker cells with 10 mL ZnO saturated 4M KOH electrolyte, electrolyte can contribute a large capacity, which is 100 times that of in coin cells with 100 μL electrolyte (TABLE 3). With this big contribution, it is hard to evaluate the true performance of zinc anodes with less amount of active materials. Coin-type cells use minimum amount of electrolyte and have a higher volumetric capacity compared with beaker cells, which is a better testing choice even though the testing environment is harsh.

TABLE 3
Calculation Of Equivalent ZnO Quantity And Capacity

| | Large Amount Of | | | |
|---|---|---|---|---|
| System | Electrolyte | | Lean Electrolyte | |
| Test equipment | Beaker cell | | Coin cell | |
| Volume of electrolyte | 10 | mL | 100 | μL |
| Electrolyte | ZnO saturated 4M KOH | | ZnO saturated 4M KOH | |
| Zincate concentration | 0.256 | mol/L (*) | 0.256 | mol/L (*) |
| Amount of zinc | 0.00256 | mol | 0.0000256 | mol |
| Mass of equivalent ZnO | 208 | mg (**) | 2.08 | mg (**) |
| Capacity contributed by electrolyte | 137 | mAh | 1.37 | mAh |
| Effect of zinc deposition from | Big | | Small | |
| electrolyte on anode shape change | | | | |

(*) ICP Emission Spectroscopy result.
(**) used to make FIG. 84.

Moreover, it is hard to evaluate the true performance of anodes with a lot of capacity contributed from electrolyte. Coin-type cells use a minimum amount of electrolyte and have a higher volumetric capacity compared with beaker cells, which is closer to practical operating conditions. Thus, even though the coin cell with lean electrolyte is an extremely harsh testing environment (˜25 cycles), that was the choice made for this testing. To evaluate the true performance of anodes, ZnO-free electrolytes were used because capacity contributed by electrolytes could cause an unrealistically high capacity of anodes. 4M KOH, 2M KF and 2M K₂CO₃ was selected as the electrolyte if not otherwise stated because it has lower Zn(OH)₄²⁻ solubility and thus less shape change than 4M KOH as evidenced by ICP results shown in TABLE 4.

ICP Emission Spectroscopy results below indicate that an electrolyte comprising 4M KOH, 2M KF and 2M K₂CO₃ has a lower Zn(OH)₄²⁻ solubility than 4M KOH electrolyte.

TABLE 4
ICP Results of Zn(OH)₄²⁻ Solubility In Different Electrolytes

| Electrolyte | Zincate Concentration (mol/L) |
|---|---|
| ZnO saturated 4M KOH | 0.256 |
| ZnO saturated 4M KOH + | 0.168 |
| 2M KF + 2M K₂CO₃ | |

As shown in FIG. 85, the ZnO@TiNₓO_{y} nanorod anode affords remarkable battery performance in a lean electrolyte configuration even with a high mass loading of active materials (˜2.1 mg/cm²). The coin cells are galvanostatically deep-cycled to approximately 100% state of charge (SOC) with approximately 1.5 and 1.9 V as cut-off voltages. The gravimetric capacity or the specific capacity was limited to the theoretical capacity of ZnO (approximately 658 mAh/g). The reversible discharge capacity of the ZnO@TiNₓO_{y} nanorod anode at the tenth galvanostatic cycle is approximately 279 mAh/g, which is twice as large as that of an uncoated ZnO nanorod anode (approximately 148 mAh/g) at a rate of C/2. The discharge capacity of the ZnO@TiNₓO_{y} nanorod anode decays to below approximately 150 mAh/g after 30 cycles, versus only 9 cycles for uncoated ZnO nanorod anode.

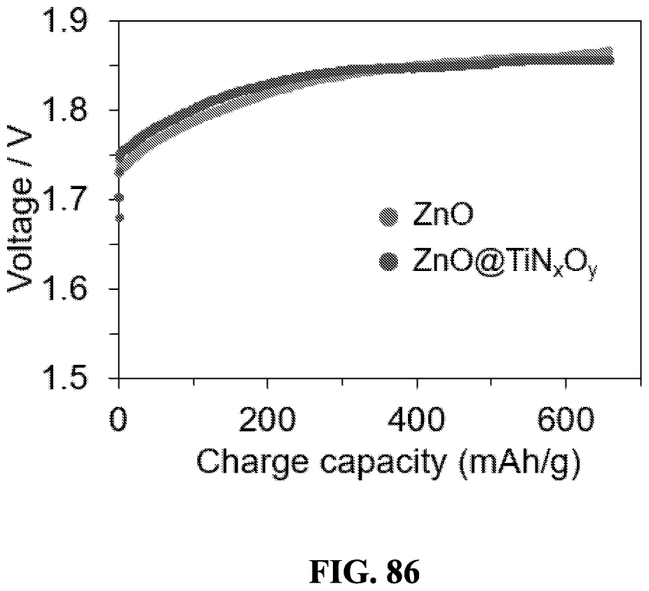

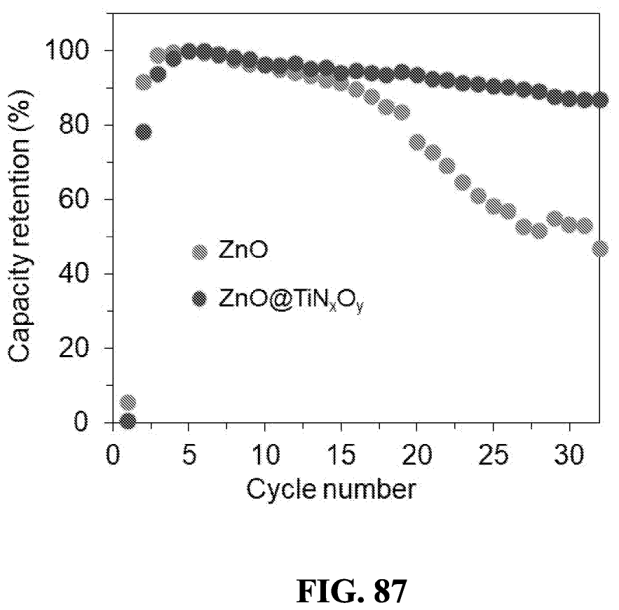

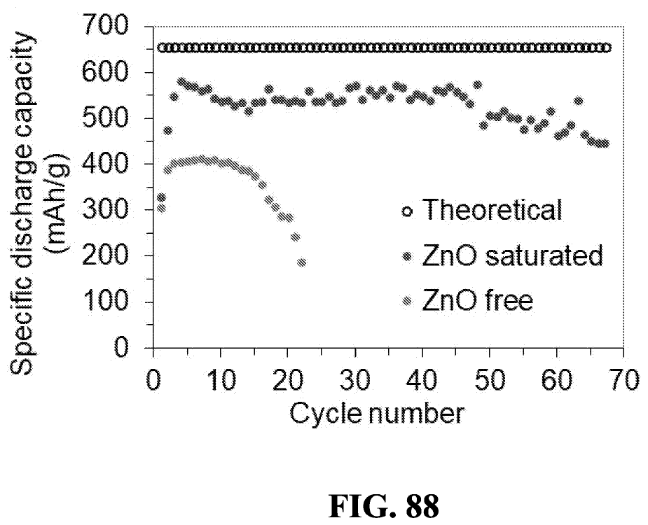

For the ZnO@TiNₓO_{y} anode, the TiNₓO_{y} coating did not change the over-potential of the ZnO anode with almost the same charge profile as the uncoated ZnO (FIG. 86). Cycled at a lower rate (C/4) with approximately 50% SOC, the capacity difference between coated and uncoated ZnO nanorod anodes in initial cycles is small, yet the ZnO@TiNₓO_{y} nanorod anode shows better capacity retention than uncoated ZnO nanorod anode (FIG. 87). The discharge capacities of uncoated and sealed ZnO nanorod anodes decay to approximately 50% after 31 and 53 cycles, respectively. To probe the behavior of ZnO over cycling, the electrodes were imaged after three galvanostatic cycles at 0.33 C. As can be seen in FIG. 88, the ZnO@TiNₓO_{y} nanorod anode keeps its original morphology after cycling, whereas almost no nanorods can be found on the carbon paper for the uncoated ZnO nanorod anode.

The superior performance of ZnO@TiNₓO_{y} nanorod anode can be attributed to the small feature size of ZnO and conformal TiNₓO_{y} coating. Below the critical passivation thickness, the anode passivation problem is nearly if not fully eliminated. The TiNₓO_{y} coating serves as an electrical pathway, confines large zincate molecules, yet allows OH⁻ and water to pass. As a mechanical backbone, the TiNₓO_{y} coating protects ZnO nanorods from detaching from the carbon paper substrate, and thus provides a short zincate mass transfer path for the reaction.

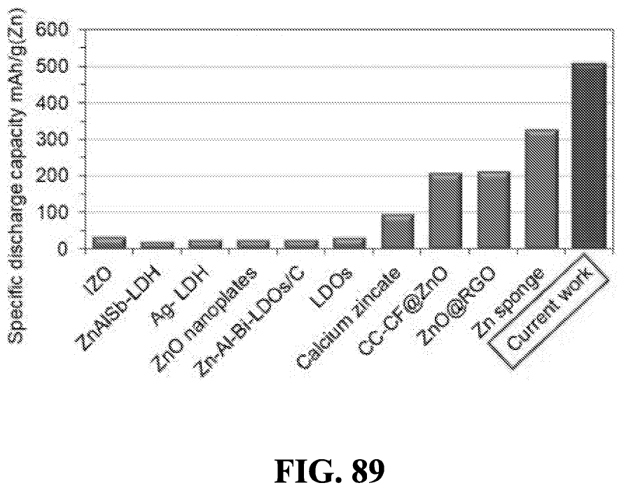

Without a TiNₓO_{y} coating, the ZnO nanorod will detach from substrate upon charging (FIG. 89). This on one hand leads to a much slower mass transport for electrically disconnected ZnO to dissolve in electrolyte to form zincate and then diffuse to current collector. On the other hand, detached ZnO or dissolved zincate may migrate far from anode and never participate in further cycling. Both mechanisms will cause capacity decay over cycling. The utilization of Zn could be potentially modeled by quantitative comparison of electroreduction rate and mass transfer rate of Zn(OH)₄²⁻.

The ZnO@TiNₓO_{y} nanorod anode was also tested in pouch cell with a ZnO-free electrolyte (FIG. 88). It achieves a specific discharge capacity of approximately 408 mAh/g (based on ZnO if not otherwise stated), which is 508 mAh/g(Zn). As shown in FIG. 89, the present ZnO@TiNₓO_{y} nanorod anode demonstrates a much higher specific capacity than that of many previously reported zinc anodes shown in TABLE 5.

TABLE 5
Comparison Of Specific Discharge Capacity Between The
Present Invention And Previously Reported Anodes

| | | | | | | Reported | Real |
|---|---|---|---|---|---|---|---|
| Anode | Cell | | Mass | | ZnO | Capacity | Capacity |
| Material | Structure | Electrolyte | Loading | | wt % | (mAh/g) | (mAh/g(Zn))^{c} |
| In doped | — ^{a} | 4.5M KOH, | 10 | mg * | 0.98 | 569 | 32.56 |
| ZnO (IZO) | | 1.0M NaOH, | | | | | |
| | | 0.5M LiOH, | | | | | |
| | | saturated with | | | | | |
| | | ZnO | | | | | |
| ZnO | — ^{a} | 4M KOH, 1.6M | 10 | mg * | 1.00 | 420 | 24.01 |
| Nanoplates | | K₂BO₃, 0.9M | | | | | |
| | | KF, 0.1M | | | | | |
| | | LiOH, saturated | | | | | |
| | | with ZnO | | | | | |
| Calcium | Sandwich | 4M KOH, | 10 | mg * | 0.64 | 230 | 95.54 |
| Zincate | cell ^{b} | saturated with | | | | | |
| | | ZnO | | | | | |
| ZnO@RGO | Sandwich | 6M KOH, | 10 | mg * | 0.90 | 510 | 211.85 |
| | cell ^{b} | saturated with | | | | | |
| | | ZnO | | | | | |
| CC—CF@ZnO | Sandwich | 2M KOH, | 0.6 | mg/cm⁻² | 1 | 500 | 207.69 |
| | cell ^{b} | saturated with | | | | | |
| | | ZnO | | | | | |
| Zn Sponge | 3D | 4M KOH, 1M | — | | 0.48 | 328 | 328.00 |
| | printed | LiOH | | | | | |
| | cell | | | | | | |
| Zn—Al—Sb— | — ₐ | 6M KOH, | 10 | mg * | 0.81 | 328 | 18.91 |
| LDH | | saturated with | | | | | |
| | | ZnO | | | | | |
| Zn—Al—Bi— | — ^{a} | 6M KOH, | 9 | mg | 0.73 | 475 | 24.83 |
| LDOs/C | | saturated with | | | | | |
| | | ZnO | | | | | |
| LDOs | — ^{a} | 6M KOH, | 10 | mg | 0.91 | 540 | 31.00 |
| | | saturated with | | | | | |
| | | ZnO | | | | | |
| Ag-LDH | — ^{a} | 6M KOH, | 10 | mg * | 0.85 | 400 | 23.02 |
| | | saturated with | | | | | |
| | | ZnO | | | | | |

a: The cell structure and electrolyte quantity were not reported. It is assumed 10 mL electrolyte was used in beaker cells. Based on ICP result, the equivalent ZnO mass is approximately 208 mg.

b: Sandwich cell: anode, separator, and cathode were packed. The electrolyte quantity was not reported. It is assumed that the capacity contributed by ZnO saturated electrolyte was 2 times of that contributed by anodes.

c: Zinc in the electrode and electrolyte are both counted.

*: The mass loading was not reported. For calculation, it is assumed the mass of materials is 10 mg.

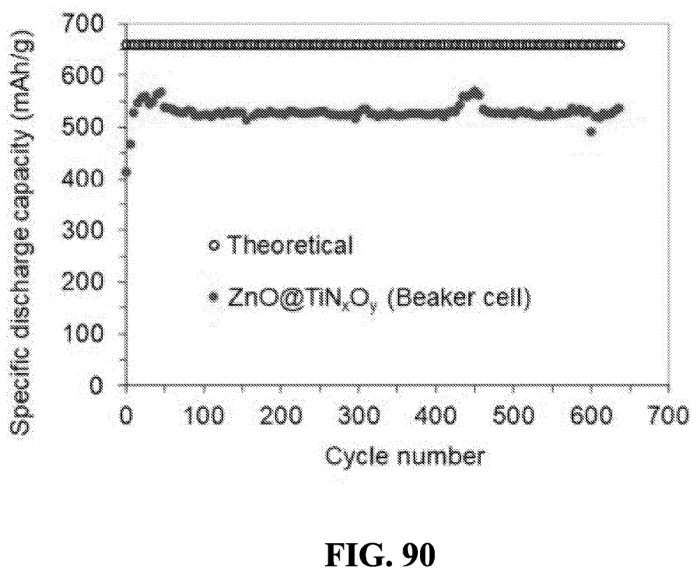

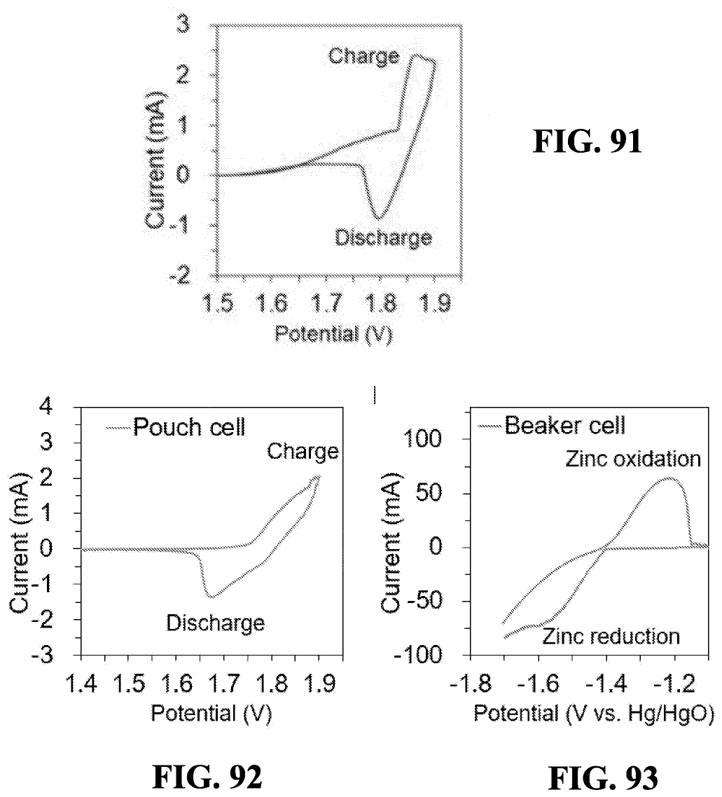

The ZnO@TiNₓO_{y} nanorod anode was also tested in a beaker cell (FIG. 90) and pouch cell (FIGS. 55 and 88) with ZnO saturated electrolyte, which achieves a discharge capacity of ˜550 mAh/g for >640 cycles (64 days) and 50 cycles, respectively. FIG. 91 shows the CV of the ZnO@TiNₓO_{y} nanorod anode in a coin cell with ZnO free electrolyte. The CV of the ZnO@TiNₓO_{y} nanorod anode in pouch and beaker cells is shown in FIGS. 92-93.

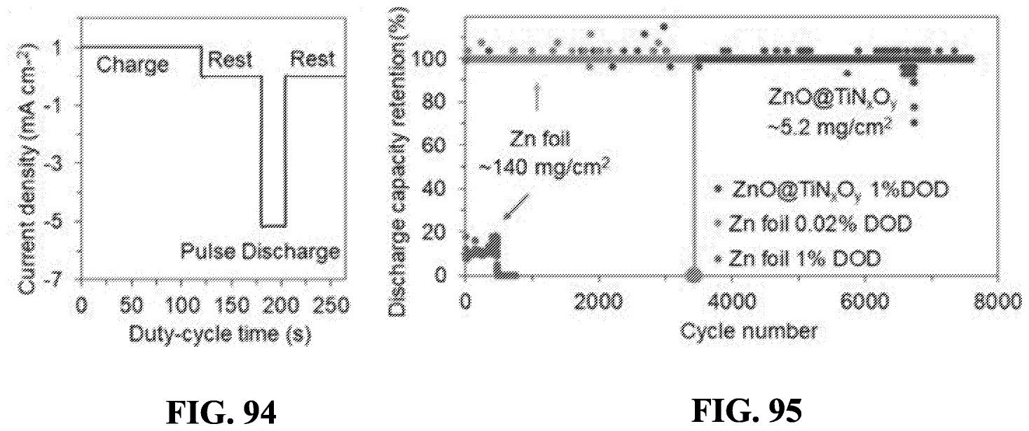

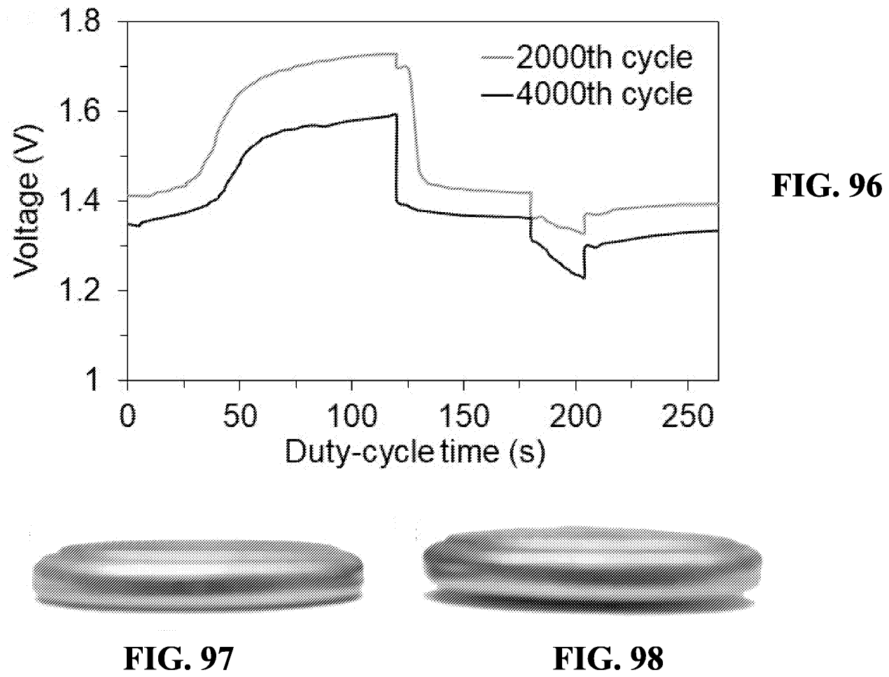

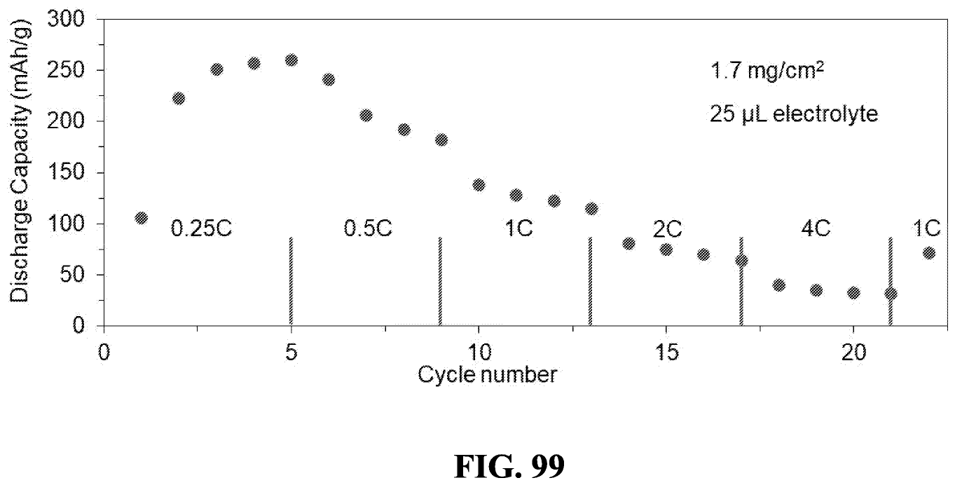

In addition, the ZnO@TiNₓO_{y} nanorod anode has excellent performance under start-stop operations, demonstrating potential to replace lead acid batteries in micro-hybrid vehicles. Engine restart, rest and pulse discharge are involved in the start-stop operation. The procedure of a test is showed in FIG. 94. The capacity of ZnO@TiNₓO_{y} nanorod anode was kept at approximately 1% DOD per duty cycle. The ZnO@TiNₓO_{y} nanorod anode maintained 100% discharge capacity for more than 7500 cycles (FIG. 95) at approximately 1% DOD. Voltage profile of the ZnO@TiNₓO_{y} nanorod anode is shown in FIGS. 96-98. Under the same current density (FIG. 95), the Zn foil died after 3400 cycles, which is less than half of cycle number of ZnO@TiNₓO_{y} nanorod anode, even though the DOD of Zn foil is only approximately 0.02% ( 1/50^{th} of that of ZnO@TiNₓO_{y} nanorod anode). This Zn foil cell died with a sudden voltage drop to <0 V because Zn is completely passivated by ZnO. And the cell was severely swelled, possibly due to accumulation of hydrogen evolved on the anode (FIGS. 96-98). Severe hydrogen evolution occurs after the passivation of Zn anode. The cell with a ZnO@TiNₓO_{y} nanorod anode only slightly swelled, which indicated less side reaction and higher utilization of zinc. Less swelling further indicates the present ZnO@TiNₓO_{y} nanorod anode does not passivate and retains its activity over thousands of cycles. Zn foil start stop performance was tested with approximately 1% DOD at the same time interval as shown in FIG. 94, which showed dramatically discharge capacity decay (FIG. 95). This result indicates the high stability of ZnO@TiNₓO_{y} nanorod anode. The ZnO@TiNₓO_{y} nanorod anode also demonstrated stable cycling at different cycling rates from 0.25 C to 4 C in FIG. 99.

The ZnO@TiNₓO_{y} nanorod anode achieves very high specific discharge capacity and superior reversibility when testing in a coin cell with lean ZnO-free electrolyte. In commercial PowerGenix AA batteries, which are made of a Zn metal anode and NiOOH cathode, the discharge capacity decayed to approximately 50% of its initial capacity after only 9 cycles (0.5 C, 20° C., charged to approximately 105% theoretical capacity). NiOOH cathodes are very reversible, and the Zn anode is the main cause of the poor reversibility.

The present ZnO@TiNₓO_{y} core/shell nanorod anode structure successfully overcomes problems of ZnO passivation and zincate dissolution simultaneously, and significantly improves the cycle life of Zn anode. Because electrolyte consumption and bubble accumulation resulted from hydrogen evolution side reaction, anodes degraded ultimately when cycled in coin cells with lean electrolyte. This can be further improved by coating hydrogen evolution suppressive materials. In addition, the mechanistic understanding and design principles provide guidance to future designs of zinc and other metal anodes (e.g. Li, Na, Mg, Ca), and a path towards rechargeable Zn-air aqueous batteries and other rechargeable, high-energy and safe batteries.

### A Deeply Rechargeable Zinc Anode With Pomegranate-Inspired Nanostructure for High-Energy Aqueous Batteries

Also, some zinc battery systems using mild electrolytes, such as ZnSO₄-MSO₄ (M=Mn, Co), Zn(CF₃SO₃)₂—Mn(CF₃SO₃), and Zn(TFSI)₂—LiTFSI, in which expensive TFSI salts should be replaced with salts having lower costs, were developed to mitigate the zinc dendritic growth effectively. Nevertheless, the reversibility of a zinc anode in alkaline electrolyte is a great concern to exploit some highly rechargeable Zn-air batteries with high specific energy density (5200 Wh/kg).

To tackle the long-standing challenges of a completely rechargeable Zn anode in a limited quantity of electrolyte, in another exemplary embodiment of the present invention, the present invention comprises a ZnO pomegranate (Zn-pome) material in which the zinc oxide nanoparticles (ZnO NPs) are analogous to seeds that are individually encapsulated and held in clusters by a carbon shell diaphragm. The carbon shell coating on the nanoparticles was chosen for its porosity, stability in aqueous alkaline media, and electroconductivity.

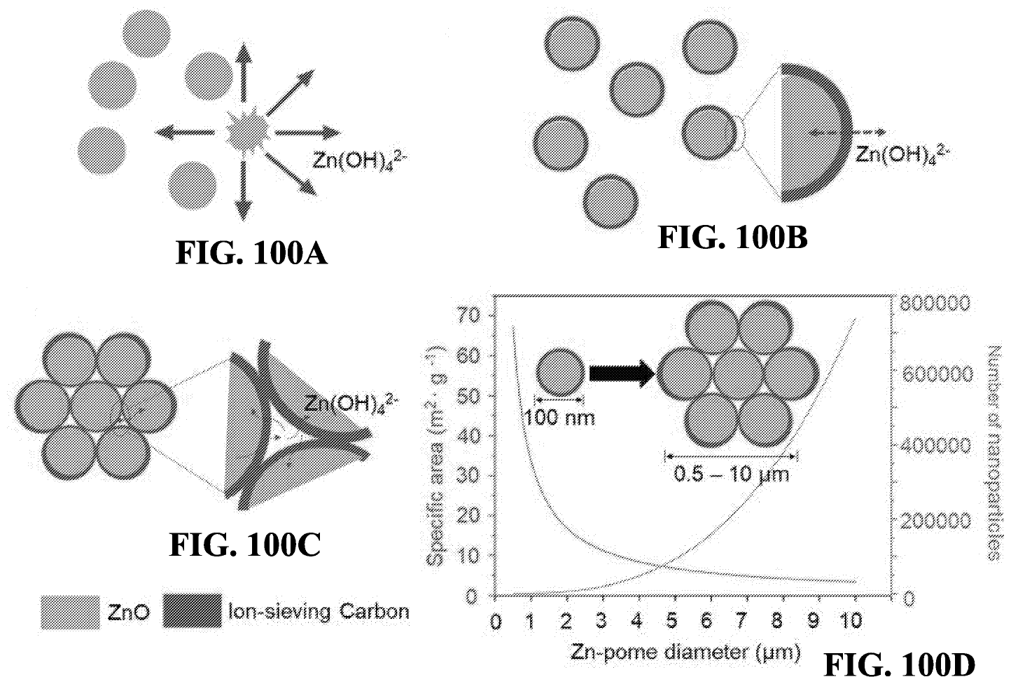

FIG. 100 shows the schematic of zincate motion during battery cycling of ZnO NPs (FIG. 100A), ZnO@C NPs (FIG. 100B) and Zn-pome (FIG. 100C). There are several distinctive advantages of the Zn-pome electrode.

First, multi-layered carbon acts as a conductor, protector, and ion barrier in Zn-pome to adequately constrain the migration of Zn(OH)₄²⁻ (the discharge product), thus mitigating the dendrite formation and shape change of the Zn electrode. Meanwhile, species with a smaller diameter (e.g., OH and H₂O) than zincate can permeate through the carbon shell.

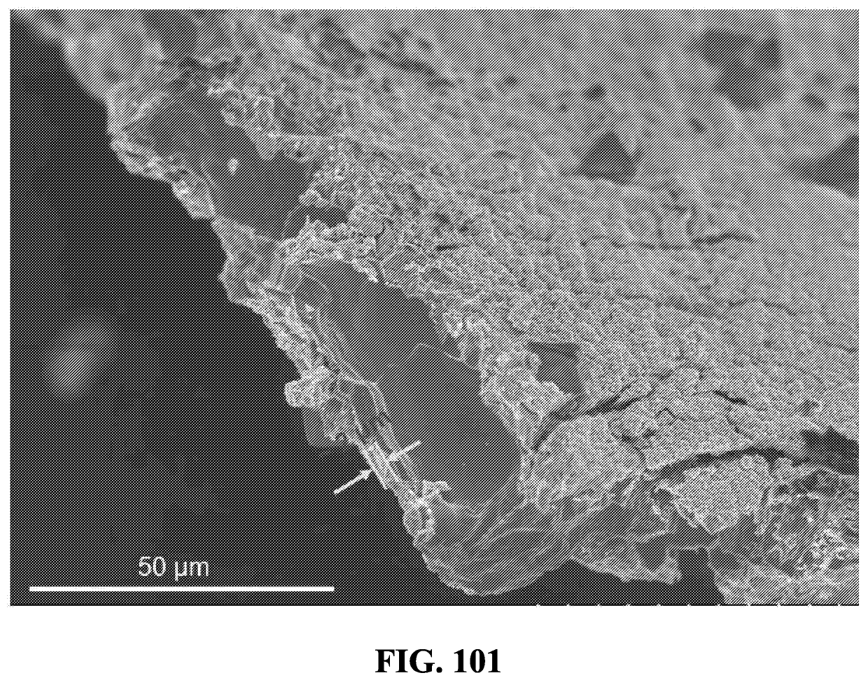

Second, the use of nano-scale (<approximately 100 nm) primary ZnO particles avoids passivation. Once ZnO reaches a critical passivation thickness, it can no longer fully convert to Zn. The thickness of the passivation layer on the zinc foil in coin cells after complete discharging was determined by SEM. As shown in FIGS. 1A, 48, and 101, the thickness of the passivation layer is ˜2 μm, which indicates that the Zn anode cannot be consumed entirely in the discharge process if the size of the Zn material is larger than ˜2 μm regardless of the shape (foil, rod, particle, etc.). Thus, controlling the size of Zn material to nanoscale is a practical approach to fully utilize the Zn material in the charge/discharge process. Therefore, the nanoscale ZnO primary material is chosen to build Zn-pome. Besides, the robust carbon shell on ZnO NPs is both electrically and ionically conducting, which not only allows for effective kinetics, but also improves the mechanical strength of the Zn anode.

Third, the Zn-pome has a smaller solid-electrolyte contact area than ZnO@C NPs (as shown in FIG. 100D), which can significantly reduce the dissolution rate during cycling. Hence, the longstanding limitations that have impeded the rechargeability of Zn electrode (i.e., Zn dendrite formation, Zn electrode shape change and ZnO passivation) can be significantly alleviated by the electrode design of the Zn-pome.

### Microemulsion-Based Assembly of ZnO Nanoparticles Into Clusters

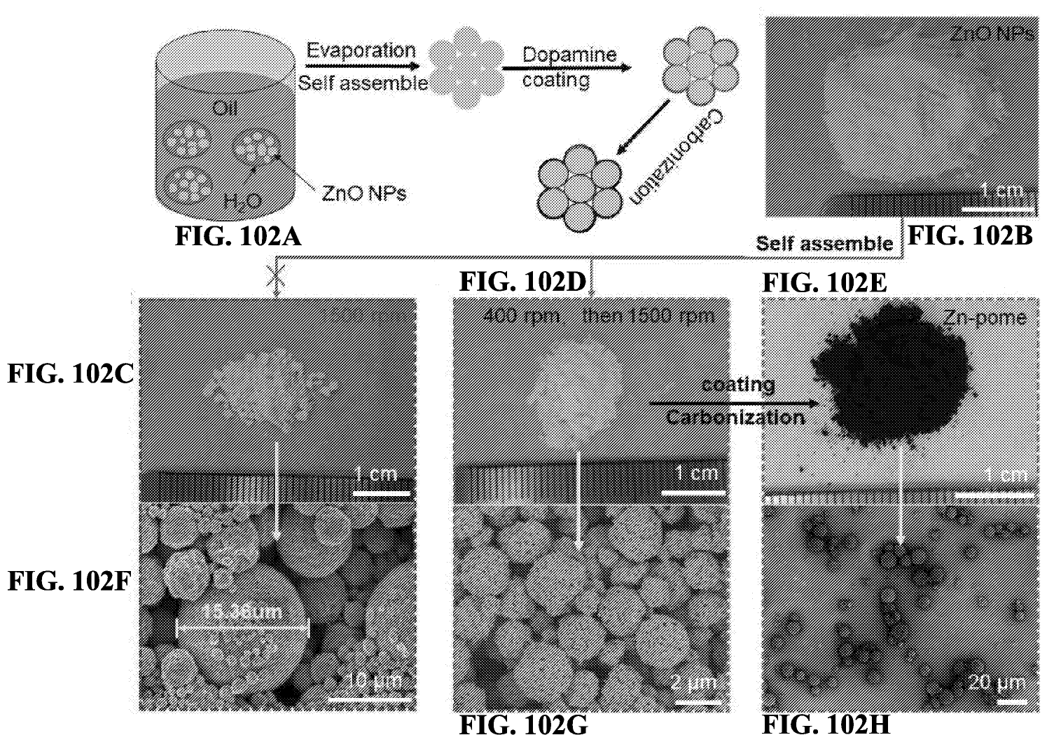

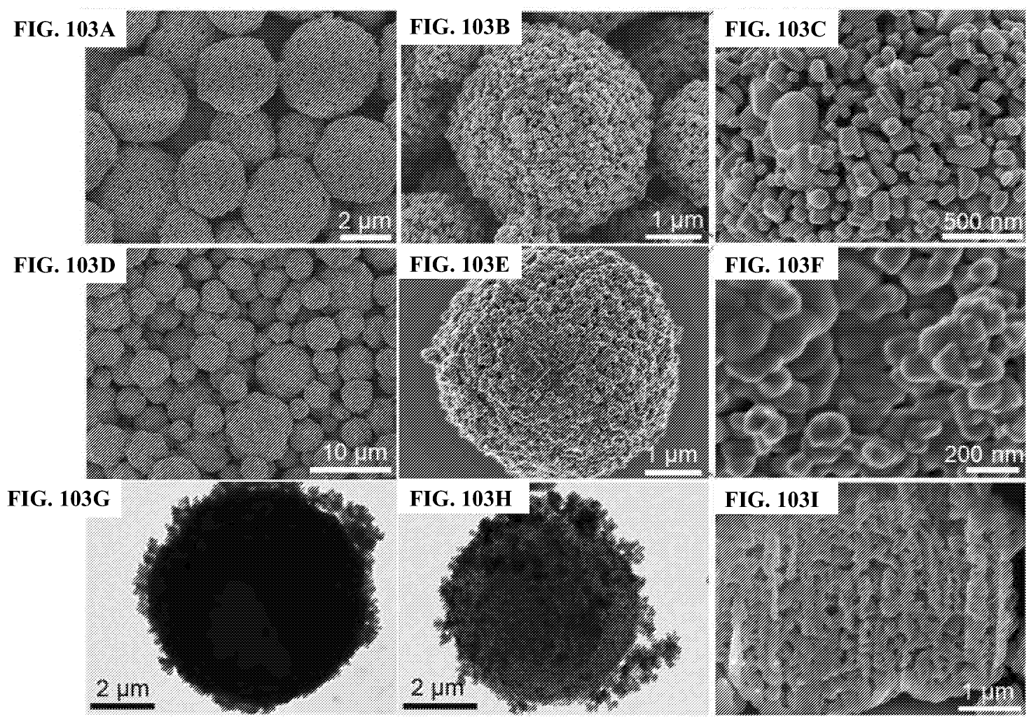

The synthesis of Zn-pome is schematically illustrated in FIGS. 102A-H. The nanoparticles of ZnO (ZnONPs, Aldrich, 100 mg) were dispersed in 2 mL distilled water by ultrasonication for 5 minutes, and then the emulsion was mixed with 8 mL 1-octadecene (ODE, Aldrich) solution containing 0.5 wt % of emulsion stabilizer (amphiphilic block copolymer, Hypermer 2524, Croda USA) and homogenized at 7000 rpm for 1 minute. The water in the mixture was evaporated at generally between 92˜98° C. until no water vapor was observed. Then the ZnO clusters were collected by centrifugation for 5 minutes at 1500 rpm and washed with cyclohexane twice. The cyclohexane was dried on the hotplate at 80° C. The final powder was calcined at 400° C. for 2 hours and 600° C. for 1 hour in air to remove the organics and condense the ZnO clusters.

### Carbon Coating on Clusters

The powder of ZnO clusters (approximately 100 mg) was dispersed in 100 mL of water in 200 mL beaker, and 1000 μL Tris buffer pH 8.5 was added into the beaker while it was stirred at 200 rpm/min The dopamine (200 mg, Aldrich) was added to the mixture, which was then stirred for 24 hours. The Zn-pome was collected by centrifugation at 1500 rpm and washed three times with distilled water. The water was subsequently removed by heating at 80° C. The final Zn-pome was carbonized at 600° C. for 1 hour with a heating rate of 5° C./min in argon atmosphere.

### Characterization

The morphology analysis of bare ZnO, ZnO Clusters, and Zn-pome was carried out using SEM (Hitachi SU 8230). The morphology of Zn-pome and the carbon shell after etching the ZnO cluster was determined using TEM (Hitachi HT7700). The cross-sectioned images of clusters after being etched in 1M HCl were generated using FEI Nova Nanolab 200 FIB/SEM that included SEM imaging and FIB milling. The XRD pattern (Panalytical XPert PRO Alpha-1) for bare ZnO, ZnONPs@C, and Zn-pome were carried out with CuK-Alpha radiation.

The XPS was measured with AlK-Alpha (Thermo K-alpha). XPS survey spectra and high-resolution spectra of Zn2 p, O1s, and C1s were measured. The weight percentage of ZnO in Zn-pome was determined from the weight loss curves measured under air atmosphere on a thermogravimetric analysis (TGA) instrument (TA instrument, Q500) with a heating rate of 5° C./min to 850° C. The specific BET surface areas and pore size distribution were determined by physisorption (BELSORP-MAX, Microtrac BEL Japan, Inc.). The dissolved concentration of bare ZnO, ZnONPs@C, Zn-pome in 4M KOH electrolyte was measured with an ICP measurement: three samples with the same amount of active material were immersed into 4M KOH for 5 minutes, and the supernatant after centrifugation was measured. The ICP samples were filtered with 0.2 μm Acrodisc IC PES filters and diluted 100 times in ICP Matrix Solution.

### Electrode Preparation

Approximately 151 mg synthesized Zn-pome was gently ground in a mortar and transferred into a 4 mL vial with 0.5 g N-Methyl-2-pyrrolidone (NMP) (Aldrich), then the 1.2 g NMP solution containing PVDF (MTI, ˜10 wt % of PVDF) was added to the sample and stirred for 30 minutes. The slurry was then cast onto Sn foil (Alfa) with a Doctor's blade and dried at 80° C. for 30 minutes.

### Electrochemistry

2032 coin cells were assembled under ambient environment, with Zn-pome anode, Ni(OH)₂ cathode obtained from commercial Zn—Ni batteries (PowerGenix), and a separator (GF 6, Whatman). The aqueous electrolyte contains 4M KOH (Aldrich), 2M K₂CO₃ (Aldrich) and 2M KF (Aldrich). The control cells were assembled using the same process as Zn-pome anode batteries, just with the Zn-pome anode replaced by the bare ZnO anode. The cells were charged and discharged at 1 C for comparison between bare ZnO and Zn-pome, and the performances of the 5 C rate discharge and self-discharge were investigated, respectively.

The SEM images of ZnO clusters were investigated under various magnifications (FIGS. 103A-C). These clusters with diameters in the range of approximately 1-6 μm primarily contained ZnO NPs. The rounded edge of the Zn-pome (FIGS. 103D-F) indicated that the ZnO clusters were adequately coated with a thin layer of carbon framework.

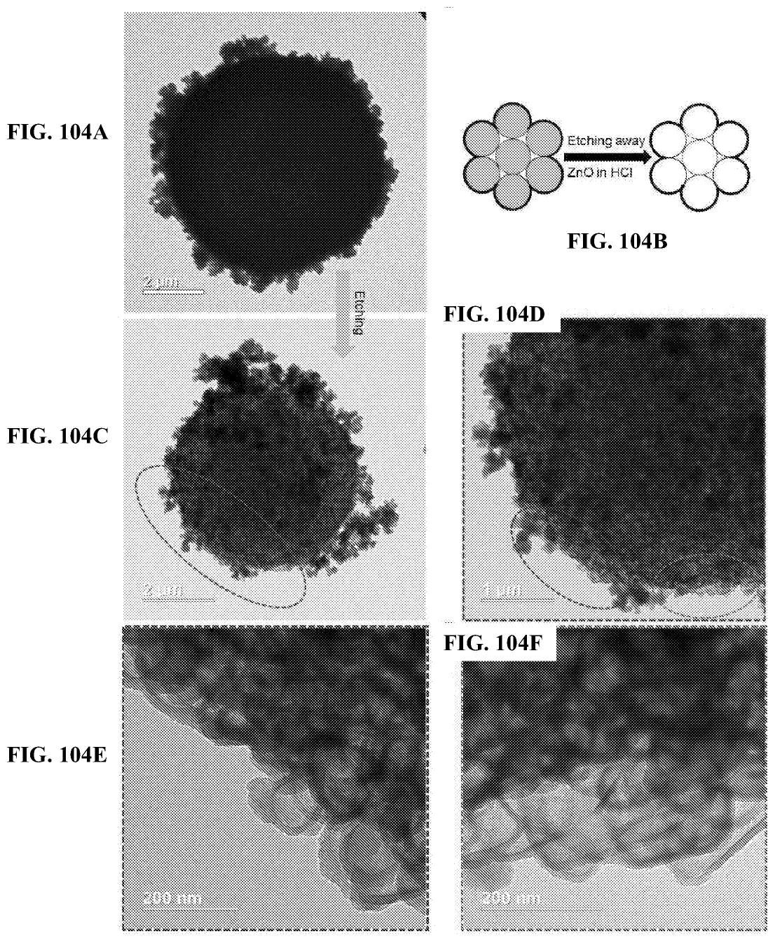

The detailed structure of the Zn-pome was investigated using HRTEM and FIB analysis. According to TEM images (FIGS. 103G and 104A), the diameter of a typical Zn-pome microparticle was ˜6 μm. When the Zn-pome was treated with 1M HCl to etch away ZnO, the hollow carbon framework could be clearly observed in TEM images (FIGS. 103H and 104C-F). This indicated that each ZnO NP was individually coated by a thin layer of carbon framework with thickness of ˜10-15 nm.

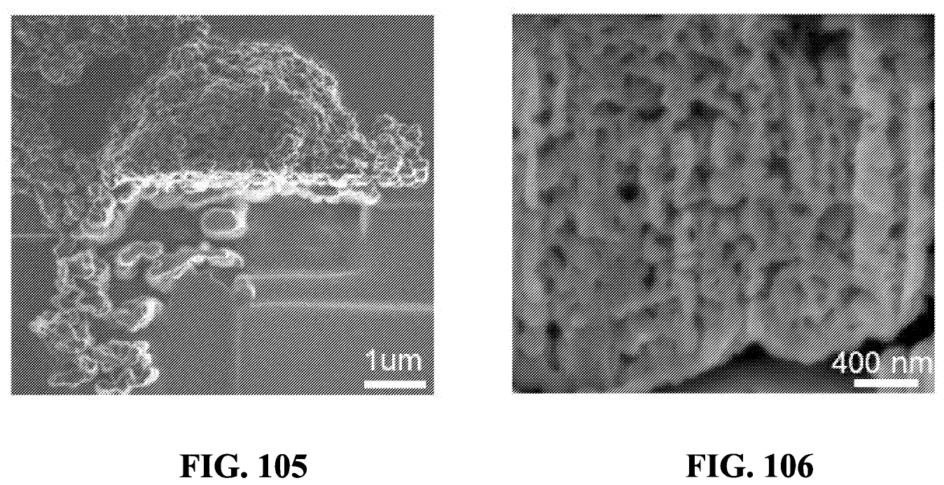

Moreover, the coated carbon framework was stable even without the solid “seeds,” i.e., ZnO NPs, which is important for the structural stability of Zn-pome, especially when the active Zn material is mainly oxidized and dissolved after the deep discharge process. FIG. 103I exhibits the cross-sectional images of the Zn-pome microparticle obtained by FIB analysis. A secondary Zn-pome microparticle comprises ZnO NP clusters, in which each ZnO NP with a rounded surface was uniformly encapsulated by the carbon framework. More cross-sectional images are illustrated in FIGS. 105-106. The abovementioned morphology investigations of Zn-pome reveal that Zn-pome fabricated by bottom-up approach, comprising a robust carbon framework and ZnO nanoparticles, can be used as an anode in zinc-based batteries.

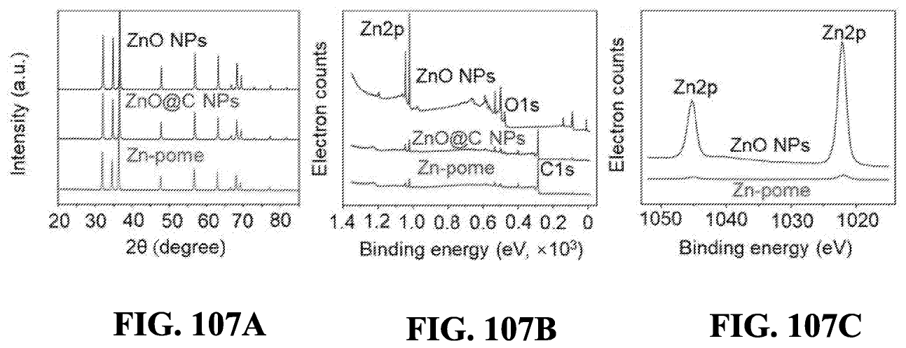

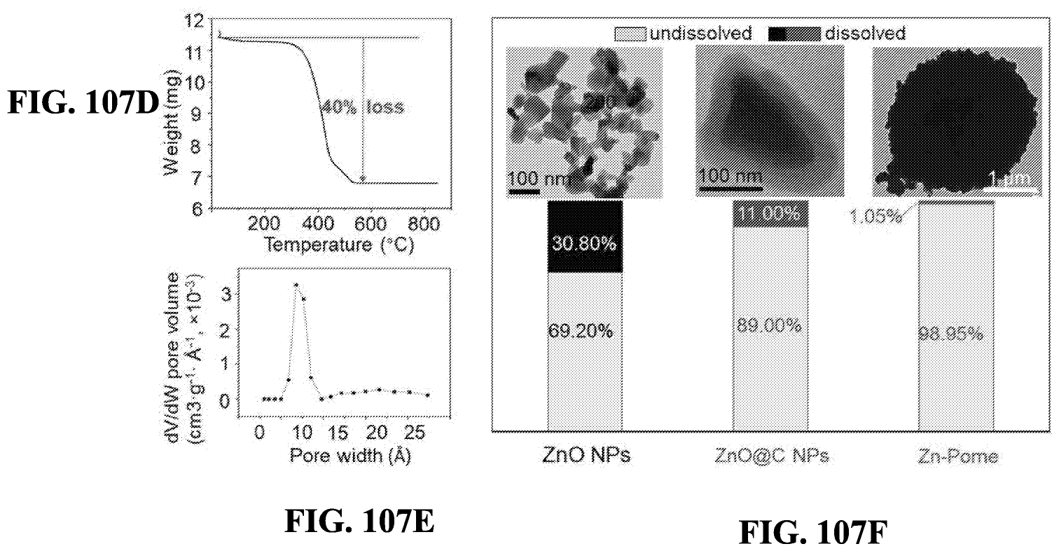

XRD and XPS were used to characterize the crystal structure and chemical composition of Zn-pome (FIGS. 107A-C). The XRD pattern of Zn-pome is similar to that of ZnO NPs and ZnO@C NPs. No characteristic peak of carbon was detected, indicating an amorphous coating of carbon on ZnO NPs. The reduced intensity of ZnO for Zn-pome suggests that ZnO NPs are uniformly covered by the carbon framework; therefore, it shields the diffractive signals of ZnO slightly.

Similarly, strong C1s signal and relatively weak Zn 2 p and O1s signals in the XPS survey spectrum can be observed for Zn-pome in comparison with that for ZnO NPs. Accordingly, Zn-pome is characterized as ZnO NP clusters uniformly coated with an amorphous carbon layer. The content of carbon is found to be approximately 40% in Zn-pome based on TGA in air, as shown in FIG. 107D. The BET results reveal that the average pore size of the carbon shell is ˜10 Å (FIG. 107E). This indicates that the carbon framework can properly mitigate the permeation of zincate through the shell structure.

To verify the ion-sieving ability of the carbon coating, the dissolution rate of ZnO in an aqueous alkaline electrolyte was investigated. Samples of ZnO NPs, ZnO@C NPs and Zn-pome containing equal amounts of zinc were immersed in 1 mL 4M KOH solutions at the same time. After a certain amount of time, the concentrations of Zn species dissolved in the solutions were analyzed by ICP. As shown in FIG. 107F, Zn-pome significantly reduced the portion of dissolved Zn in KOH (approximately 1.05%) in comparison with ZnO NPs (approximately 30.8%) and ZnO@C NPs (approximately 11%). This effect is ascribed to the synergistic function of carbon shell and secondary structure in Zn-pome. The diffusion of zincate in alkaline media is confined within the secondary particles, whereas the confined zincate can still be electrochemically reduced. The pomegranate structure is also expected to alleviate Zn dendrite formation and shape change (i.e., localized densification) during the charge/discharge process. Thus, the long-standing constraints for rechargeability of Zn electrodes can be effectively overcome.

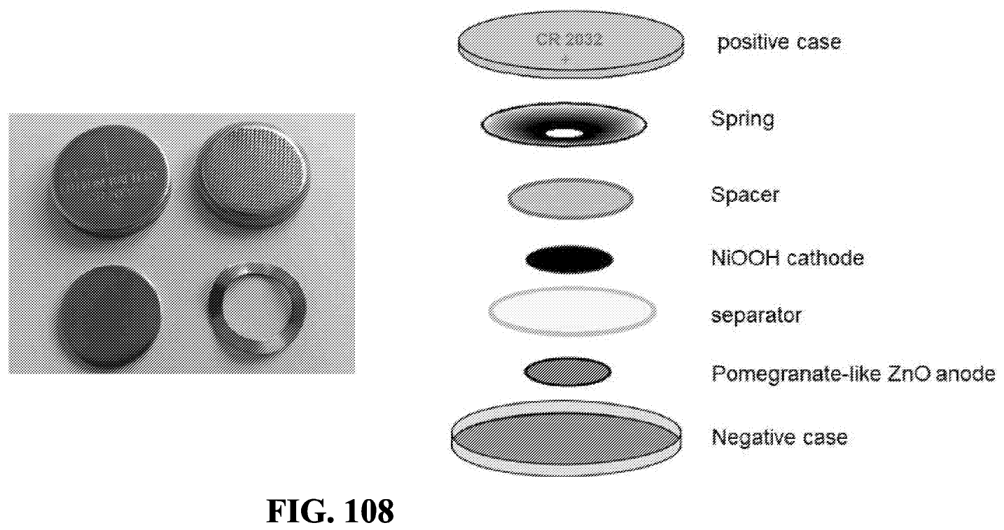

The electrochemical performances of Zn-pome and ZnO NPs were evaluated by a full cell configuration comprising Ni(OH)₂ cathode with excess capacity obtained from commercial zinc-nickel batteries. The cells were cycled at 1 C in a voltage window between 1.5 and 2.0 V in 2M KF, 2M K₂CO₃ and 4M KOH. It should be noted that the battery testing protocols used in this study were extremely harsh in three aspects: (1) limited electrolyte: 2032 coin cells were used with a limited amount of electrolyte (FIG. 108) rather than beaker cells with excess electrolyte because coin cells better represent real operating conditions; (2) ZnO-free electrolyte: ZnO-saturated KOH electrolyte is commonly used to provide higher specific capacity and longer cycle life, but zinc species initially present in the electrolyte probably contribute to the capacity of the cell and conceal the actual performance of active zinc material on the electrode; and (3) approximately 100% DOD: under 100% DOD, the full energy density can be delivered. However, <approximately 50% DOD is used for Zn anodes because of the passivation problem.

Under such harsh testing conditions, the cells containing Zn-pome anode (Zn-pome/Ni(OH)₂) exhibited remarkable capacity and cycle life, which were superior to those of ZnO NP and ZnO NPs@C anodes with Ni(OH)₂ cathode, respectively.

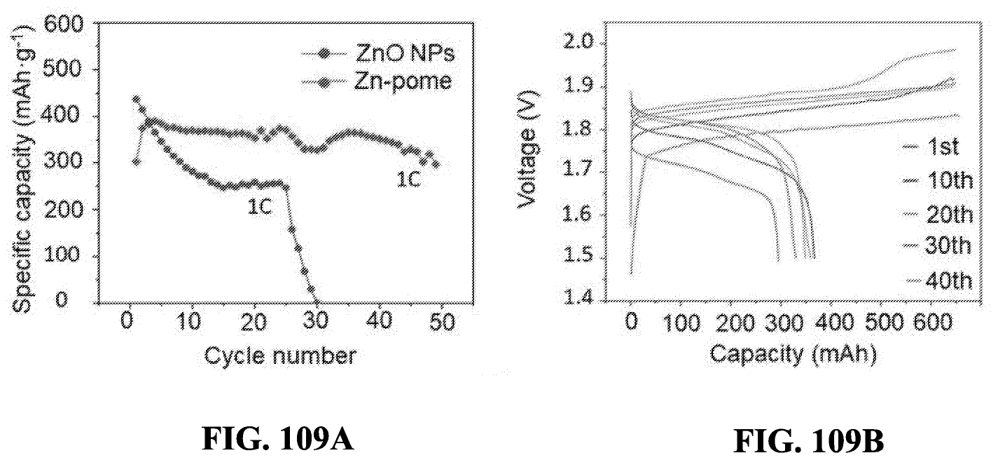

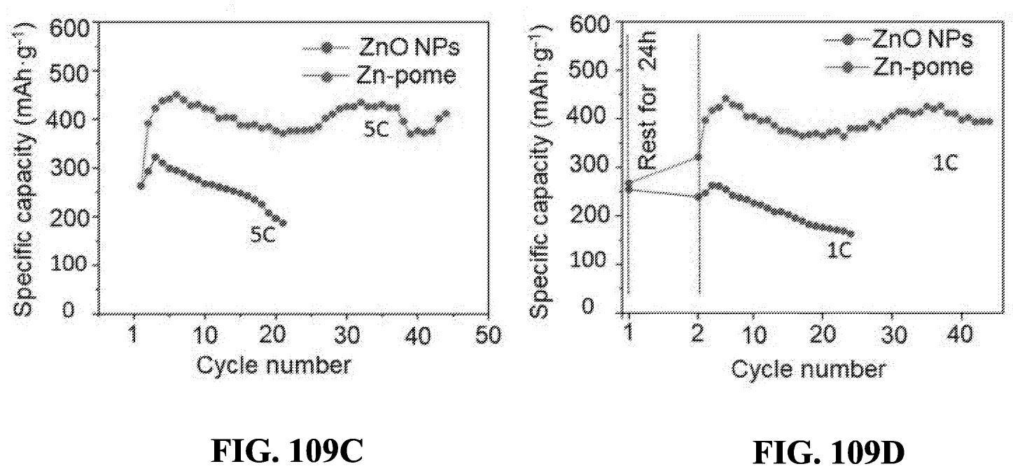

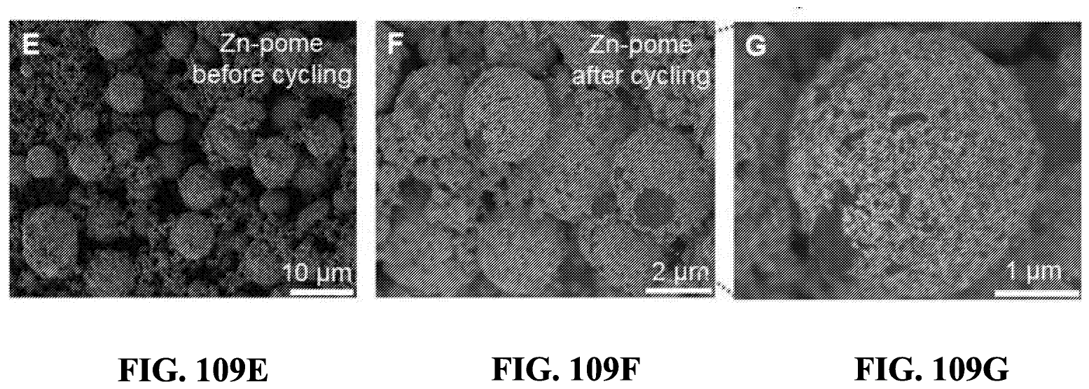

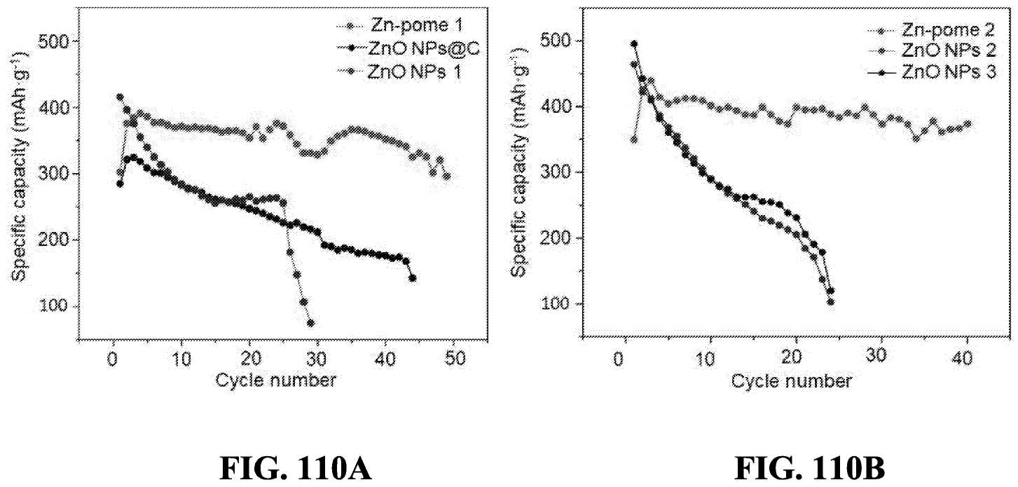

As shown in FIG. 109A and FIGS. 110A-B, although the specific capacity of Zn NPs/Ni(OH)₂ was higher than that of Zn-pome in the first few cycles, the discharge capacity of Zn NPs/Ni(OH)₂ decreased sharply over 20 cycles due to the fading of the anode resulting from the high dissolution rate of ZnO in strong aqueous alkali electrolyte. The problem of abrupt capacity decay of the control sample after 25 cycles can best be ascribed to high dissolution of zinc, which subsequently results in the formation of dendrites and substantial electrode shape change after several cycles from repeated redistribution of the active material.

Other issues stem from the HER on the surface of zinc, which not only worsens efficient utilization of zinc but also leads to swelling of the cell, causing the cell to crack and the electrolyte to dry out. The loose contact in the cells inflated by hydrogen further causes abrupt capacity fading. In contrast, the capacity of Zn-pome/Ni(OH)₂ is stable for 50 cycles and then gradually decreases, showing better cyclability than that of Zn NPs/Ni(OH)₂. This improvement can be ascribed to the ion blocking ability of the carbon shell in the Zn-pome anode and the smaller solid-electrolyte contact area. FIG. 109B presents the typical charge/discharge profiles of the Zn-pome/Ni(OH)₂ battery in the 1^{st}, 10^{th}, 20^{th}, 30^{th} and 40^{th} cycles. The average discharge voltage of the Zn-pome/Ni(OH)₂ cell is maintained at approximately 1.80 V after 40 cycles, indicating excellent cycling stability.

The improved performance of Zn-pome/Ni(OH)₂ cells compared to that of Zn NPs/Ni(OH)₂ is due to the ion-sieving ability of the carbon shell and secondary particle structure. The increase in charging voltage in consecutive cycling is possibly due to the accumulation of hydrogen evolved in the reduction of water. Although managing gas generation in sealed cells remains a concern, hydrogen evolution can be effectively suppressed by the adjustments of electrolyte (such as the use of water-in-salt or solid state additives).

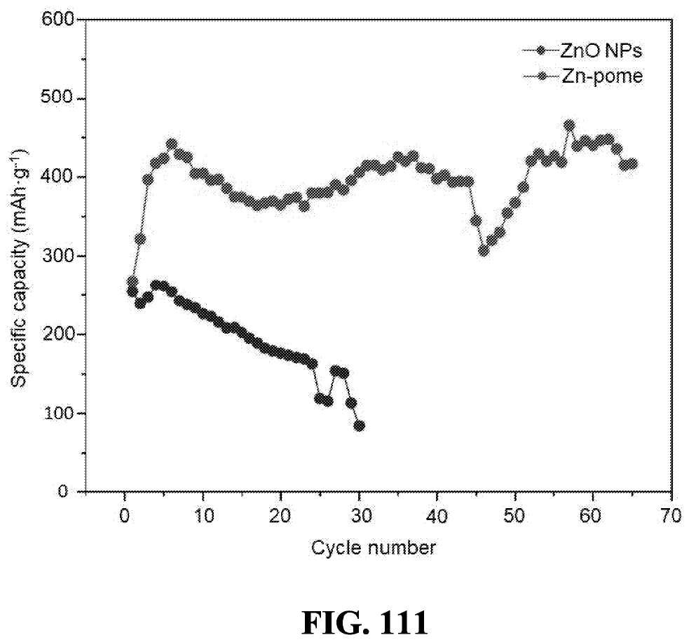

The electrochemical performance of Zn-pome/Ni(OH)₂ is also superior to that of Zn NPs/Ni(OH)₂ at a higher discharge rate (5 C), as shown in FIGS. 109C and 111. The discharge capacity of Zn-pome/Ni(OH)₂ is maintained approximately 400 mAh/g for 45 cycles (e.g., 411 mAh/g at the 44^{th} cycle). However, Zn NPs/Ni(OH)₂ suffers from a quick decay of discharge capacity after the 3^{rd} cycle (merely approximately 186 mAh/g at the 21^{st} cycle). Accordingly, the superior performances (both specific capacity and cyclability) of Zn-pome in comparison with that of ZnO NPs clearly demonstrate the merits of the nano-design of pomegranate-structure ZnO.

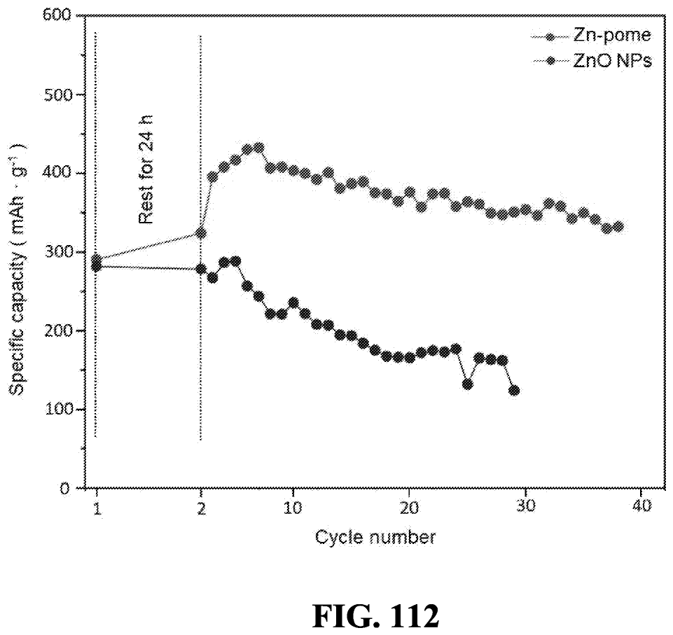

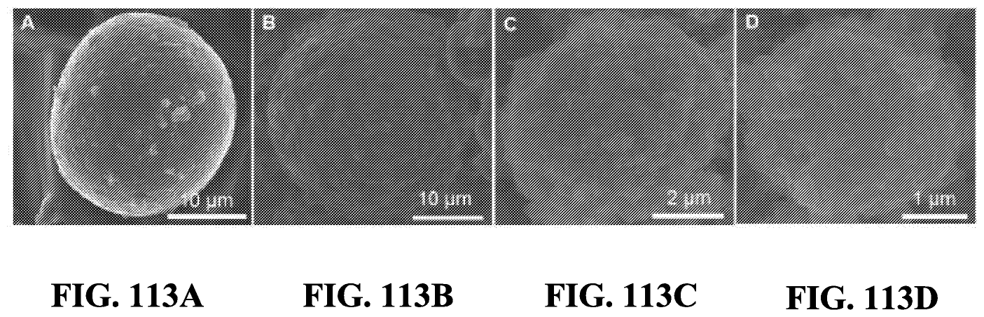

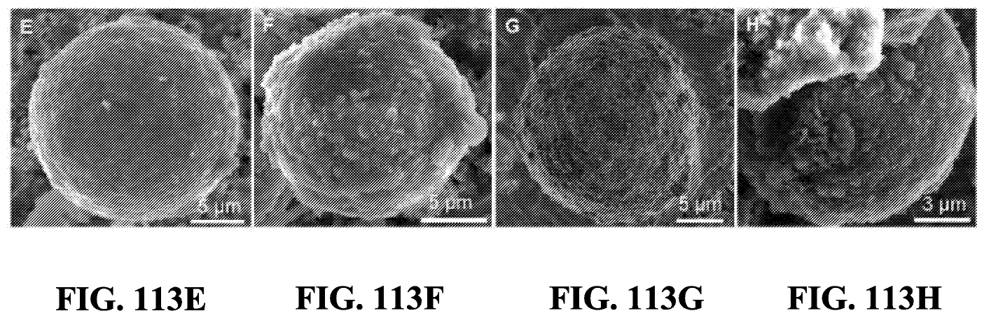

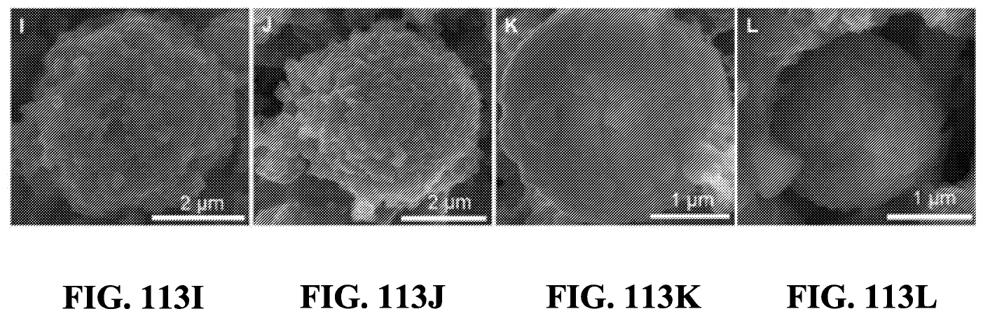

To further investigate dissolution-resistivity, coin cells were used for one cycle at 0.5 C and then rested for 24 hours before resuming cycling at 1 C. During the 24 hour resting period, Zn anodes were in the discharged state, and ZnO, the dominant species, rapidly dissolved in the electrolyte if left unprotected (FIG. 109F). As shown in FIGS. 109D and 112, Zn NPs/Ni(OH)₂ exhibited fast capacity fading. On the other hand, Zn-pome/Ni(OH)₂ still exhibited high capacity after resting and maintained approximately 84% of capacity even after 40 cycles (on the basis of the 3rd cycle), indicating that Zn-pome anode is effective in retaining Zn active species due to the carbon framework.

The morphology evolution of Zn-pome was investigated by SEM (FIGS. 109E-G, and 113A-L). The Zn-pome anode maintained the microspheric morphology after ten charge/discharge cycles, indicating the robust morphology of the pomegranate structure. Therefore, Zn-pome is considered to be a novel Zn anode material that can mitigate the Zn dendrite formation, shape change and passivation issues in alkaline Zn-ion batteries.

A nanoscale pomegranate-inspired hierarchical Zn anode material (Zn-pome) is fabricated via a bottom-up microemulsion approach. Each Zn-pome microsphere is around 6 μm in size and is composed of on the order of 10⁵ ZnO nanoparticles individually encapsulated by an amorphous, microporous, and conductive carbon shell that slows down the dissolution of zincate intermediate species during cycling. The secondary structure further suppresses the zinc dissolution by decreasing the electrode-electrolyte contact area. ICP analysis confirms that Zn-pome exhibits significantly suppressed dissolution of zinc compared to ZnO NP nano-particles and ZnO@C nanoparticles.

The Zn-pome anode demonstrates remarkable capacity and cycle stability under extremely harsh testing conditions (limited electrolyte, ZnO-free electrolyte, and 100% DOD); it also retains high capacity after long-term resting in a discharged state, in which ZnO in the electrode has a massive tendency to dissolve. The success of the Zn-pome anode can be ascribed to inventive design principles that manage soluble intermediates during repeated electrochemical cycling; this is important for future designs of Zn aqueous anodes as well as other battery systems involving soluble intermediates (e.g., lithium-sulfur batteries).

### Ion-Sieving Carbon Nanoshells for Deeply Rechargeable Zn-Based Aqueous Batteries

An optimized structure to solve Zn anodes' passivation and dissolution problems simultaneously is fashioned. Specifically, the structure features (1) a sub-micrometer ZnO particle as the core, and (2) an ion-sieving carbon coating as the shell. First, unlike the bulk Zn foil which is several hundreds of micrometers thick, sub-micrometer particles will not have a passivation problem and will remain active in extended cycling. Starting from ≈100 nm ZnO nanoparticles (discharged state) rather than Zn nanoparticles (charged state) was selected because on the synthesis and scalability aspect, compared to Zn, ZnO is much easier to make into nanostructures which serves as the starting material.

On the battery performance aspect, starting from Zn to ZnO will rupture the carbon shell due to volume expansion. It is of note that nanoparticles with even smaller diameter offer no further benefit to reversibility but have much more severe dissolution concerns. The carbon shell is deposited on the ZnO nanoparticles through carbonization of a uniform polydo-pamine coating. The ability of polydopamine coatings to form a uniform shell with controllable thickness has been confirmed before. The present two-step synthesis method is relatively simple and scalable, and the carbon shell thickness is controllable by simply adjusting the dopamine mass during synthesis.

### ZnO@C Synthesis

100 mg commercial ZnO nanoparticles (<approximately 100 nm, Aldrich) were dispersed into 100 mL DI water followed by 10 minutes of ultrasonication, then 1 mL of Tris-buffer (pH 8.5, Alfa) and 100 (1:1), 200 (2:1) and 300 (3:1) mg of dopamine hydrochloride (Aldrich) were added and mixed for different nanoshell thickness, and then stirred for 24 hours. The fabricated polydopamine-coated ZnO nanoparticles ZnO@P were collected and washed with DI water two times in the centrifuge and dried overnight. Then the ZnO@P particles were heated in a tube furnace under Ar gas to 400° C. with a rate of 1° C./min and stayed for two hours, then to 600° C. with a rate of 5° C./min and stay for one hour.

### Characterization

The morphology analysis of ZnO@C nanoparticles was carried out using SEM (Hitachi SU 8230) and TEM (Hitachi HT7700). The weight percentage of carbon for the sample was determined from the weight loss curves measured under ambient environment on a TGA (TA instrument, Q500) with a heating rate of 5° C./min to 850° C. The threshold ZnO@P calcination temperature was measured with TGA by heating the sample in Ar gas to 900° C. with a heating rate of 5° C./min.

The XRD pattern (Panalytical XPert PRO Alpha-1) for both bare ZnO and ZnO@C nanoparticles were carried out with CuK-Alpha radiation. The specific BET surface areas and pore size distribution were determined by physisorption (BELSORP-MAX, Microtrac BEL Japan, Inc.). The XPS was measured with AlK-Alpha (Thermo K-alpha), XPS survey spectra and high-resolution Zn 2 p, O1s, C1s spectra were measured.

The dissolved concentration of both samples in 4M KOH electrolyte was measured with an ICP measurement, the samples with the same among of active material were immersed into 4M KOH for 5 minutes, 1 day and 10 days, and the supernatant after centrifugation was measured. The ICP samples were filtered with 0.2 μm Acrodisc IC PES filters and diluted 100 times in ICP Matrix Solution.

### Electrode Preparation

Synthesized ZnO@C or as-received ZnO nanoparticles was mixed with carbon black (MTI) and PVDF (MTI) of an 80:10:10 ratio and grinded in a mortar, then NMP (Aldrich) of two times the mass of slurry was added to the sample and stirred in a 4 mL vial for 8 hours to ensure the slurry uniformity. The slurry was then casted onto Sn foil (Alfa) with a Doctor's blade and dried at 90° C. for 1 hour then calendared.

### Electrochemistry

2032 coin cells were assembled under atmosphere environment with the can at the bottom, followed by the ZnO anode, 100 μL electrolyte immersed separator, then the Ni(OH)₂ cathode, spacer, spring and the cap. A commercial Ni(OH)₂ electrode (PowerGenix) was used as the cathode. The separator used for battery testing was glass fiber filter (GF 6, Whatman) unless otherwise noted.

The composition of the electrolyte was KOH (4M, Aldrich) with K₂CO₃ (2M, Aldrich) and KF (2M, Aldrich) added to enhance ionic conductivity. Zn mesh (Dexmet) was discharged with 1 mA in 10 μL with a Celgard 3501 separator. For bulk Zn foil battery testing, Zn foil (0.25 mm, Alfa) was used for the anode while other battery parts remained the same and the GCPL (galvanostatic cycling with potential limitation) test was performed with 2 mAh at 1 C.

The voltage cutoff for GCPL was 2 V and 1.5 V for the charging and discharging processes, the cells were charged and discharged at 1 C for comparison between bare ZnO and ZnO@C nanoparticles. The mass loading of bare ZnO and ZnO@C was 1.03 mg and 0.904 mg for the comparison at low mass loading. Another set of experiments were conducted with 0.941 mg of bare ZnO and 0.98 mg of ZnO@C. The capacity for each cell was calculated with Equation 16:

$$Capacity = \frac{A ctive mass of material}{Molar mass of material} * \frac{n F}{\frac{3.6 C}{mAh}} \qquad ( 11 )$$

Where n is the number of electrons transferred in the relevant reaction, and F is the Faraday constant.

### Computation

Planewave DFT calculations were performed within the generalized gradient approximation of Perdew, Burke, and Ernzerhof (PBE) using the Vienna ab initio Simulation Package (VASP). Projector augmented wave pseudopotentials were used for all calculations. A planewave basis set cutoff energy of 600 eV, k-point sampling at Γ, and an interionic force requirement of forces <0.01 eV/Å were used to model molecular species in a cubic box with 20 Å edge length. All ions were allowed to relax freely to convergence, and molecular species size was determined from the ionic coordinates.

The characterizations and battery performance are for the powders synthesized with a 2:1 dopamine hydrochloride to ZnO nanoparticles ratio except otherwise specified.

As noted, the pore size of the carbon nanoshell is tailored to allow hydroxide ions to pass through while blocking transport of zincate ions. During charging, the zincate intermediate is trapped inside the carbon shell and reacts with Zn within the shell, preventing deposition of Zn in another location. In contrast, the OH⁻ by-product can diffuse out freely through the micropores in the shell due to their smaller size. During discharging, the trapped Zn oxidizes to form ZnO with the participation of OH⁻ coming from outside the shell.

The uniform polydopamine shell is first coated onto ZnO nanoparticles by stirring the particles with dopamine hydrochloride in Tris buffer (pH 8.5) for 24 hours at room temperature in the presence of air. After carbonization at 600° C., ZnO@C nanoparticles are obtained.

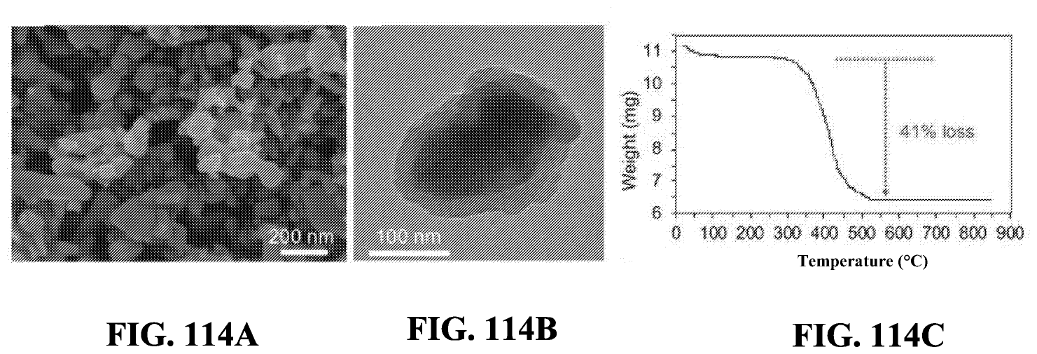

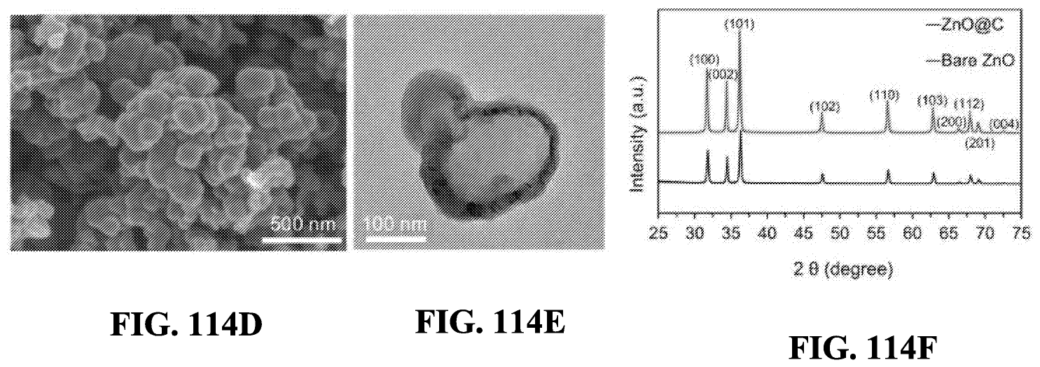

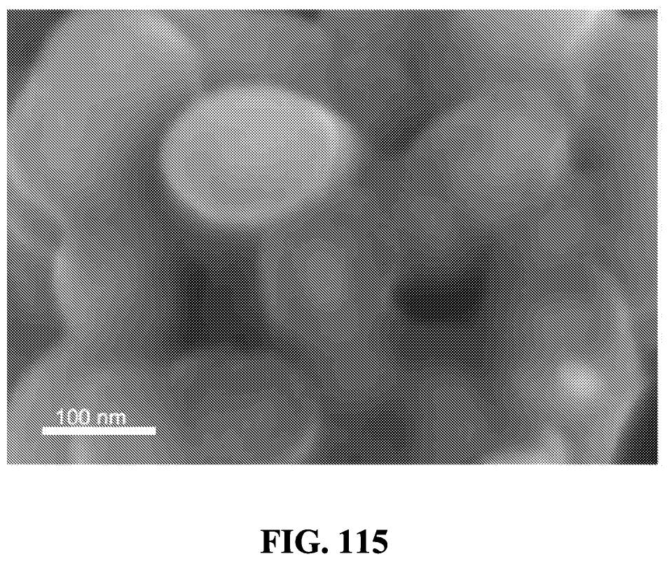

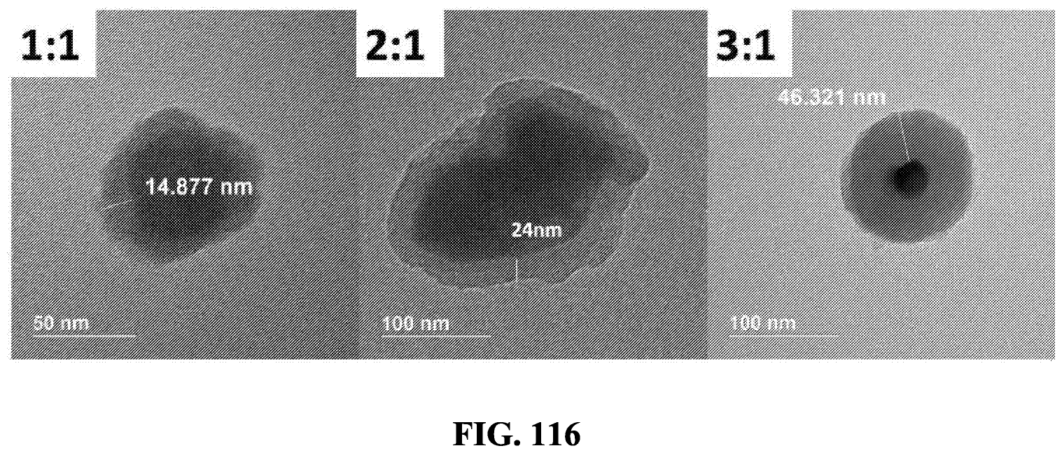

The particles are of short rod-like shapes. An SEM image shows a quasi-spherical morphology of ZnO@C (FIGS. 114B and 115), which indicates the coating is successful, and the particles are of slightly larger size than bare ZnO. The TEM image in FIG. 114B shows a single ZnO@C nanoparticle with an amorphous carbon shell coated uniformly on the surface and the thickness of the carbon shell is approximately 20-30 nm. Notice that the coating thickness is tunable by simply changing the dopamine hydrochloride mass.

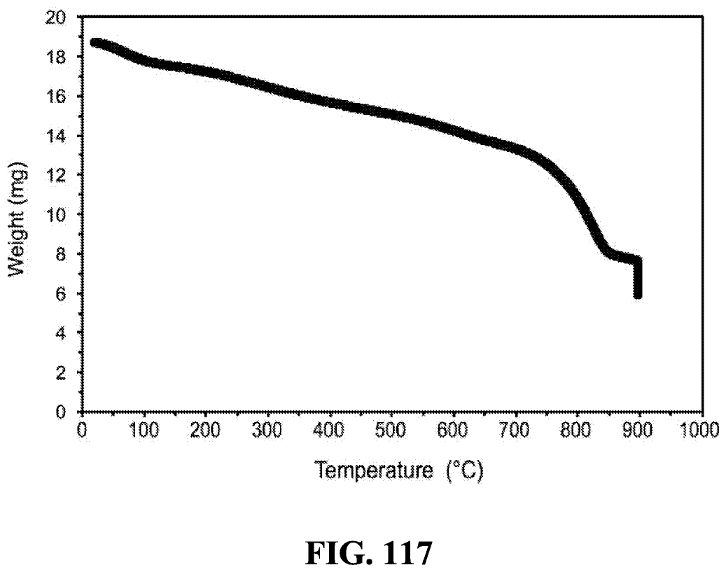

TEM images of single coated particles with different coating thickness are shown in FIG. 116. 600° C. was selected as the carbonization temperature because the ZnO core is reduced to Zn vapor and escapes at above 680° C., determined from the TGA results above, and FIG. 117.

TEM results confirm partial ZnO loss inside the carbon shell at 700° C. and complete loss at 800° C. This phenomenon is also confirmed by the fact that 100 mg ZnO@polydopamine becomes ≈20 mg after 800° C. carbonization, and ≈70 mg after 600° C. treatment, respectively. Complete and self-supporting hollow carbon nanoshells can be obtained after etching away ZnO using HCl (FIG. 114E). The carbon mass fraction in the ZnO@C nanoparticles is determined to be 41% by TGA in ambient air (FIG. 114C). The XRD patterns in FIG. 114F for both the bare ZnO and ZnO@C have the same peak positions, indicating the retention of ZnO hexagonal wurtzite crystalline structure after coating. No signature of crystallinity is observed for the carbon shell.

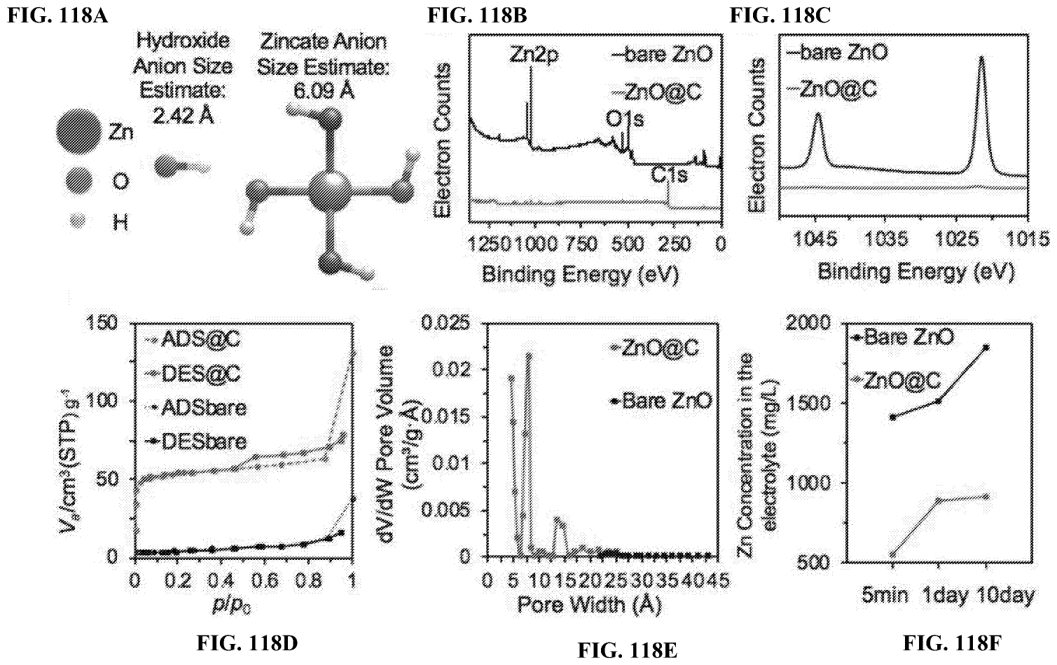

To investigate the nature of the zincate and hydroxide anion species, density functional theory (DFT) calculations discussed above were performed to study the structure and size of each species. The sizes of hydroxide ion and zincate ion, without solvation shells, are simulated to be 2.42 and 6.09 Å, respectively (FIG. 118A). These “rigid molecule” sizes computed here are substantially smaller than the sizes of these ions under thermal motion, but that the calculations support the much smaller size of the hydroxide anion relative to the zincate anion species. An effective ion-sieving nanoshell should be uniform and have a pore size between the sizes of hydroxide and zincate ions.

XPS results confirm the uniformity of the carbon coating. As shown in FIG. 118B, bare ZnO has strong Zn and O signals, while ZnO@C only has a C signal. A comparison between both samples' high-resolution Zn spectra further confirms the complete coverage of carbon on ZnO in ZnO@C (FIG. 118C). The BET method is used to analyze the pore size of carbon-coated ZnO (FIG. 118D). The pore width is calculated from the adsorption/desorption isotherm to be around 5-8 Å (FIG. 118E), between the sizes of hydroxide and zincate ions plus the solvation shell.

Hydroxide species are expected to be more mobile and zincate species to be less mobile when diffusing through the nanoshell. In comparison, uncoated ZnO particles do not have pores in the same range. To directly verify the ability of the sample to prevent ZnO@C from dissolving into the alkaline electrolyte, both ZnO and ZnO@C powders are soaked in KOH (4M) for 5 minutes, 1 day, and 10 days and the dissolved Zn(OH)₄^{2 -} are quantified using inductively coupled plasma atomic emission spectroscopy (ICP-AES). As shown in FIG. 118F, although Zn still dissolves into the electrolyte, the dissolved Zn(OH)₄²⁻ from bare ZnO is much lower and slower than that from ZnO@C, which confirms that the carbon nanoshell functions as a barrier to slow down the zincate escape.

To evaluate the electrochemical performance of ZnO@C nanoparticle anodes, they were paired with commercial Ni(OH)₂ counter electrodes with largely excess areal capacity. 2032 coin-type batteries are used to limit the amount of electrolyte and mimic practical application conditions. A Ni(OH)₂ counter electrode is used rather than an air electrode to evaluate the present anode because Ni(OH)₂ has simpler electrochemistry, fewer factors influencing its battery performance, and it is compatible with sealed coin cells.

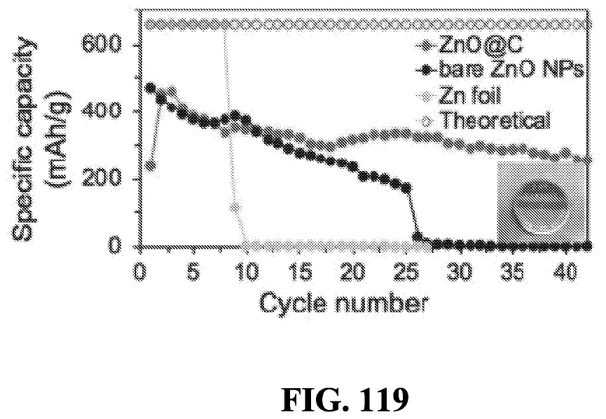

The cells are galvanostatically charged to the theoretical capacity (658.5 mAh/g(ZnO)) and fully discharged to 1.5 V at 1 C rate and 100% DOD. An upper voltage cutoff of 2 V is set to avoid electrolyte decomposition. FIG. 119 compares the specific capacity of ZnO@C anode with a bare ZnO anode at similar mass loading. Performance of Zn foil, which degrades quickly in only seven cycles due to severe ZnO passivation is also shown in the same plot. The bare ZnO anode lasts for 20 cycles before severe capacity degradation is evident, indicating the success of decreasing feature size in mitigating passivation. Without nanoshell encapsulation, zincate is able to dissolve and diffuse prior to redeposition, and electrode morphology changes over cycling. The ZnO@C anode outlasts the bare ZnO anode with ≈1.6 times longer life in terms of cycles, we attribute the increased performance to reduction in the mobility of zincate.

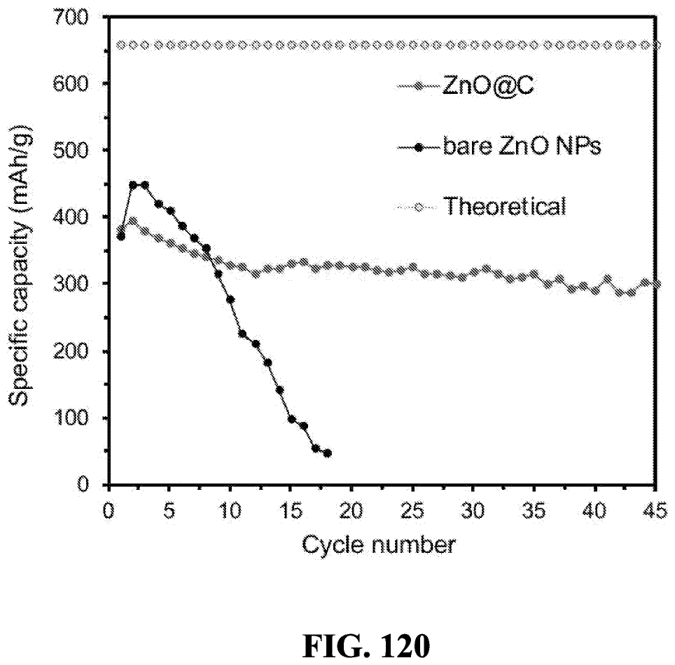

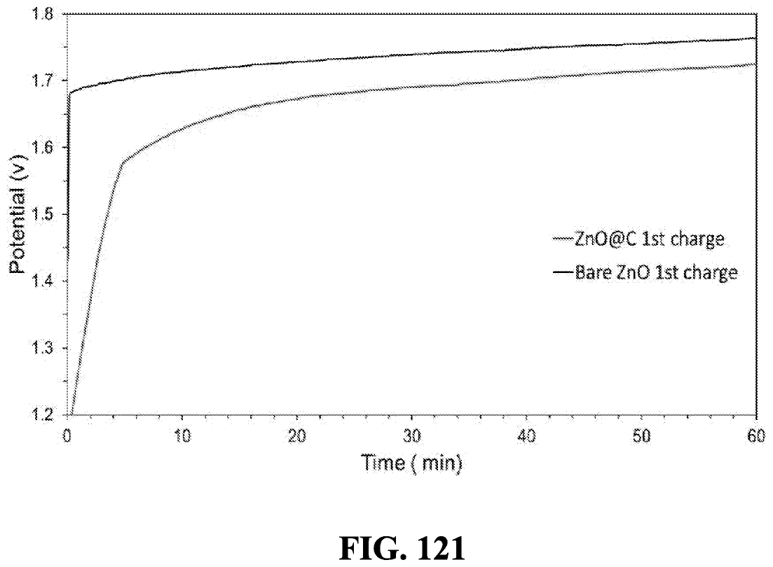

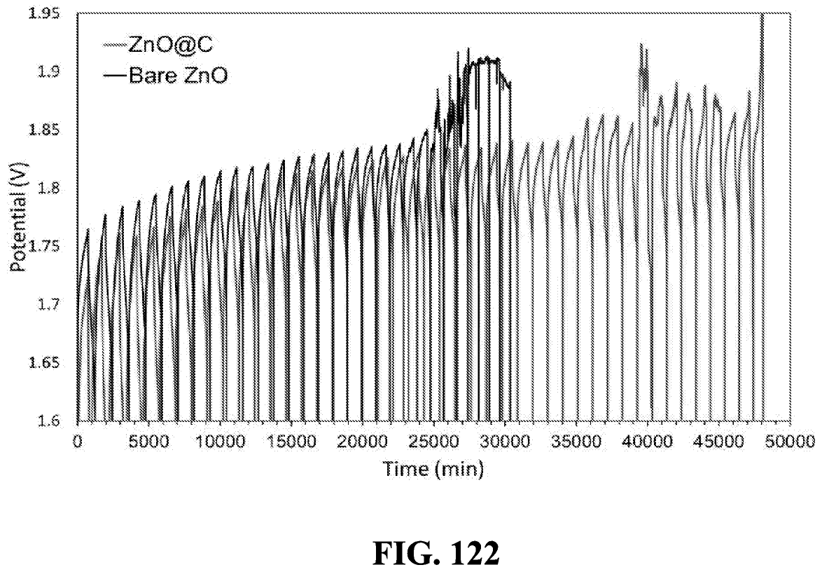

Noticeably, bare ZnO quickly decays to half of the initial energy storage capacity, while ZnO@C has a significantly slower decay and longer cycle life. Another set of cycling data shown in FIG. 120 demonstrates similar battery performance. This supports the hypothesis that the carbon nanoshell has suitable pore sizes to reduce the transport of zincate ions while allowing the hydroxide ions to pass freely. The carbon shell also increases the conductivity of the anode material, which is helpful for preventing the formation of a passivation layer, also with the help of the carbon nanoshell the overpotential for every single cycle of the battery with ZnO@C is lower than that of bare ZnO (FIGS. 121-122).

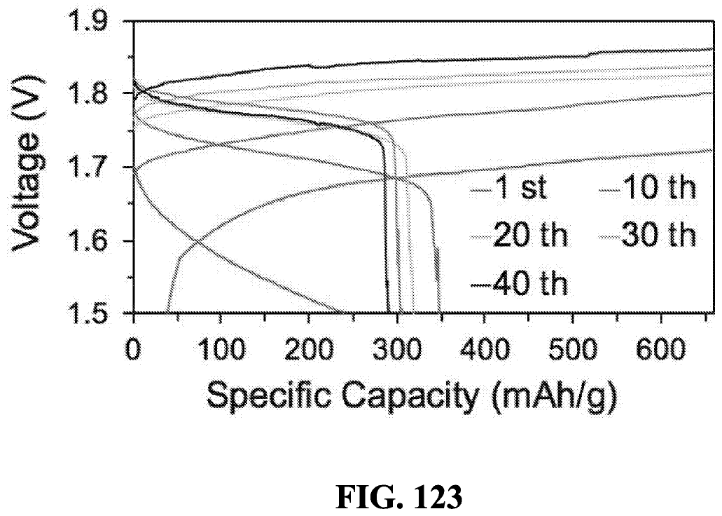

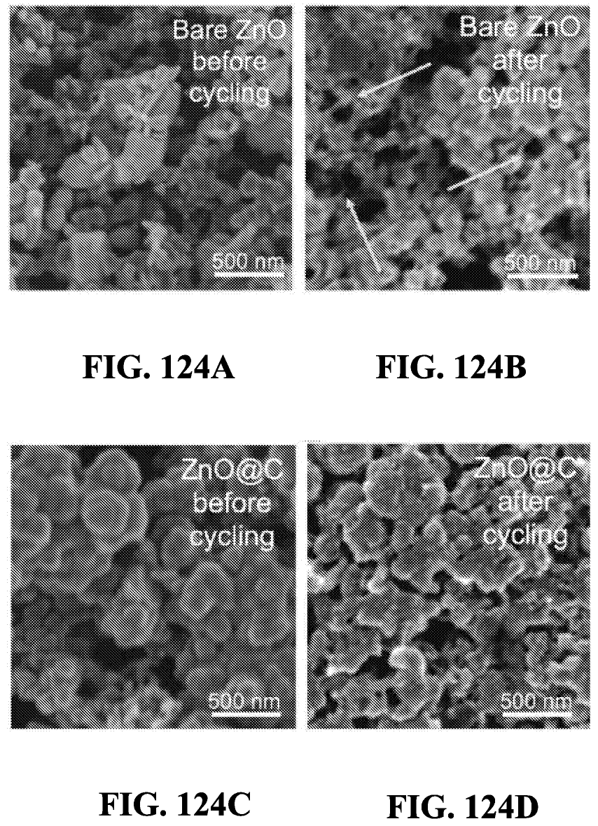

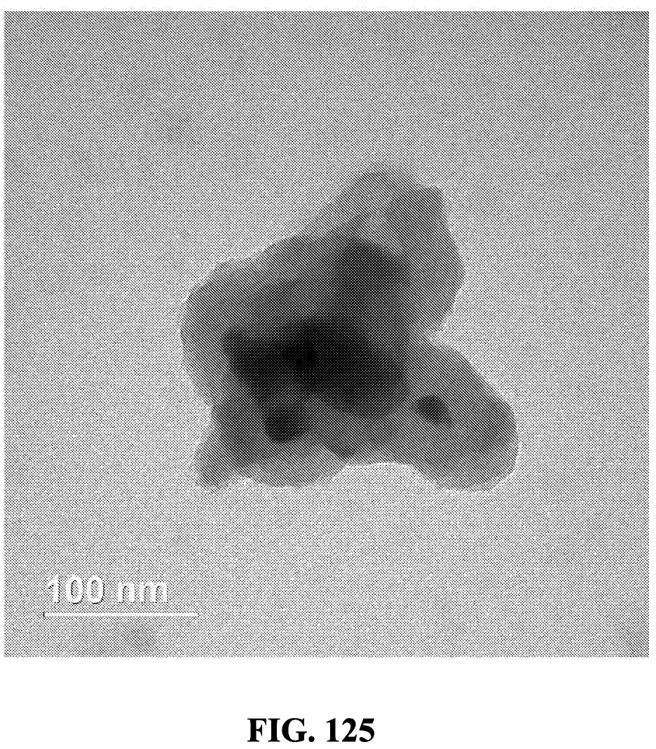

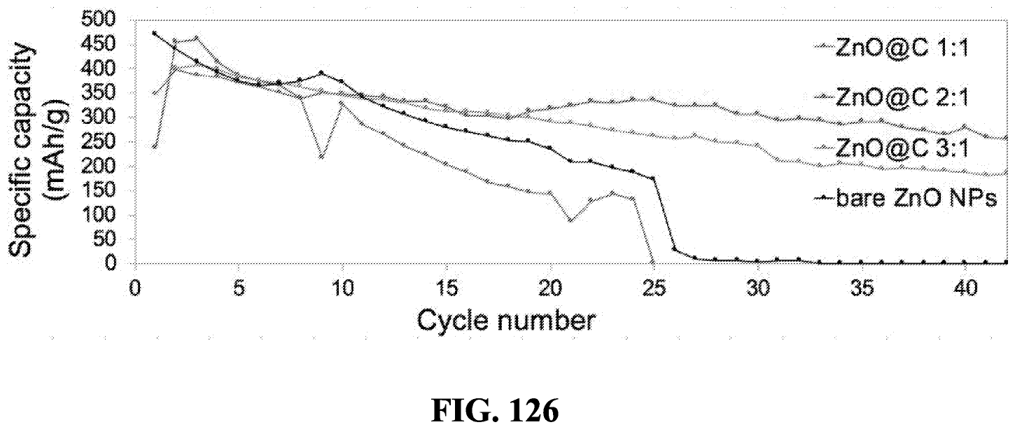

The nitrogen doping also facilitates the conductivity of the carbon layer and charge transfer at the interface. FIG. 123 shows the voltage versus specific capacity during the charging and discharging processes. The performances of the charging processes are similar, indicating a stable performance. FIGS. 124A-D shows the SEM images of both bare and coated ZnO anodes before cycling and after three cycles. Noticeably, the surface of bare ZnO anode has holes after cycling, labeled with yellow arrows in FIG. 124B, which is a result of ZnO dissolution. In contrast, the ZnO@C anode maintained the electrode morphology, which confirms the ability of the carbon shell on ZnO@C to mitigate Zn anode dissolution and passivation. It is also confirmed from the TEM image in FIG. 125 that after charging the active material is still confined in the nanoshell.

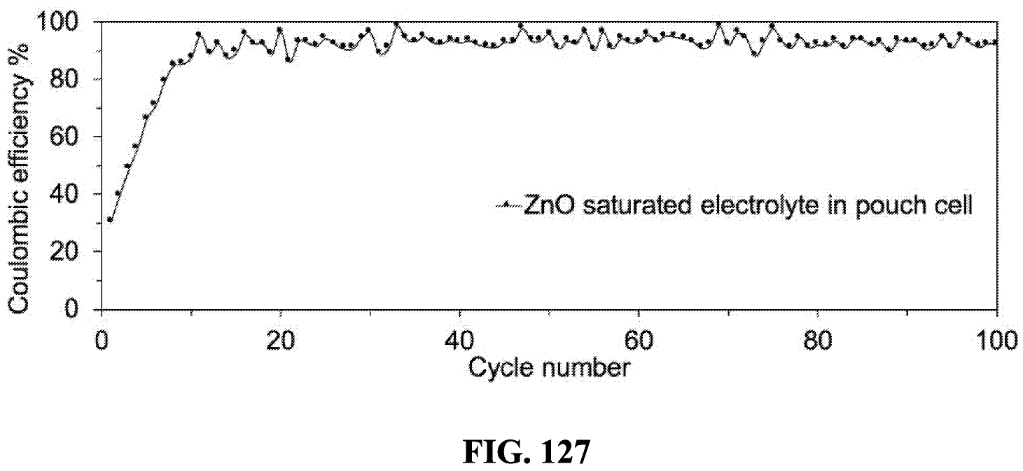

To compare the battery performance under harsh testing conditions reported in this work to the performance under mild testing conditions in most of the past reports, we test a ZnO@C pouch cell using electrolyte saturated with ZnO (FIG. 127), and the battery reaches 100 cycles with >90% efficiency under 100% DOD at 1 C.

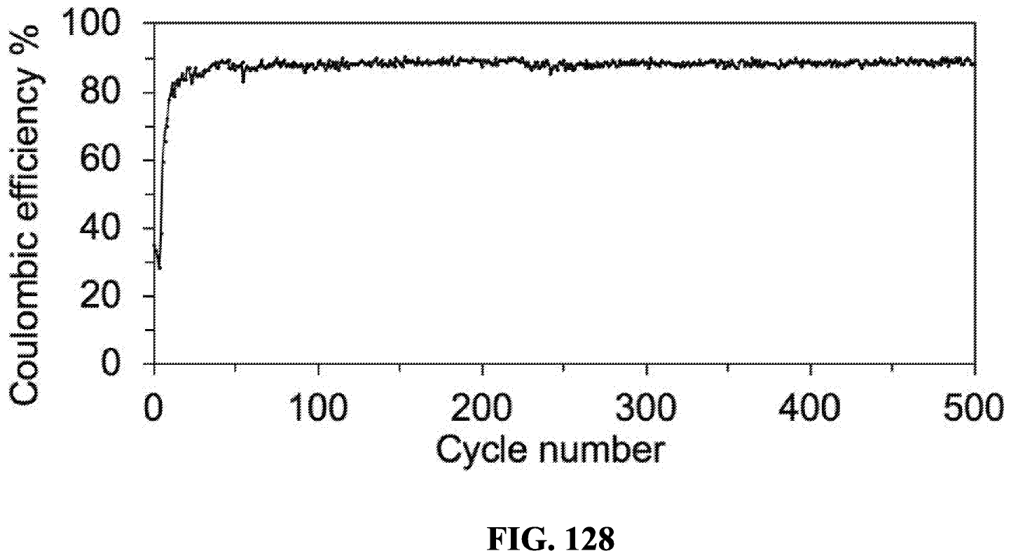

Another ZnO@C pouch cell using electrolyte saturated with ZnO shows a performance of ≈95% efficiency and 100% retention for 500 cycles (FIG. 128), but the battery is cycled at 12 C. The comparison is clear evidence that a deeply rechargeable anode in lean electrolyte configuration is in demand and necessary to reflect the true performance of battery active material in Zn-based aqueous batteries while the drastically enhanced battery performance in most of the past reports is attributed to the ZnO saturated in the electrolyte and low utilization of active material.

In yet another exemplary embodiment of the present invention, the dissolution and passivation problems of Zn anode materials is simultaneously solved by applying an ion-sieving carbon nanoshell coating onto ZnO nanoparticles which are well below the critical passivation thickness. The carbon nanoshell is uniform and complete. The micropores successfully slow down ZnO dissolution and limit zincate ion transport, but allow hydroxide ions to pass freely, and the nanoshells' rigidity prevents anode shape change and dendrite growth.

The battery lifetime is greatly enhanced with the ZnO@C anode; the coated anode outperforms bare ZnO and Zn foil with ≈1.6 and 6 times longer cycle life in a coin cell with harsh testing conditions, respectively. The synthesis is relatively simple and scalable with a controllable nanoshell thickness.

It is to be understood that the exemplary embodiments and claims disclosed herein are not limited in their application to the details of construction and arrangement of the components set forth in the description and illustrated in the drawings. Rather, the description and the drawings provide examples of the exemplary embodiments envisioned. The exemplary embodiments and claims disclosed herein are further capable of other exemplary embodiments and of being practiced and carried out in various ways. Also, it is to be understood that the phraseology and terminology employed herein are for the purposes of description and should not be regarded as limiting the claims.

Accordingly, those skilled in the art will appreciate that the conception upon which the application and claims are based can be readily utilized as a basis for the design of other structures, methods, and systems for carrying out the several purposes of the exemplary embodiments and claims presented in this application. It is important, therefore, that the claims be regarded as including such equivalent constructions.

1. An electrode comprising:
anodic core elements comprising core material, the core material having a core material passivation interface size, a core material intrinsic dissolution rate, and a core material hydrogen evolution reaction (HER) rate; and
a conformal shell coating on an outer surface of the anodic core elements forming core/shell structures;
wherein the anodic core elements comprise a feature size smaller than the core material passivation interface size;
wherein a dissolution rate of the core material from the core/shell structures is less than the core material intrinsic dissolution rate; and
wherein the HER rate of the shell is less than the core material HER rate.

2. The electrode of claim 1, wherein the electrode is deeply rechargeable.

3. The electrode of claim 1, wherein the electrode has a depth of discharge (DOD) of greater than 50%.

4. The electrode of claim 1, wherein the core material is selected from the group comprising a metal, metal oxide, metal sulfide, and combinations thereof.

5. The electrode of claim 1, wherein the core material is selected from the group comprising Zn, Li, Na, Mg, Ca, ZnO, Li₂O, Na₂O, MgO, CaO, ZnS, Li₂S, Na₂S, MgS, CaS, and combinations thereof.

6. The electrode of claim 1, wherein the conformal shell coating comprises a cermet.

7. The electrode of claim 1, wherein the conformal shell coating comprises carbon.

8. The electrode of claim 6, wherein the core/shell structures have a specific discharge capacity of at least 70% of the theoretical limit of the specific discharge capacity of the core material.

9. The electrode of claim 6, wherein the electrode has a coulombic efficiency greater than about 93.5%.

10. The electrode of claim 1, wherein the anodic core/shell structures are formed by a deposition technique of layers of the conformal shell coating over a deposition cycling series; and
wherein a morphology of the anodic core elements prior to the deposition cycling series is substantially the same as a morphology of the core/shell structures after the deposition cycling series.

11. The electrode of claim 1, wherein the anodic core/shell structures are formed by an atomic layer deposition (ALD) technique of layers of the conformal shell coating over an ALD cycling series; and
wherein a morphology of the anodic core elements prior to the ALD cycling series is substantially the same as a morphology of the core/shell structures after the ALD cycling series.

12. The electrode of claim 1, wherein:
the anodic core elements are nanorod structures;
the core material comprises ZnO; and
the conformal shell coating comprises TiNₓO_{y}.

13. The electrode of claim 12, wherein the feature size is diameter of the nanorod structures; and
wherein the diameter is less than approximately 2 μm.

14. (canceled)

15. The electrode of claim 12, wherein the conformal shell coating has a thickness of less than 10 nm.

16. (canceled)

17. The electrode of claim 12, wherein the core/shell structures have a specific discharge capacity of over 500 mAh/g.

18. The electrode of claim 1, wherein:
the anodic core elements are nanoparticles;
the core material comprises ZnO; and
the conformal shell coating comprises carbon.

19. The electrode of claim 18, wherein the conformal shell coating comprises an amorphous, microporous, and conductive carbon.

20. The electrode of claim 19, wherein an assembly of core/shell structures form Zn-pome microspheres (pomegranate-like nanoporous carbon-coated ZnO clusters).

21. The electrode of claim 20, wherein each Zn-pome microsphere has a diameter of approximately 6 μm.

22. The electrode of claim 20, wherein each Zn-pome microsphere comprises on the order of approximately 10⁵ core/shell structures.

23.-26. (canceled)

27. The electrode of claim 20, wherein the Zn-pome microspheres have a specific discharge capacity of over 400 mAh/g.

28. (canceled)

29. The electrode of claim 18, wherein the conformal shell coating comprises an ion-sieving carbon shell.

30.-33. (canceled)

34. A rechargeable battery system comprising:
the electrode of claim 1, wherein the anodic core/shell structures comprise a ZnO core coated with a shell layer of TiNₓO_{y},
an aqueous electrolyte; and
a cathode.

35. The rechargeable battery system of claim 34, wherein one or more of:
the rechargeable battery system is deeply rechargeable;
the rechargeable battery system has a depth of discharge (DOD) of greater than 50%;
each of the core/shell structures function as an electrical pathway and is electrochemically active, and the dissolution rate of Zn from the anodic core/shell structures is less than the intrinsic dissolution rate of ZnO; and
the anodic core/shell structures comprise nanorod structures.

36.-38. (canceled)

39. The rechargeable battery system of claim 35, wherein the cathode comprises Ni(OH)_{2.}

40. The rechargeable battery system of claim 35, wherein the anodic core/shell structures are formed by an atomic layer deposition (ALD) technique of the TiNₓO_{y} on the core over an ALD cycling series; and
wherein a morphology of the core prior to the ALD cycling series remains substantially the same as the morphology of the core/shell structures after the ALD cycling series.

41. The rechargeable battery system of claim 40, wherein the ALD cycling series comprises at least 100 cycles.

42. The rechargeable battery system of claim 41, wherein over an electrochemical cycling series of the battery, the morphology of the core/shell structures after the electrochemical cycling series is substantially the same as the morphology of the core/shell structures prior to the electrochemical cycling series.

43. The rechargeable battery system of claim 42, wherein a mass loading of the anodic core/shell structures is greater than approximately 1.7 mg/cm².

44. The rechargeable battery system of claim 35, wherein the core has a core specific discharge capacity;
wherein the core/shell structures have a core/shell specific discharge capacity;
wherein if the battery has a core electrochemical cycling series defined as the number of cycles until the core specific discharge capacity decays to 50%;
then a core/shell electrochemical cycling series defined as the number of cycles until the core/shell specific discharge capacity decays to 50% is at least 150% longer than the core electrochemical cycling series.

45. A rechargeable battery system comprising:
the electrode of claim 1, wherein an assembly of core/shell structures form anodic Zn-pome microspheres each comprising a pomegranate-like assembly of individual ZnO nanoparticles coated with a shell layer of carbon;
an aqueous electrolyte; and
a cathode.

46. The rechargeable battery system of claim 45, wherein the rechargeable battery system is deeply rechargeable.

47. The rechargeable battery system of claim 45, wherein the Zn-pome microspheres are configured with ion-sieving ability due both to the shell layer of carbon and the micro-structure of the Zn-pome microsphere; and
wherein the dissolution rate of Zn from the Zn-pome microspheres is less than the intrinsic dissolution rate of ZnO.

48.-49. (canceled)

50. A rechargeable battery system comprising:
the electrode of claim 1, wherein the anodic core/shell structures comprise anodic core/shell nanoparticles comprising a ZnO core coated with a shell layer of carbon;
an aqueous electrolyte; and
a cathode.

51. The rechargeable battery system of claim 50, wherein the rechargeable battery system is deeply rechargeable;
wherein the conformal shell coating comprises an ion-sieving carbon shell;
wherein the core/shell nanoparticles have a diameter less than approximately 2 μm;
wherein the conformal shell coating has a thickness of less than approximately 30 nm; and
wherein the cathode comprises Ni(OH)₂.

52.-57. (canceled)
